(19) United States
(12) Patent Application Publication
(10) Pub. No.: US 2025/0280541 A1
(43) Pub. Date: Sep. 4, 2025

(54) MEMORY DEVICE AND MANUFACTURING METHOD THEREOF

(71) Applicant: WUHAN XINXIN SEMICONDUCTOR MANUFACTURING CO., LTD., WUHAN (CN)

(72) Inventor: Kaiwei CAO, WUHAN (CN)

(21) Appl. No.: 19/207,414

(22) Filed: May 14, 2025

Related U.S. Application Data
(63) Continuation of application No. PCT/CN2023/124594, filed on Oct. 13, 2023.

(30) Foreign Application Priority Data
Dec. 20, 2022 (CN) 202211643910.2

(51) Int. Cl. H10B 43/30; H10B 41/27; H10B 41/30; H10B 43/27

(52) U.S. Cl. CPC H10B 43/30; H10B 41/27; H10B 41/30; H10B 43/27

(57) ABSTRACT

The present disclosure provides a memory device and a manufacturing method thereof. The memory device includes a substrate and at least one memory array. Each memory subarray layer in each memory array includes a drain region semiconductor layer, a channel semiconductor layer, and a source region semiconductor layer. The drain region semiconductor layer, the channel semiconductor layer, and the source region semiconductor layer respectively include multiple drain region semiconductor strips, channel semiconductor strips, and source region semiconductor strips. A column of drain region semiconductor strips, channel semiconductor strips, and source region semiconductor strips is a column of semiconductor strip structures. Each memory array includes a channel connection structure, in contact with each channel semiconductor strip in each column of semiconductor strip structures, and insulated from each drain region semiconductor strip and each source region semiconductor strip in each column of semiconductor strip structures.

### CROSS REFERENCE TO RELATED APPLICATIONS

The present disclosure is a continuation of International Patent Application No. PCT/CN2023/124594, filed on Oct. 13, 2023, which claims priority to Chinese patent application No. 202211643910.2, filed on Dec. 20, 2022, the entire contents of these applications are incorporated herein by reference.

### TECHNICAL FIELD

The present disclosure relates to the field of semiconductor technologies, and in particular to a memory device and a manufacturing method thereof.

### BACKGROUND

Two-dimensional (2D) memory devices are prevalent in electronic devices and may include, for example, NOR-flash memory arrays, NAND-flash memory arrays, dynamic random-access memory (DRAM) arrays, etc. However, 2D memory arrays are approaching scaling limits and the storage density cannot be further increased. Channel connection posts, which are respectively configured to lead out each channel portion from a plurality of stacked memory cells for storage, occupy a relatively large area on surfaces of the memory arrays, leading to a relatively high degree of difficulty and a relatively high cost in a manufacturing process.

### SUMMARY

To solve the above technical problems, a solution adopted by the present disclosure is to provide a memory device. The memory device includes: a substrate; at least one memory array arranged on the substrate. Each memory array includes a plurality of memory subarray layers sequentially stacked along a height direction, and each memory subarray layer includes a drain region semiconductor layer, a channel semiconductor layer, and a source region semiconductor layer stacked along the height direction. In each memory subarray layer, the drain region semiconductor layer includes a plurality of drain region semiconductor strips spaced apart along a row direction, each drain region semiconductor strip extending along the row direction; the channel semiconductor layer includes a plurality of channel semiconductor strips spaced apart along the row direction, each channel semiconductor strip extending along a column direction; the source region semiconductor layer includes a plurality of source region semiconductor strips spaced apart along the row direction, each source region semiconductor strip extending along the column direction. A column of drain region semiconductor strips, channel semiconductor strips, and source region semiconductor strips in the memory subarray layers is defined as a column of semiconductor strip structures. Each memory array further includes a channel connection structure, the channel connection structure extends along the height direction, and the channel connection structure is in contact with each channel semiconductor strip in each column of semiconductor strip structures, and is insulated from each drain region semiconductor strip and each source region semiconductor strip in each column of semiconductor strip structures.

To solve the above technical problems, another solution adopted by the present disclosure is to provide a manufacturing method of a memory device. The method includes: providing a semiconductor substrate, the semiconductor substrate including a substrate and a plurality of memory subarray layers arranged on the substrate and sequentially stacked in a height direction, and each memory subarray layer including a drain region semiconductor layer, a channel semiconductor layer, and a source region semiconductor layer stacked along the height direction; in each memory subarray layer, the drain region semiconductor layer includes a plurality of drain region semiconductor strips spaced apart along a row direction, each drain region semiconductor strip extending along the row direction; the channel semiconductor layer includes a plurality of channel semiconductor strips spaced apart along the row direction, each channel semiconductor strip extending along a column direction; the source region semiconductor layer includes a plurality of source region semiconductor strips spaced apart along the row direction, each source region semiconductor strip extending along the column direction; a column of drain region semiconductor strips, channel semiconductor strips, and source region semiconductor strips in the memory subarray layers being defined as a column of semiconductor strip structures; defining a connection hole on the semiconductor substrate; forming a channel connection structure through the connection hole, the channel connection structure extending along the height direction, and the channel connection structure being in contact with each channel semiconductor strip in each column of semiconductor strip structures, and being insulated from each drain region semiconductor strip and each source region semiconductor strip in each column of semiconductor strip structures.

### BRIEF DESCRIPTION OF THE DRAWINGS

In order to more clearly illustrate the technical solutions in the embodiments of the present disclosure or in the related art, a brief introduction will be provided below for the drawings required in the embodiments. It is apparent that the drawings described herein are merely some embodiments of the present disclosure. For those skilled in the art, other drawings may also be obtained according to the drawings without inventive effort.

FIG. 1 is a perspective structural schematic view of a memory array according to an embodiment of the present disclosure.

FIG. 2 is another perspective structural schematic view of a memory array according to an embodiment of the present disclosure.

FIG. 3 is further another perspective structural schematic view of a memory array according to an embodiment of the present disclosure.

FIG. 4 is further another perspective structural schematic view of a memory array according to an embodiment of the present disclosure.

FIG. 5 is a perspective structural schematic view of a memory cell according to an embodiment of the present disclosure.

FIG. 6 is a perspective schematic view of a structure in which of two memory cells share the same column of drain region semiconductor strip, channel semiconductor strip, and source region semiconductor strip.

FIG. 7 is a perspective structural schematic view of a memory cell according to another embodiment of the present disclosure.

FIG. 8 is a perspective structural schematic view of a memory cell according to further another embodiment of the present disclosure.

FIG. 9 is a perspective schematic view of a partial structure of a memory device according to another embodiment of the present disclosure.

FIG. 10 is a perspective structural schematic view of a memory cell according to further another embodiment of the present disclosure.

FIG. 11 is a perspective structural schematic view of a memory device according to further another embodiment of the present disclosure.

FIG. 12 is a structural schematic view of a circuit connection of part of memory cells of a memory device according to an embodiment of the present disclosure.

FIG. 13 is a schematic view of a circuitry of the memory device shown in FIG. 11.

FIG. 14 is a schematic sketch of a plan view of the memory device shown in FIG. 11.

FIG. 15 is a schematic view of a memory cell corresponding to each layer of bit lines.

FIG. 16 is a schematic view of a three-dimensional distribution of word-lines and bit lines.

FIG. 17 is a flowchart of a manufacturing method of a memory device according to an embodiment of the present disclosure.

FIG. 18 is a schematic view of structure at a specific operation of a manufacturing method of a memory block according to an embodiment of the present disclosure.

FIG. 19 is a schematic view of structure at another specific operation of a manufacturing method of a memory block according to an embodiment of the present disclosure.

FIG. 20 is a schematic view of structure at further another specific operation of a manufacturing method of a memory block according to an embodiment of the present disclosure.

FIG. 21 is a schematic view of structure at further another specific operation of a manufacturing method of a memory block according to an embodiment of the present disclosure.

FIG. 22 is a schematic view of structure at further another specific operation of a manufacturing method of a memory block according to an embodiment of the present disclosure.

FIG. 23 is a schematic view of structure at further another specific operation of a manufacturing method of a memory block according to an embodiment of the present disclosure.

FIG. 24a is a schematic view of structure at further another specific operation of a manufacturing method of a memory block according to an embodiment of the present disclosure.

FIG. 24b is a schematic view of structure at further another specific operation of a manufacturing method of a memory block according to an embodiment of the present disclosure.

FIG. 25a is a schematic view of structure at further another specific operation of a manufacturing method of a memory block according to an embodiment of the present disclosure.

FIG. 25b is a schematic view of structure at further another specific operation of a manufacturing method of a memory block according to an embodiment of the present disclosure.

FIG. 26 is a schematic view of structure at further another specific operation of a manufacturing method of a memory block according to an embodiment of the present disclosure.

FIG. 27 is a schematic view of structure at further another specific operation of a manufacturing method of a memory device according to an embodiment of the present disclosure.

FIG. 28 is a flowchart of a manufacturing method of a memory device according to another embodiment of the present disclosure.

FIG. 29 is a schematic view of structure at a specific operation of a manufacturing method of a memory block according to another embodiment of the present disclosure.

FIG. 30 is a schematic view of structure at another specific operation of a manufacturing method of a memory block according to another embodiment of the present disclosure.

FIG. 31 is a schematic view of structure at further another specific operation of a manufacturing method of a memory block according to another embodiment of the present disclosure.

FIG. 32 is a schematic view of structure at further another specific operation of a manufacturing method of a memory block according to another embodiment of the present disclosure.

FIG. 33 is a schematic view of structure at further another specific operation of a manufacturing method of a memory block according to another embodiment of the present disclosure.

FIG. 34 is a schematic view of structure at further another specific operation of a manufacturing method of a memory block according to another embodiment of the present disclosure.

FIG. 35 is a schematic view of structure at further another specific operation of a manufacturing method of a memory block according to another embodiment of the present disclosure.

FIG. 36a is a schematic view of structure at further another specific operation of a manufacturing method of a memory block according to another embodiment of the present disclosure.

FIG. 36b is a schematic view of structure at further another specific operation of a manufacturing method of a memory block according to another embodiment of the present disclosure.

FIG. 37 is a schematic view of structure at further another specific operation of a manufacturing method of a memory block according to another embodiment of the present disclosure.

FIG. 38 is a schematic view of structure at further another specific operation of a manufacturing method of a memory block according to another embodiment of the present disclosure.

FIG. 39a is a schematic view of structure at further another specific operation of a manufacturing method of a memory block according to another embodiment of the present disclosure.

FIG. 39b is a schematic view of structure at further another specific operation of a manufacturing method of a memory block according to another embodiment of the present disclosure.

FIG. 40 is a schematic view of structure at further another specific operation of a manufacturing method of a memory block according to another embodiment of the present disclosure.

FIG. 41 is a schematic view of structure at further another specific operation of a manufacturing method of a memory block according to another embodiment of the present disclosure.

FIG. 42 is a schematic view of structures at further another specific operation of a manufacturing method of a memory device according to another embodiment of the present disclosure.

FIG. 43a is a perspective structural schematic view of a memory array according to another embodiment of the present disclosure.

FIG. 43b is a schematic sketch of a plan view of a memory device corresponding to the memory array shown in FIG. 43a.

FIG. 44a is a distribution schematic view of channel connection posts according to an embodiment of the present disclosure.

FIG. 44b is another distribution schematic view of channel connection posts according to an embodiment of the present disclosure.

FIG. 45 is a cross-sectional view along G-direction of a product corresponding to FIG. 43b.

FIG. 46a is a perspective structural schematic view of a memory array according to another embodiment of the present disclosure.

FIG. 46b is another perspective structural schematic view of a memory array according to another embodiment of the present disclosure.

FIG. 47 is a schematic sketch of a plan view of a memory device corresponding to the memory array shown in FIG. 46b.

FIG. 48 is a partial top view of a memory device according to an embodiment of the present disclosure.

FIG. 49 is a flowchart of a manufacturing method of a memory device according to further another embodiment of the present disclosure.

FIG. 50 is a schematic view of structures at a specific operation of a manufacturing method of a memory device according to further another embodiment of the present disclosure.

FIG. 51 is a schematic view of structure at another specific operation of a manufacturing method of a memory block according to further another embodiment of the present disclosure.

FIG. 52 is a schematic view of structure at further another specific operation of a manufacturing method of a memory block according to further another embodiment of the present disclosure.

FIG. 53 is a schematic view of structure at further another specific operation of a manufacturing method of a memory block according to further another embodiment of the present disclosure.

FIG. 54 is a schematic view of structure at further another specific operation of a manufacturing method of a memory block according to further another embodiment of the present disclosure.

FIG. 55 is a schematic view of structure at further another specific operation of a manufacturing method of a memory block according to further another embodiment of the present disclosure.

FIG. 56 is a schematic view of structure at further another specific operation of a manufacturing method of a memory block according to further another embodiment of the present disclosure.

FIG. 57 is a schematic view of structure at further another specific operation of a manufacturing method of a memory block according to further another embodiment of the present disclosure.

FIG. 58 is a schematic view of structure at further another specific operation of a manufacturing method of a memory block according to further another embodiment of the present disclosure.

FIG. 59 is a schematic view of structure at further another specific operation of a manufacturing method of a memory block according to further another embodiment of the present disclosure.

FIG. 60 is a schematic view of structures at further another specific operation of a manufacturing method of a memory device according to further another embodiment of the present disclosure.

FIG. 61 is a schematic view of structure at further another specific operation of a manufacturing method of a memory block according to further another embodiment of the present disclosure.

FIG. 62 is a schematic view of structure at further another specific operation of a manufacturing method of a memory block according to further another embodiment of the present disclosure.

FIG. 63 is a schematic view of structure at further another specific operation of a manufacturing method of a memory block according to further another embodiment of the present disclosure.

FIG. 64 is a schematic view of structure at further another specific operation of a manufacturing method of a memory block according to further another embodiment of the present disclosure.

FIG. 65 is a schematic view of structure at further another specific operation of a manufacturing method of a memory block according to further another embodiment of the present disclosure.

FIG. 66 is a schematic view of structure at further another specific operation of a manufacturing method of a memory block according to further another embodiment of the present disclosure.

FIG. 67 is a schematic view of structure at further another specific operation of a manufacturing method of a memory block according to further another embodiment of the present disclosure.

FIG. 68 is a schematic view of structure at further another specific operation of a manufacturing method of a memory block according to further another embodiment of the present disclosure.

FIG. 69 is a schematic view of structure at further another specific operation of a manufacturing method of a memory block according to further another embodiment of the present disclosure.

FIG. 70 is a schematic view of structures at further another specific operation of a manufacturing method of a memory device according to further another embodiment of the present disclosure.

FIG. 71 is a schematic view of structure at further another specific operation of a manufacturing method of a memory block according to further another embodiment of the present disclosure.

FIG. 72 is a schematic view of structure at further another specific operation of a manufacturing method of a memory block according to further another embodiment of the present disclosure.

FIG. 73 is a schematic view of structure at further another specific operation of a manufacturing method of a memory block according to further another embodiment of the present disclosure.

FIG. 74 is a schematic view of structure at further another specific operation of a manufacturing method of a memory block according to further another embodiment of the present disclosure.

FIG. 75 is a schematic view of structure at further another specific operation of a manufacturing method of a memory device according to further another embodiment of the present disclosure.

### Reference Numerals

memory array 1; memory subarray layer 1a; drain region semiconductor strip 11; bit line connection line 11a; channel semiconductor strip 12; well region connection line 12a; common well region line 12b; common well region lead line 12d; source region semiconductor strip 13; source connection line 13a; common source line 13b; common source lead line 13d; interlayer isolation strip 14a; second single-crystal sacrificial semiconductor layer 14; insulating isolation layer 14′; body structure 15a; protrusion 15b; support post 16; column of semiconductor strip structures 1b; gate strip 2; isolation wall 3; isolation wall hole 31; word-line hole 4; storage structure 5; first dielectric layer 51; charge storage layer 52; second dielectric layer 53; floating gate 54; first insulating dielectric layer 56; odd word-line 8a; even word-line 8b; word-line connection line 7; drain region portion 11′; channel portion 12′; source region portion 13′; gate portion 2′; storage structure portion 5′; substrate 81; first single-crystal sacrificial semiconductor layer 82; first hard mask layer 83; word-line opening 831; first recess 84; second recess 84′; third recess 84a; first insulating dielectric 85; first insulating dielectric layer 85a; second insulating dielectric layer 85b; second insulating dielectric 86; drain region semiconductor layer 11c; channel semiconductor layer 12c; source region semiconductor layer 13c; channel connection post 91; first insulating material 92; channel connection wall 93; connection layer 94; second insulating material 95; first-type connection hole 96; isolation recess 97; second-type connection hole 98; first conductive medium 99.

### DETAILED DESCRIPTION

The technical solutions in embodiments of the present disclosure will be clearly and completely described below in conjunction with the accompanying drawings in the embodiments of the present disclosure, and it is obvious that the described embodiments are only a part of the embodiments of the present disclosure, but not all of them. Based on the embodiments of the present disclosure, all other embodiments obtained by those skilled in the art without creative labor fall within the protection scope of the present disclosure.

The terms “first”, “second”, and “third” in the present disclosure are intended for descriptive purposes only and are not to be construed as indicating or implying relative importance or implicitly indicating the number of indicated technical features. Therefore, a feature defined with “first”, “second”, or “third” may explicitly or implicitly include at least one such feature. In the description of the present disclosure, the terms “a plurality of” or “multiple” means at least two, e.g., two, three, etc., unless otherwise expressly and specifically limited. All directional indications (e.g., up, down, left, right, forward, backward . . . ) in the present disclosure are intended only to explain relative position relationships, movements, etc., between components in a particular posture (as shown in the accompanying drawings). If the particular posture is changed, the directional indications are changed accordingly. In addition, the terms “include” and “have”, and any variations thereof are intended to cover non-exclusive inclusion. For example, a process, method, system, product, or device including a series of steps or units is not limited to the listed steps or units, but optionally further includes steps or units not listed, or optionally further includes other steps or units inherent to the process, method, product, or device.

References herein to the term “embodiment” mean that particular features, structures, or characteristics described in conjunction with an embodiment may be included in at least one embodiment of the present disclosure. The presence of the phrase at various positions in the specification does not necessarily mean the same embodiment, nor is it a separate or alternative embodiment that is mutually exclusive with other embodiments. It is understood, both explicitly and implicitly, by those skilled in the art that the embodiments described herein may be combined with other embodiments.

The present disclosure is described in detail below in conjunction with the accompanying drawings and embodiments.

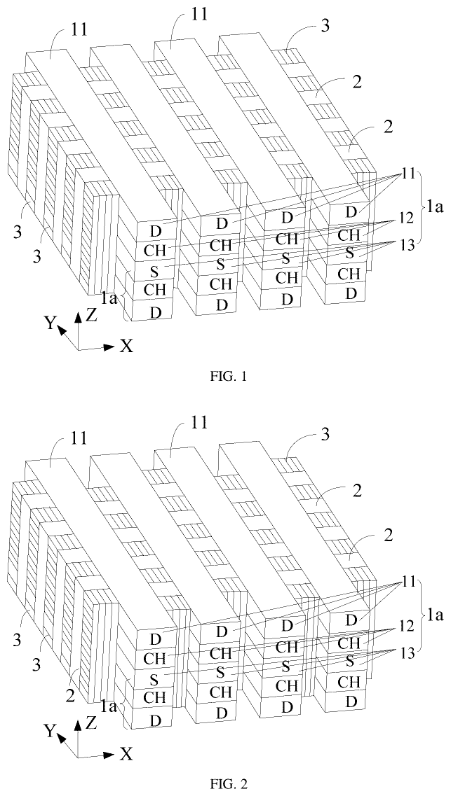

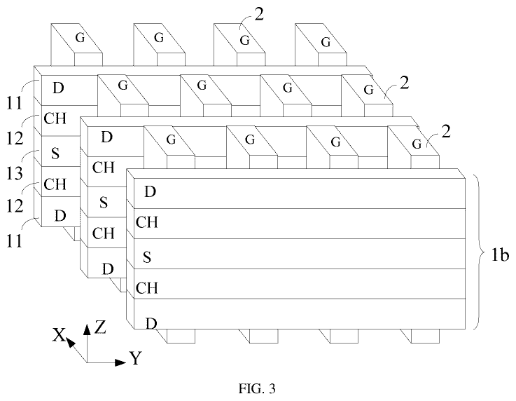

Embodiments of the present disclosure provide a memory device, and the memory device may specifically be a non-volatile memory device. As shown in FIG. 1 to FIG. 3, FIG. 1 to FIG. 3 are perspective structural schematic views of a memory array according to an embodiment of the present disclosure. The memory device may include substrate 81 and one or more memory arrays 1 arranged on the substrate 81. The memory array 1 includes a structure in which multiple memory cells are arranged in a three-dimensional array; and the memory device may include, in addition to the memory array 1 formed by the multiple memory cell arrays, other components, such as various types of wires (or connection lines), etc., enabling the memory device to implement various memory operations.

An example is given with a number of the memory arrays 1 being one. The memory array 1 includes multiple memory cells distributed in a three-dimensional array. As shown in FIG. 1, the memory array 1 includes multiple memory subarray layers 1a stacked sequentially along a height direction Z. Each memory subarray layer 1a includes a drain region semiconductor layer, a channel semiconductor layer, and a source region semiconductor layer stacked along the height direction Z. The drain region semiconductor layer, the channel semiconductor layer, and the source region semiconductor layer may each be a single-crystal semiconductor layer grown by epitaxy. The height direction Z is a direction perpendicular to the substrate 81. The sequential stacking indicates a sequential arrangement on the substrate from bottom to top, and the stacking represents an arrangement and does not express or imply a structure or a top-to-bottom relationship of the layers.

In each memory subarray layer 1a, the drain region semiconductor layer (D) includes multiple drain region semiconductor strips 11 spaced along a row direction X, each drain region semiconductor strip 11 extending along a column direction Y. The channel semiconductor layer (CH) includes multiple channel semiconductor strips 12 spaced along the row direction X, each channel semiconductor strip 12 extending along the column direction Y. The source region semiconductor layer (S) includes multiple source region semiconductor strips 13 spaced along the row direction X, each source region semiconductor strip 13 extending along the column direction Y. Each drain region semiconductor strip 11, channel semiconductor strip 12, and source region semiconductor strip 13 is a single-crystal semiconductor strip, respectively. It is understood by those skilled in the art that each drain region semiconductor strip 11, channel semiconductor strip 12, and source region semiconductor strip 13 may be a single-crystal semiconductor strip formed by processing the drain region semiconductor layer, channel semiconductor layer, and source region semiconductor layer formed by epitaxy generation, respectively. As shown in FIG. 1 to FIG. 3, multiple gate strips 2 (G) are arranged on each side of each column of drain region semiconductor strips 11, channel semiconductor strips 12, and source region semiconductor strips 13, respectively. The multiple gate strips 2 distributed on a side of each column of drain region semiconductor strips 11, channel semiconductor strips 12, and source region semiconductor strips 13 are spaced along the column direction Y, and each gate strip 2 extends along the height direction Z. In this way, corresponding parts of the multiple drain region semiconductor strips 11, channel semiconductor strips 12, and source region semiconductor strips 13 in the same column in the multiple memory subarray layers la share the same gate strip 2.

As shown in FIG. 2, among the multiple gate strips 2, each gate strip 2 in the same column and a corresponding gate strip 2 are staggered from each other in the column direction Y, and the corresponding gate strip 2 is in a column adjacent to the column where the gate strip 2 is located and corresponds the gate strip 2 in the row direction X. For example, each gate strip 2 in a first column and each gate strip 2 in a second column are staggered from each other in the column direction Y. Of course, as shown in FIG. 1, each gate strip 2 in the same column and the corresponding gate strip 2 may be aligned with each other in the column direction Y, and the corresponding gate strip 2 is in a column adjacent to the column where the gate strip 2 is located and corresponds to the gate strip 2 in the row direction X. The staggered arrangement may reduce the influence on an electric field between corresponding two gate strips 2 in two adjacent columns.

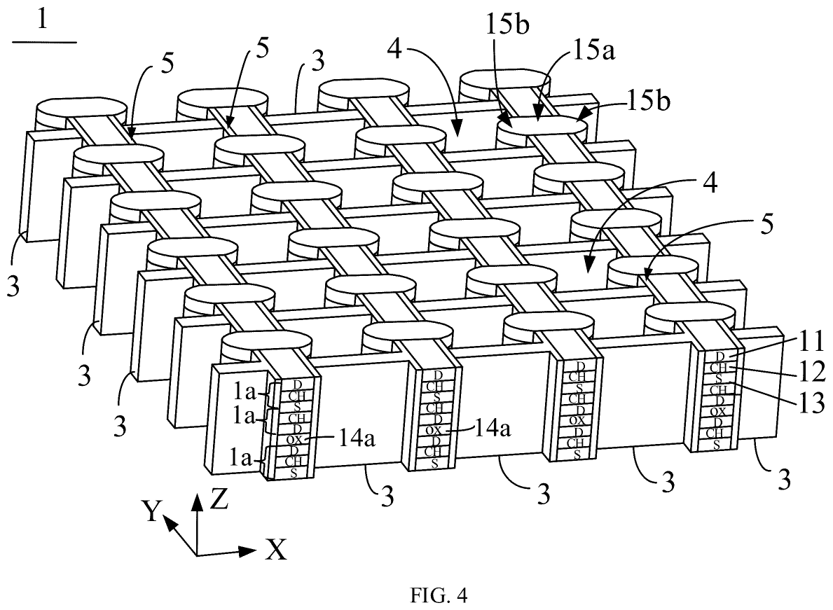

In the height direction Z, a projection of at least a part of each gate strip 2 coincides with a projection of a part of a corresponding channel semiconductor strip 12 in each memory subarray layer la on a projection plane. The projection plane is a plane defined by the height direction Z and the column direction Y, i.e., the projection plane extends along the height direction Z and the column direction Y. As shown in FIG. 1 to FIG. 3, for the purpose of description, it is defined that a column of drain region semiconductor strip 11, channel semiconductor strip 12, and source region semiconductor strip 13 in each memory subarray layer la constitutes a semiconductor strip structure; two adjacent memory subarray layers la may share a common source, i.e., the two adjacent memory subarray layers la share the same source region semiconductor layer (S). Therefore, two semiconductor strip structures corresponding to the two adjacent memory subarray layers la share the same source region semiconductor strip 13. Of course, it is understood by those skilled in the art that the two adjacent memory subarray layers 1a may be arranged with a non-common source design, i.e., each memory subarray layer 1a has an independent source region semiconductor layer. In this way, the two semiconductor strip structures 1b corresponding to the two adjacent memory subarray layers 1a each has its own independent source region semiconductor strip 13. In the multiple memory subarray layers 1a, the drain region semiconductor strips 11, channel semiconductor strips 12, and source region semiconductor strips 13 in the same column constitute a column of semiconductor strip structures 1b, i.e., a stacked structure 1b. The column of semiconductor strip structures 1b includes multiple semiconductor strip structures, and the number of the semiconductor strip structures in the column of semiconductor strip structures 1b is the same as the number of the memory subarray layers 1a. As shown in FIG. 1 to FIG. 3, each column of semiconductor strip structures 1b includes two semiconductor strip structures, but those skilled in the art can understand that a column of semiconductor strip structures 1b may include multiple stacked semiconductor strips. As shown in FIG. 4, which is a sketch of a perspective structure of a memory array according to another embodiment of the present disclosure, where a column of semiconductor strip structures 1b includes three semiconductor strip structures.

In other words, it is understood by those skilled in the art that the memory array 1 includes multiple stacked structures 1b distributed along the row direction X, each stacked structure 1b extending along the column direction Y. Each stacked structure 1b includes drain region semiconductor strips 11, channel semiconductor strips 12, and source region semiconductor strips 13 stacked along the height direction. Each drain region semiconductor strip 11, channel semiconductor strip 12, and source region semiconductor strip 13 extends along the column direction Y. Multiple gate strips 2 spaced along the column direction Y are arranged on each of two sides of each stacked structure 1b, and each gate strip 2 extends along the height direction Z.

A projection of a part of each column of semiconductor strip structures 1b coincides with a projection of a corresponding part of a corresponding gate strip 2 on the projection plane. In particular, a projection of a part of the channel semiconductor strip 12 in each column of semiconductor strip structures 1b coincides with a projection of a part of a corresponding gate strip 2 on the projection plane. In this way, a part of the gate strip 2, a corresponding part of the channel semiconductor strip 12, a part of the drain region semiconductor strip 11 adjacent to the corresponding part of the channel semiconductor strip 12, and a part of the source region semiconductor strip 13 adjacent to the corresponding part of the channel semiconductor strip 12are configured to form a memory cell. For example, as shown in FIG. 1 to FIG. 3, for the gate strip 2 of the first column along the row direction X and the first row along the column direction Y, a projection of a part of the gate strip 2 coincides with a projection of a corresponding part of the channel semiconductor strip 12 of the first column of the drain region semiconductor strip 11, the channel semiconductor strip 12, and the source region semiconductor strip 13 (a column of semiconductor strip structures 1b with a D/CH/S structure) of the first memory subarray layer 1a in the height direction Z. That is, the part of the gate strip 2 of the first column and the first row, the corresponding part of the first column of the channel semiconductor strip 12 of the first memory subarray layer 1a in the height direction Z, and a part of the drain region semiconductor 11 and a part of the source region semiconductor 13, that are matched with the corresponding part of the first column of the channel semiconductor strip 12 of the first memory subarray layer 1a in the height direction Z, are configured to form a memory cell.

It will be understood by those skilled in the art that, a channel is required to be formed in a semiconductor region between the semiconductor drain region and the semiconductor source region; and the gate is arranged on a side of the semiconductor region between the semiconductor drain region and the semiconductor source region for constituting a semiconductor device. Therefore, as shown in FIG. 1 to FIG. 3, the part of each gate strip 2 whose projection overlaps with the projection of a channel semiconductor strip 12 in an adjacent stacked structure 1b on the above projection plane is configured as a gate, i.e., a control gate of the corresponding memory cell; the part of the channel semiconductor strip 12 whose projection overlaps with the projection of the gate strip 2 on the above projection plane, i.e., the corresponding part of the channel semiconductor strip 12, is configured as the channel region (well region) for forming a channel therein; and the drain region semiconductor strip 11 and the source region semiconductor strip 13 adjacent to the channel semiconductor strip 12 each has a part arranged just above or below the corresponding part of the channel semiconductor strip 12, i.e., the parts of the drain region semiconductor strip 11 and the source region semiconductor strip 13 exactly match the corresponding part of the channel semiconductor strip 12 as the semiconductor drain region and the semiconductor source region. Therefore, the parts of the drain region semiconductor strip 11 and the source region semiconductor strip 13, the corresponding part of the channel semiconductor strip 12 sandwiched between the parts of the drain region semiconductor strip 11 and the source region semiconductor strip 13,cooperating with the part of the gate strip 2 as the control gate, are configured to form a memory cell.

Therefore, as shown in FIG. 1 to FIG. 3, the memory array 1 of the present disclosure is formed with multiple memory cells arranged in an array, and the multiple memory cells is comprised by the drain region semiconductor strips 11, the channel semiconductor strips 12, the source region semiconductor strips 13, and the gate strips 2. In particular, the memory array 1 of the present disclosure includes multiple memory subarray layers la stacked sequentially along the height direction Z. Each memory subarray layer 1a includes a layer of drain region semiconductor strips 11, a layer of channel semiconductor strips 12, a layer of source region semiconductor strips 13, and parts of gate strips 2 matching the above layers, such that each memory subarray layer 1a includes a layer of array-arranged memory cells along the height direction Z, and the stacked multiple memory subarray layers la constitute multiple layers of memory cells arrayed along the height direction Z.

In the present disclosure, each drain region semiconductor strip 11 is a semiconductor strip of a first doping type, such as an N-type doped semiconductor strip. In some embodiments, each drain region semiconductor strip 11 serves as a bit line (BL) of a memory device.

Each channel semiconductor strip 12 is a semiconductor strip of a second doping type, such as a P-type doped semiconductor strip. In some embodiments, each channel semiconductor strip 12 serves as a well region of a memory cell.

Each source region semiconductor strip 13 is also a semiconductor strip of the first doping type, such as an N-type doped semiconductor strip. In some embodiments, each source region semiconductor strip 13 serves as a source line (SL) of the memory device.

Of course, it is understood by those skilled in the art that in other types of memory devices, each drain region semiconductor strip and each source region semiconductor strip may also be a P-type doped semiconductor strip, while each channel semiconductor strip 12 is an N-type doped semiconductor strip. The present disclosure does not limit thereto.

Referring further to FIG. 1 to FIG. 3, in the height direction Z, two adjacent memory subarray layers 1a include a drain region semiconductor layer, a channel semiconductor layer, a source region semiconductor layer, a channel semiconductor layer, and a drain region semiconductor layer stacked in sequence to share the common source region semiconductor layer. As shown in FIG. 1 to FIG. 3, the common source region semiconductor strip 13 is arranged between two adjacent channel semiconductor strips 12 in the height direction Z in the same column, and two drain region semiconductor strips 11 are arranged on two sides of the two adjacent channel semiconductor strips 12. That is, in the height direction Z, the same column of semiconductor strip structures 1b of two adjacent memory subarray layers 1a includes the drain region semiconductor strip 11, the channel semiconductor strip 12, the source region semiconductor strip 13, the channel semiconductor strip 12, and the drain region semiconductor strip 11 stacked in sequence, thereby forming two column of semiconductor strip structures 1b which share the common source region semiconductor strip 13. In this way, the storage density of the memory device may be further increased while reducing cost and process.

As shown in FIG. 4, the memory array 1 includes multiple memory subarray layers 1a stacked sequentially along the height direction Z. Each memory subarray layer 1a includes a drain region semiconductor layer, a channel semiconductor layer, and a source region semiconductor layer stacked along the height direction Z.

In each memory subarray layer 1a, the drain region semiconductor layer, the channel semiconductor layer, and the source region semiconductor layer include multiple drain region semiconductor strips 11, multiple channel semiconductor strips 12, and multiple source region semiconductor strips 13, respectively, spaced along the row direction X.

Two adjacent memory subarray layers la include a drain region semiconductor layer, a channel semiconductor layer, a source region semiconductor layer, a channel semiconductor layer, and a drain region semiconductor layer sequentially stacked to share the same source region semiconductor layer.

An interlayer isolation layer is arranged between every two memory subarray layers 1a to isolate from the other two memory subarray layers 1a. That is, an interlayer isolation layer is arranged between each two consecutive memory subarray layers 1a and another two consecutive memory subarray layers 1a, the another two consecutive memory subarray layers 1a being adjacent to the each two consecutive memory subarray layers 1a. For example, in the height direction Z, an interlayer isolation layer is arranged between the first/second memory subarray layers 1a and the third/fourth memory subarray layers 1a; another interlayer isolation layer is arranged between the third/fourth memory subarray layer 1a and the fifth/sixth memory subarray layer 1a, and so on. It is understood that the one interlayer isolation layer is disposed between the second memory subarray layer 1a and the third memory subarray layer 1a; and the other interlayer isolation layer is disposed between the fourth memory subarray layer 1a and the fifth memory subarray layer 1a.

Specifically, as shown in FIG. 4, one interlayer isolation strip 14a is arranged between every two adjacent columns of semiconductor strip structures 1b in the same column of semiconductor strip structures 1b in the height direction Z. Similarly, an interlayer isolation strip 14a is arranged between every two adjacent columns of semiconductor strip structures 1b in another column of semiconductor strip structures 1b. It is understood by those skilled in the art that multiple interlayer isolation strips 14a in the same horizontal plane constitute an interlayer isolation layer to isolate from the semiconductor strip structures 1b in the other two memory subarray layers 1a.

In other words, in the present disclosure, each stacked structure 1b′ may include multiple stacked substructures, and each stacked substructure includes a drain region semiconductor strip 11, a channel semiconductor strip 12, a source region semiconductor strip 13, a channel semiconductor strip 12, and a drain region semiconductor strip 11 stacked sequentially along the height direction Z, thereby sharing the same source region semiconductor strip 13. In the stacked structure 1b′, an interlayer isolation strip 14a is arranged between two adjacent stacked substructures to isolate them from each other. That is, in two adjacent memory subarray layers 1a, the drain region semiconductor strip 11, channel semiconductor strip 12, source region semiconductor strip 13, channel semiconductor strip 12, and drain region semiconductor strip 11 in the same column form a stacked substructure, such that two adjacent memory subarray layers 1a share a common source region semiconductor strip 13.

Referring further to FIG. 4 or FIG. 1, multiple isolation walls 3 are distributed in the memory array 1, and the multiple isolation walls 3 are arranged in a matrix in the row direction X and the column direction Y. As shown in FIG. 1, multiple isolation walls 3 distributed along the column direction Y are arranged on each of two sides of each column of semiconductor strip structures 1b. Each isolation wall 3 extends along the height direction Z and the row direction X to separate at least parts of two adjacent columns of drain region semiconductor strips 11, channel semiconductor strips 12, and source region semiconductor strips 13. That is, the multiple isolation walls 3 distributed along the column direction Y are arranged on each of the two sides of each stacked structure 1b′ to separate at least parts of the two adjacent columns of stacked structures 1b′. In some embodiments, particularly during the manufacturing process of the memory device, the isolation walls 3 may further serve as support structures that may support two adjacent columns of the stacked structures 1b′ during and/or after the manufacturing process. In addition, a part of each side of each stacked structure 1b′ may be arranged with support posts (not shown and described in detail below), respectively, to support the two adjacent columns of the stacked structures 1b′ during and/or after the manufacturing process of the memory array 1.

A region between two adjacent isolation walls 3 in the same column in the column direction Y is configured to define a word-line hole 4. That is, any two adjacent isolation walls 3 in the same column, cooperating with two columns of semiconductor strip structures 1b (i.e., stacked structures 1b′) on both sides thereof, may define multiple regions for the word-line holes 4, and these regions may be processed such that corresponding word-line holes 4 may be defined. That is, the multiple columns of drain region semiconductor strips 11, channel semiconductor strips 12, and source region semiconductor strips 13 extending along the column direction Y pass through the multiple rows of isolation walls 3 extending along the row direction X, to define the multiple word-line holes 4 cooperating with the multiple isolation walls 3. Each word-line hole 4 extends along the height direction Z.

Each word-line hole 4 is configured to fill a gate material to form a corresponding gate strip 2. That is, a gate strip 2 is filled between two adjacent isolation walls 3 in the same column direction Y.

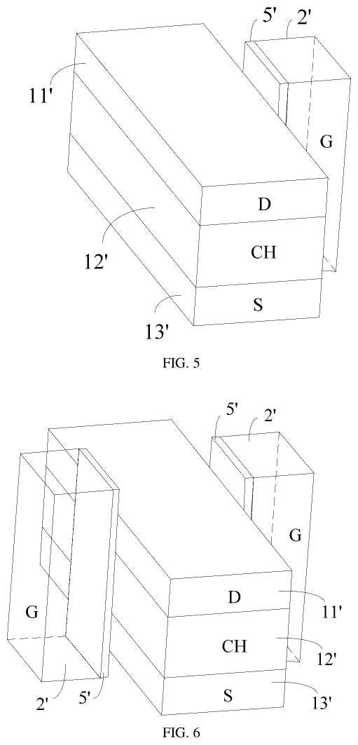

As shown in FIG. 5, FIG. 5 is a perspective structural schematic view of a memory cell according to an embodiment of the present disclosure. As shown in FIG. 5, the memory cell includes a drain region portion 11′, a channel portion 12′, a source region portion 13′, and a gate portion 2′. The drain region portion 11′, the channel portion 12′, and the source region portion 13′ are stacked along the height direction Z, respectively. The channel portion 12′ is disposed between the drain region portion 11′ and the source region portion 13′. The gate portion 2′ is disposed on a side of the drain region portion 11′, the channel portion 12′, and the source region portion 13′. The drain region portion 11′, the channel portion 12′, and the source region portion 13′ are each a single-crystal semiconductor.

In addition, a projection of the gate portion 2′ at least partially coincides with a projection of the channel portion 12′on a projection plane in the height direction Z. The projection plane is located on a side of the drain region portion 11′, the channel portion 12′, and the source region portion 13′, and extends along the height direction Z and the column direction Y.

As shown in FIG. 5, it is easily understood by those skilled in the art that the drain region portion 11′ is a part of one of the drain region semiconductor strips 11 shown in FIG. 1 to FIG. 4, the channel portion 12′ is a part of one of the channel semiconductor strips 12 shown in FIG. 1 to FIG. 4, the source region portion 13′ is a part of one of the source region semiconductor strips shown in FIG. 1 to FIG. 4, and the gate portion 2′ is a part of one of the gate strips 2 shown in FIG. 1 to FIG. 4. Therefore, in the height direction Z, the multiple memory subarray layers la includes multiple memory cells.

In addition, as shown in FIG. 5, a storage structure portion 5′ is arranged between the gate portion 2′ and the drain region portion 11′, the channel portion 12′, and the source region portion 13′. The storage structure portion 5′may be configured to store electric charges; the gate portion 2′, the drain region portion 11′, the channel portion 12′, the source region portion 13′, and the storage structure portion 5′ sandwiched between the gate portion 2′ and the channel portion 12′, constitutes a memory cell. The memory cell may indicate logical data 1 or logical data 0 by a state of storing or not storing electric charges in the storage structure portion 5′, thereby enabling storage of data. The storage structure portion 5′ may include a charge trapping storage structure portion, a floating gate storage structure portion, or other types of capacitive storage structure portions.

Therefore, it will be understood by those skilled in the art that in the memory array 1 shown in FIG. 1 to FIG. 4, a storage structure 5 is also arranged between the gate strip 2 and the drain region semiconductor strip 11, the channel semiconductor strip 12, and the source region semiconductor strip 13, such that each memory cell can store electric charges by its corresponding storage structure portion 5′.

In addition, it should be noted that for the convenience of the accompanying drawings showing the storage structure portion 5′, the drain region portion 11′, the channel portion 12′, the source region portion 13′, the gate portion 2′, and the storage structure portion 5 shown in FIG. 5′ are shown for illustrative purposes only and do not represent actual dimensions or proportions.

It will be understood by those skilled in the art that, as above, the part of the gate strip 2 whose projection coincides with the projection of the adjacent channel semiconductor strip 12 on the above projection plane is configured as the control gate of the memory cell, such that the part of the gate strip 2 as the gate portion 2′ is the part whose projection coincides with the projection of the channel semiconductor strip 12 on the projection plane; the part of the channel semiconductor strip 12 whose projection coincides with the projection of the gate strip 2 on the above projection plane is the corresponding part of the channel semiconductor strip 12 as the well region, such that the part of the channel semiconductor strip 12 as the channel portion 12′ is the part of the channel semiconductor strip 12 whose projection coincides with the projection of the gate strip 2 on the projection plane; the parts of the drain region semiconductor strip 11 and the source region semiconductor strip 13 as the drain region portion 11′ and the source region portion 13′, i.e., the part of the drain region semiconductor strip 11 or the source region semiconductor strip 13 arranged above or below the channel portion 12′, are configured as the semiconductor drain region and the semiconductor source region, respectively.

Similarly, the storage structure portion 5′ is a part of the storage structure 5 disposed between the channel portion 12′ and the gate portion 2′.

Referring further to FIG. 1 to FIG. 4, a gate strip 2 is flanked by two adjacent columns of drain region semiconductor strips 11, channel semiconductor strips 12, and source region semiconductor strips 13. Therefore, these two adjacent columns of drain region semiconductor strips 11, channel semiconductor strips 12, and source region semiconductor strips 13 share the same gate strip 2. That is, for a gate strip 2, in a memory subarray layer la, the gate strip cooperates with corresponding parts of the drain region semiconductor strip 11, channel semiconductor strip 12, and source region semiconductor strip 13 on the left side of the gate strip 2 to form a memory cell, and cooperates with corresponding parts of the drain region semiconductor strip 11, channel semiconductor strip 12, and source region semiconductor strip 13 on the right side of the gate strip 2 to form another memory cell. In other words, in the same row, two gate strips 2 are arranged on the left and right sides of one column of drain region semiconductor strip 11, channel semiconductor strip 12, and source region semiconductor strip 13 in one memory subarray layer la. In this way, the one column of drain region semiconductor strip 11, channel semiconductor strip 12, and source region semiconductor strip 13 cooperates with a part of the gate strip 2 on the left side to constitute a memory cell, and cooperates with a part of the gate strip 2 on the right side to constitute another memory cell. That is, in the same row, a column of drain region semiconductor strip 11, channel semiconductor strip 12, and source region semiconductor strip 13 in one memory subarray layer la is shared by two gate strips 2 on its left and right sides.

Specifically, further referring to FIG. 6, FIG. 6 is a perspective schematic view of a structure in which of two memory cells share the same column of drain region semiconductor strip, channel semiconductor strip, and source region semiconductor strip. As shown in FIG. 6, the source region portion 13′, channel portion 12′, and drain region portion 11′ stacked along the height direction Z′ cooperate with the gate portion 2′ on the left side and the storage structure portion 5′ between them to constitute a memory cell; similarly, the drain region portion 11′, the channel portion 12′, and the source region portion 13′cooperate with the gate portion 2′ on the right side and the storage structure portion 5′ between them to constitute another memory cell. In this way, both the two memory cells share the same drain region portion 11′, channel portion 12′, and the source region portion 13′.

For ease of understanding, it may be considered that the drain region portion 11′, the channel portion 12′, and the source region portion 13′cooperate with the gate portion 2′ on the left side and the storage structure portion 5′ between them to form a memory cell (bit); the drain region portion 11′, the channel portion 12′, and the source region portion 13′ cooperate with the gate portion 2′ on the right side and the storage structure portion 5′ between them to form another memory cell (bit).

Therefore, returning to FIG. 1 to FIG. 4, it will be understood by those skilled in the art that a storage structure 5 is first arranged on each of the left and right sides in each word-line hole 4, and the gate material is filled in the word-line hole 4 to form the gate strip 2. That is, the two adjacent columns of drain region semiconductor strips 11, channel semiconductor strips 12, and source region semiconductor strips 13 in conjunction with the storage structures 5 share the same gate strip 2.

In conjunction with FIG. 1 to FIG. 3, FIG. 5 and FIG. 6, in some embodiments, each of the above drain region semiconductor strip 11, channel semiconductor strip 12, and source region semiconductor strip 13 is a standard strip structure. That is, each drain region semiconductor strip 11, channel semiconductor strip 12, and source region semiconductor strip 13 has a standard rectangular cross-section at each position along the respective extension direction. The memory cell corresponding to the embodiments may be illustrated specifically in FIG. 5 and FIG. 6.

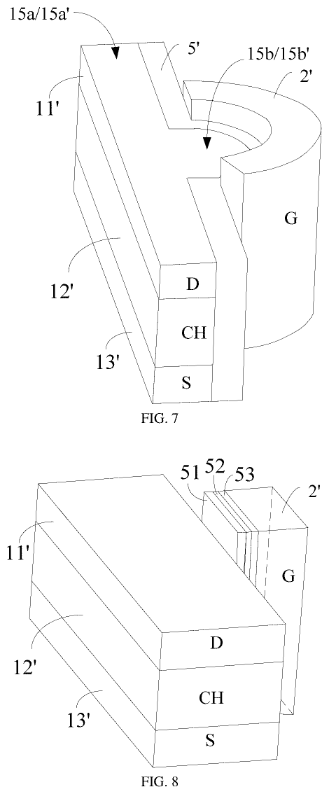

In other embodiments, in conjunction with FIG. 4 and FIG. 7, FIG. 7 is a perspective structural schematic view of a memory cell according to another embodiment of the present disclosure. Each drain region semiconductor strip 11, channel semiconductor strip 12, and source region semiconductor strip 13 includes a body structure 15a and multiple protrusions 15b, respectively. The body structure 15a extends along the column direction Y and is in the shape of a strip. The multiple protrusions 15b are distributed on both sides of the body structure in two columns, and each column includes multiple protrusions 15b spaced apart, each protrusion 15b extending from the body structure 15a in the row direction X toward a corresponding gate strip 2 (word-line hole 4) in a direction deviating from the body structure 15a. In other words, in each column of drain region semiconductor strips 11, channel semiconductor strips 12, and source region semiconductor strips 13, two columns of protrusions 15b extend from the strip-shaped body structure 15a toward the gate strips 2 (word-line holes 4) on each side. Therefore, it is understood by those skilled in the art that a surface of the storage structure 5 formed in the word-line hole 4 and a surface of the gate strip 2 near the drain region semiconductor strip 11, the channel semiconductor strip 12, and the source region semiconductor strip 13 are curved concave surfaces.

As shown in FIG. 7, for each memory cell, the drain region portion 11′, the channel portion 12′, and the source region portion 13′include a body portion 15a′ and a protrusion portion 15b′, and each of the storage structure portion 5′ and the gate portion 2′includes a concave surface corresponding to the protrusion portion 15b′ to wrap a surface of the protrusion 15b away from the body structure 15a.

In the present disclosure, by making each drain region semiconductor strip 11, channel semiconductor strip 12, and source region semiconductor strip 13 include multiple protrusions 15b that are raised toward the two sides, it is possible to increase the surface area of each drain region semiconductor strip 11, channel semiconductor strip 12, and source region semiconductor strip 13, thereby increasing the area of a corresponding region of the channel portion 12′ and the gate portion 2′ in each memory cell, thereby enhancing the performance of the memory device.

Specifically, the convex surface of the protrusion 15b away from the body structure 15a may be an arc or other form of convex surface, where the arc may include a columnar semicircular surface. The protrusions 15b of each column of drain region semiconductor strip 11, channel semiconductor strip 12, and source region semiconductor strip 13 form a columnar semicircle. The gate strip 2 corresponding to the protrusions 15b is arranged with a concave surface toward the drain region semiconductor strip 11, the channel semiconductor strip 12, and the source region semiconductor strip 13, and the concave surface is a curved surface corresponding to the convex surface of the protrusions 15b to ensure that the gate strip 2 matches the channel semiconductor strip 12 at the corresponding position.

In some embodiments, as shown in FIG. 4, the storage structure 5 extends inside the word-line hole 4 in the height direction Z and is arranged between the gate strip 2 and the adjacent drain region semiconductor strip 11, the channel semiconductor strip 12, and the source region semiconductor strip 13, such that the storage structures 5 may form the multiple memory cells together with the parts of the drain region semiconductor strips 11, the channel semiconductor strips 12, and the source region semiconductor strips 13 at corresponding positions. In the present disclosure, the storage structure 5 may be a charge trapping storage structure, a floating gate storage structure, or other types of capacitive dielectric structures.

As shown in FIG. 8, FIG. 8 is a perspective structural schematic view of a memory cell according to further another embodiment of the present disclosure. In the embodiments, the storage structure 5 is a charge trapping storage structure. As shown in FIG. 8, the storage structure portion 5′ of the memory cell includes a first dielectric portion 51, a charge storage portion 52, and a second dielectric portion 53. The first dielectric portion 51 is disposed between the charge storage portion 52 and the stacked drain region portion 11′, the channel portion 12′, and the source region portion 13′; the charge storage portion 52 is disposed between the first dielectric portion 51 and the second dielectric portion 53; and the second dielectric portion 53 is disposed between the charge storage portion 52 and the gate portion 2′. The charge storage portion 52 is configured to store electrical charges to enable the memory cell to store data.

Therefore, with reference to FIG. 8, it will be understood by those skilled in the art that the storage structure 5 in the memory array shown in FIG. 1 to FIG. 4 of the present disclosure includes a first dielectric layer, a charge storage layer, and a second dielectric layer, the first dielectric layer being disposed between the charge storage layer and the drain region semiconductor strip 11, the channel semiconductor strip 12, and the source region semiconductor strip 13, the charge storage layer being disposed between the first dielectric layer and the second dielectric layer, and the second dielectric layer being disposed between the charge storage layer and the gate strip 2.

The first dielectric layer (first dielectric portion 51) and the second dielectric layer (second dielectric portion 53) may be made of an insulating material, such as silicon oxide. The charge storage layer (charge storage portion 52) may be made of a storage material with charge trapping properties, in particular, the charge storage layer may be made of silicon nitride. Therefore, the first dielectric layer (first dielectric portion 51), the charge storage layer (charge storage portion 52), and the second dielectric layer (second dielectric portion 53) form an ONO storage structure. Specifically, reference thereto may be made to a manufacturing method involving a memory device of a charge trapping storage structure in the following embodiments.

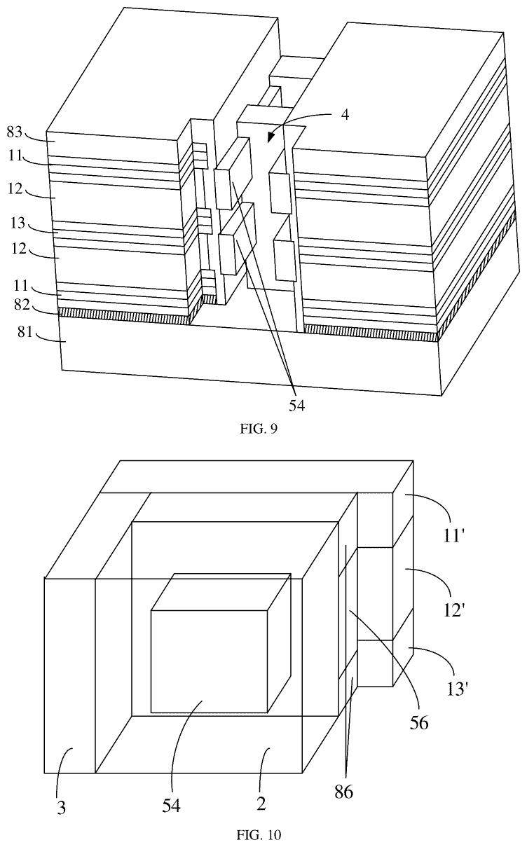

In other embodiments, referring to FIG. 9, FIG. 9 is a perspective schematic view of a partial structure of a memory device according to another embodiment of the present disclosure. In the embodiments, the storage structure 5 is a floating gate storage structure, and the floating gate storage structure extends at least partially within the word-line hole 4 in the height direction Z and is arranged between the gate strip 2 and the drain region semiconductor strip 11, the channel semiconductor strip 12, and the source region semiconductor strip 13.

Specifically, in conjunction with FIG. 9 and FIG. 10, FIG. 10 is a perspective structural schematic view of a memory cell according to further another embodiment of the present disclosure. For each memory cell, the floating gate storage structure includes multiple floating gates 54 and an insulating dielectric wrapping each floating gate 54. As shown in FIG. 9, as can be seen through the word-line hole 4, the multiple floating gates 54 are spaced along the height direction Z, and each floating gate 54 is arranged on a side of the channel semiconductor strip 12 along the row direction X and faces a corresponding part of the channel semiconductor strip 12. As shown in FIG. 10, the insulating dielectric wrapping the floating gate 54 includes a first insulating dielectric layer 56 between the channel semiconductor strip 12 and the floating gate 54 (referring also to the first insulating dielectric layer 85a shown in FIG. 41 below), and a second insulating dielectric layer covering several other faces of the floating gate 54 (not shown in FIG. 10, referring to the second insulating dielectric layer 85b shown in FIG. 41 below). That is, the insulating dielectric is present between the floating gate 54 and the corresponding part of the channel semiconductor strip 12, between two adjacent floating gates 54, and between the floating gate 54 and the gate strip 2. The insulating dielectric wraps every surface of the floating gate 54 to completely isolate the floating gate 54 from the rest of the structure.

Among them, the floating gate 54 may be made of polycrystalline silicon. The insulating dielectric may be made of an insulating material such as silicon oxide. Specifically, reference thereto may be made to a manufacturing method involving a memory device of a floating gate storage structure in the following embodiments.

In the memory cell of the charge trapping storage structure shown in FIG. 8 and FIG. 1 to FIG. 4, the storage structure 5 is adopted with a first dielectric layer (first dielectric portion 51), a charge storage layer (charge storage portion 52), and a second dielectric layer (second dielectric portion 53) to form an ONO storage structure.

The ONO storage structure is characterized by the fact that the charges injected into can be fixed near an injection point, while the floating gate storage structure (e.g., FIG. 9 to FIG. 11 is adopted with polysilicon as a floating gate) is characterized by the fact that the charges injected into can be uniformly distributed in over the entire floating gate 54. In other words, in the ONO storage structure, the charges can only move in the injection/removal direction, i.e., the stored charges can only be fixed near the injection point and cannot move arbitrarily in the charge storage layer, especially cannot move in the extension direction of the charge storage layer. Therefore, for the ONO storage structure, the charge storage layer only needs to have an insulating dielectric on its front and back side, and the charges stored in each memory cell will be fixed near the injection point of the charge storage portion 52 and will not move along the same layer of the charge storage layer to the charge storage portion 52 in another memory cell. While in the floating gate storage structure, the charge can not only move in the injection/removal direction, but also can move arbitrarily in the floating gate 54. Therefore, when the floating gate 54 is a continuous structure, the stored charges can move in the direction of extension of the floating gate 54 and thus move to the floating gate 54 in another memory cell. Therefore, for the floating gate storage structure, the floating gates 54 of each memory cell are independent, and each surface of each floating gate needs to be covered by an insulating dielectric, and need to be isolated from each other, to prevent the charges stored in the floating gates 54 in one memory cell from moving to the floating gates 54 in the other memory cells.

That is, for the memory cell and memory device of the charge trapping storage structure shown in FIG. 8 and FIG. 1 to FIG. 4, the storage structure 5 may extend from top to bottom in the word-line hole 4, and it is sufficient to arrange a first dielectric layer and a second dielectric layer on both sides of the charge storage layer, respectively.

In contrast, in the floating gate storage structure shown in FIG. 9 to FIG. 11, the floating gates 54 of each memory cell are independent, and each surface of each floating gate 54 needs to be covered by an insulating dielectric, and need to be isolated from each other, to prevent the charges stored in the floating gates 54 in one memory cell from moving to the floating gates in other memory cells.

It will be understood by those skilled in the art that some parts of the insulating dielectric (e.g., the second insulating dielectric layer 85b mentioned above) are interconnected with each other, as long as it is possible to ensure that the floating gates 54 of each memory cell are independent of each other and that the surfaces of each floating gate 54 are wrapped with the insulating dielectric. Therefore, parts of the insulating dielectric (e.g., the second insulating dielectric layer 85b mentioned above) that wraps the floating gates 54 in the word-line hole 4 may extend substantially in the height direction, thereby wrapping the floating gates 54 of each memory cell. Specifically, reference to the memory device with a floating gate storage structure may be made to a manufacturing method involving a memory device of a floating gate storage structure in the following embodiments.

In addition, it will be understood by those skilled in the art that the storage structure 5 may be adopted with other types of storage structures, such as ferroelectric, variable resistance, or other types of capacitive storage structures.

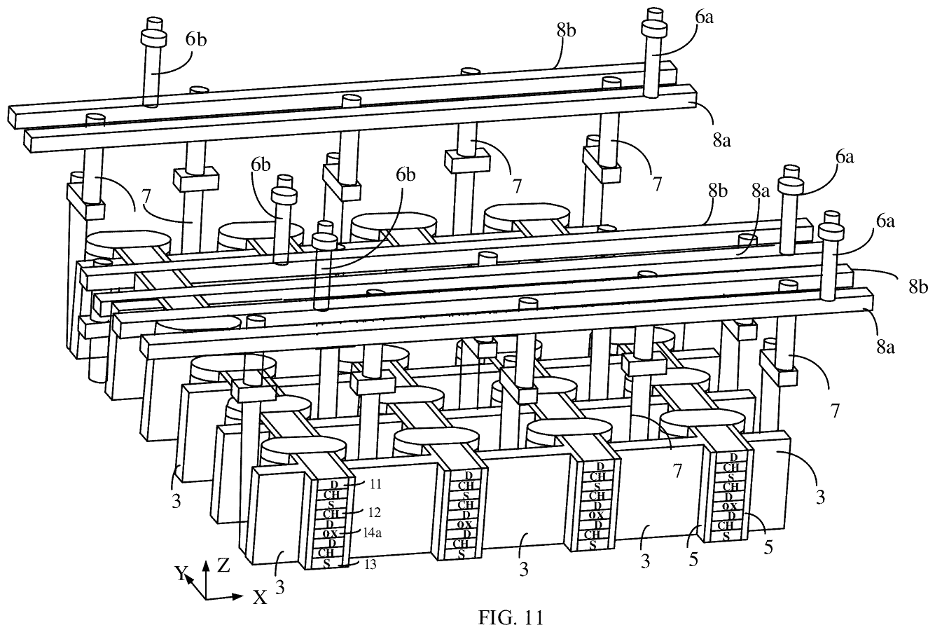

In some embodiments, referring to FIG. 11, FIG. 11 is a perspective structural schematic view of a memory device according to further another embodiment of the present disclosure. In FIG. 11, only three layers of memory subarray layers la are shown, which are merely schematic, and it will be understood by those skilled in the art that the memory device includes multiple layers of memory subarray layers 1a, with each two layers of memory subarray layers la separated from each other by an interlayer isolation layer (formed by multiple interlayer isolation strips 14a). The memory device further includes multiple word-lines (WL) and multiple word-line connection lines 7.

As above, the part of the gate strip 2 whose projection overlaps with the projection of the channel semiconductor strip 12 in an adjacent stacked structures 1b′ on the above projection plane is configured as the control gate of the corresponding memory cell. Therefore, each gate strip 2 is configured to form the control gate (CG) of multiple memory cells. As is known, the control gates of a row of memory cells need to be connected to a corresponding word-line, through which a voltage is applied to the control gates of the row of the memory cells, thereby controlling the memory cells to perform various memory operations.

In the present disclosure, as shown in FIG. 11, multiple word-lines are arranged on top of multiple memory subarray layers 1a and are spaced apart in the column direction Y, with each word-line extending along the row direction X. Each word-line is connected to multiple word-line connection lines 7. The multiple word-line connection lines 7 connected to the same word-line extend along the height direction Z, respectively, and extend to the gate strips 2 in the multiple word-line holes 4 in the same row, respectively, to be connected to the gate strips 2 in the corresponding word-line holes 4, thereby realizing the connection of the word-line to the control gates of the multiple memory cells in the same row of the multiple memory subarray layers 1a. It can be understood that the multiple word-line holes 4 and the multiple word-line connection lines 7 are arranged in a one-to-one correspondence.

Specifically, the word-line of the same row may be an individual word-line connected to the gate strip 2 in each word-line hole 4 of the same row. Of course, the word-line of the same row may include multiple different types of word-lines; the gate strips 2 in multiple word-line holes 4 of the same row may each be connected to the multiple different types of word-lines of the corresponding row. In some embodiments, as shown in FIG. 11, multiple gate strips 2 in the same row are configured to be connected to two corresponding word-lines, i.e., each row of word-lines include an odd word-line 8a and an even word-line 8b. It should be noted that one odd word-line 8a and one even word-line 8b connected to the multiple gate strips 2 of the same row in the present disclosure are defined as one row of word-line corresponding to one row of gate strips 2.

Specifically, the memory cells of the same row in the multiple memory subarray layers 1a are connected to the odd word-line 8a of the corresponding row through the odd word-line holes 4 of the same row, respectively; the others of the memory cells of the same row in the multiple memory subarray layers 1a are connected to the even word-line 8b of the corresponding row through the even word-line holes 4 of the same row, respectively. For example, a first part of the memory cells of the first row are connected to the odd word-line 8a of the first row through the first word-line hole 4, the third word-line hole 4, the fifth word-line hole 4 . . . respectively; a second part of the memory cells of the first row are connected to the even word-line 8b of the first row through the second word-line hole 4, the fourth word-line hole 4, the sixth word-line hole 4 . . . , respectively. That is, the odd word-line 8a of the word-line of the same row is connected to multiple memory cells (the first part of the memory cells) in the multiple memory subarray layers 1a corresponding to the odd word-line holes 4 of this row; the even word-line 8b of the word-line of the same row are connected to multiple memory cells (the second part of the memory cells) in the multiple memory subarray layers 1a corresponding to the even word-line holes 4 of this row.

As above, each drain region semiconductor strip 11, channel semiconductor strip 12, and source region semiconductor strip 13 has odd word-line holes 4 distributed on one side thereof and even word-line holes 4 distributed on the other side thereof. Therefore, a part of the drain region semiconductor strip 11, channel semiconductor strip 12, and source region semiconductor strip 13 in each same column in each memory subarray layer 1a may cooperate with an odd number gate strip 2 in an odd word-line hole 4 on one side thereof and a storage structure 5 arranged between the gate strip 2 and the drain region semiconductor strip 11, channel semiconductor strip 12, and source region semiconductor strip 13, to form a memory cell, i.e., a first memory cell; and may cooperated with an even word-line hole 4 on the other side thereof and a storage structure 5 arranged therebetween, to form another memory cell, i.e., a second memory cell.

In other words, the gate strip 2 filled in each word-line hole 4 may be configured to form a memory cell (bit) in conjunction with the drain region semiconductor strip 11, the channel semiconductor strip 12, the source region semiconductor strip 13, and the storage structure 5 on the left side in each memory subarray layer 1a; and may be configured to form another memory cell (bit), i.e., a second memory cell, in conjunction with the drain region semiconductor strip 11, the channel semiconductor strip 12, the source region semiconductor strip 13, and the storage structure 5 on the right side in each memory subarray layer 1a.

Therefore, for an odd word-line hole 4, the left half or right half of each drain region semiconductor strip 11, channel semiconductor strip 12, and source region semiconductor strip 13 in the same column in each memory subarray layer 1a may cooperate with the corresponding gate strip 2 in the odd word-line hole 4 to form a first memory cell. Specifically, in each memory subarray layer 1a, for each column of drain region semiconductor strip 11, channel semiconductor strip 12, and source region semiconductor strip 13; for example, word-line holes 4 on the left side of the first column of drain region semiconductor strip 11, channel semiconductor strip 12, and source region semiconductor strip 13 counting from left to right are odd word-line holes, and a part of the drain region semiconductor strip 11, channel semiconductor strip 12, and source region semiconductor strip 13 of that column cooperate with a gate strip 2 in a corresponding odd word-line hole 4 on its left side for forming a first memory cell. Word-line holes 4 on the right side of the second column of the drain region semiconductor strip 11, channel semiconductor strip 12, and source region semiconductor strip 13 counting from left to right are odd word-line holes, and a part of the drain region semiconductor strip 11, channel semiconductor strip 12, and source region semiconductor strip 13 of this column cooperate with a gate strip 2 in a corresponding odd word-line hole 4 on its right side also for constituting a first memory cell.

Similarly, for an even word-line hole 4, the other half of each drain region semiconductor strip 11, channel semiconductor strip 12, and source region semiconductor strip 13 in the same column in each memory subarray layer 1a may cooperate with a corresponding gate strip 2 in the even word-line hole 4 to form a second memory cell. Specifically, in each memory subarray layer 1a, for each column of drain region semiconductor strip 11, channel semiconductor strip 12, and source region semiconductor strip 13: for example, word-line holes 4 on the right side of the first column of drain region semiconductor strip 11, channel semiconductor strip 12, and source region semiconductor strip 13 from left to right are even word-line holes, and a part of the drain region semiconductor strip 11, channel semiconductor strip 12, and source region semiconductor strip 13 of that column cooperate with a gate strip 2 in a corresponding even word-line hole 4 on its right side for forming a second memory cell. Word-line holes 4 on the left side of the second column of the drain region semiconductor strip 11, channel semiconductor strip 12, and source region semiconductor strip 13 from left to right are even word-line holes, and a part of the drain region semiconductor strip 11, channel semiconductor strip 12, and source region semiconductor strip 13 of this column cooperate with a gate strip 2 in a corresponding even word-line hole 4 on its left side also for forming a second memory cell.

Therefore, in the present disclosure, each gate strip 2 in the memory array 1 is connected to a corresponding word-line, and the gate strips 2 in the same row are connected to the corresponding row of word-line. The gate strips 2 in the odd word-line holes 4 in the same row are connected to the odd word-lines 8a in the corresponding row of word-line, and the gate strips 2 in the even word-line holes 4 in the same row are connected to the even word-line 8b in the corresponding row of word-line. In other words, all the first memory cells of the same row in the multiple memory subarray layers 1a are each connected to an odd word-line 8a of the corresponding row through odd number gate strips 2 in odd word-line holes 4 of the same row, and all the second memory cells of the same row in the multiple memory subarray layers 1a are each connected to an even word-line 8a of the corresponding row through even number gate strips 2 in even word-line holes 4 of the same row.

Of course, in other embodiments, it may be, in the same row, every adjacent three, four or five word-line holes 4, etc. are configured as a group, then each line word-line includes three, four, five, etc. different types of word-lines, and the gate strip 2 in each word-line hole 4 in each group is connected to a different type of word-line.

Furthermore, as shown in FIG. 11, in the present disclosure, the number of rows of word-lines may be defined to be the same as the number of rows of word-line holes 4. That is, as shown in FIG. 11, although the gate strips 2 in the word-line holes 4 of the same row are connected to a corresponding odd word-line 8a and a corresponding even word-line 8b, one odd word-line 8a and one even word-line 8b corresponding to the word-line holes 4 of the same row may be defined as one row of word-lines corresponding to the row of gate strips 2 (word-line holes 4). That is, each row of word-line includes one odd word-line 8a and one even word-line 8b, and the number of rows of word-lines is the same as the number of rows of the word-line holes 4. It should also be noted that, as shown in FIG. 11, in each row, each of the left side and right side of a word-line hole 4 not disposed on ends of the memory array correspond to a column of drain region semiconductor strips 11, channel semiconductor strips 12, and source region semiconductor strips 13. However, from left to right, for a word-line hole 4 disposed on a left terminal of the memory array (first terminal), only the right side of the word-line hole 4 corresponds to a column of drain region semiconductor strips 11, channel semiconductor strips 12, and source region semiconductor strips 13; for a word-line hole 4 disposed on a right terminal of the memory array (last terminal), only the left side of the word-line hole 4 corresponds to a column of drain region semiconductor strips 11, channel semiconductor strips 12, and source region semiconductor strips 13. Therefore, it is understood by those skilled in the art that in each row, the word-line hole 4 at the first terminal and the word-line hole 4 at the last terminal functionally constitute a complete word-line hole.

As shown in FIG. 11, in the embodiments, multiple word-lines may be arranged above the multiple memory subarray layers 1a in the memory device, each of which is connected to corresponding word-line holes 4 through word-line connection lines 7.

Of course, it is understood by those skilled in the art that multiple word-lines may be arranged on another stacked chip, and the stacked chip may be stacked with and electrically connected to a chip in which the memory device is located. For example, the stacked chip may be stacked with the chip in which the memory device is located by means of hybrid bonding. A terminal of each word-line connection line 7 in the memory device away from the corresponding gate strip 2 serves as a word-line connection terminal of the memory device for connecting to the stacked chip stacked together in the height direction Z of the memory device.

In addition, as shown in FIG. 11, in another embodiments, the memory device may further include multiple word-line lead lines 6a or 6b, each word-line further corresponding to a word-line lead line 6a or 6b, respectively, with the word-line lead line 6a or 6b extending in the height direction Z and away from the gate strips 2 with respect to the word-line connection lines 7. A terminal of the word-line lead line 6a or 6b away from the word-line is configured as a word-line connection terminal for connecting to the stacked chip stacked together in the height direction Z of the memory device. That is, the word-lines are arranged on the memory array chip and the control circuit is arranged on the other chip. Of course, those skilled in the art can understand that each word-line may be connected to the control circuit on the chip on which the memory device is located through a corresponding word-line lead line 6a or 6b, i.e., the relevant lines, memory array, and control circuit are arranged on the same chip.

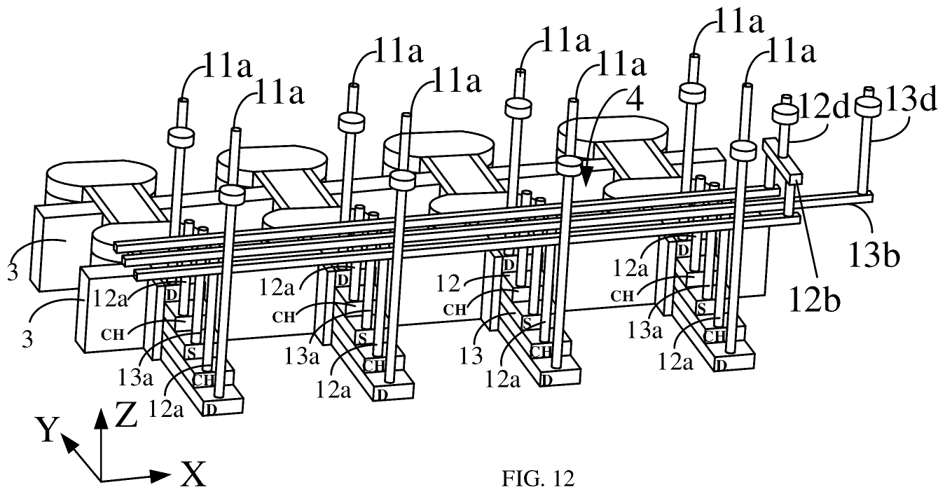

Referring further to FIG. 12, FIG. 12 is a structural schematic view of a circuit connection of part of memory cells of a memory device according to an embodiment of the present disclosure. As shown in FIG. 12, for each column of drain region semiconductor strips 11, channel semiconductor strips 12, and source region semiconductor strips 13 of the multiple memory subarray layers 1a: the multiple drain region semiconductor strips 11 in the same column are led out through different bit line connection lines 11a arranged on an end of each drain region semiconductor strip 11, the bit line connection lines 11a extending along the height direction Z as shown in FIG. 12. For example, for the drain region semiconductor strips 11, the channel semiconductor strips 12, and the source region semiconductor strips 13 in the first column, the drain region semiconductor strip 11 in the first memory subarray layer 1a is led out at its terminal by a bit line connection line 11a, where a terminal of the bit line connection line 11a away from the drain region semiconductor strip 11 may be configured as a bit line connection terminal; the drain region semiconductor strip 11 in the second memory subarray layer 1a is led out at its terminal by another bit line connection line 11a, and a terminal of the another bit line connection line 11a away from the corresponding drain region semiconductor strip 11 is configured as another bit line connection terminal; . . . , and so on. Therefore, each drain region semiconductor strip 11 may serve as a bit line and receive a bit line voltage through the each bit line connection terminal.

It will be understood by those skilled in the art that the memory device may be connected to another stacked chip stacked together in the height direction Z of the memory device through the bit line connection terminal, and provide a bit line voltage to each drain region semiconductor strip 11 in the memory device as a bit line through the bit line connection terminal by means of another stacked chip. Of course, the bit line connection terminal may be further configured to be connected to the control circuit on the chip where the memory device is located, i.e., the relevant lines, the memory array 1, and the control circuit are arranged on the same chip.

Similarly, for each column of drain region semiconductor strips 11, channel semiconductor strips 12, and source region semiconductor strips 13 of the multiple memory subarray layers 1a, the multiple source region semiconductor strips 13 in the same column are led out through different source connection lines 13a disposed on a terminal of each source region semiconductor strip, and the source connection lines 13a extend along the height direction Z.

As shown in FIG. 12, all of the source connection lines 13a in the memory device may be connected to the same common source line 13b, respectively, and a source voltage is applied to the source region semiconductor strips 13 in the memory device through the common source line 13b and the source connection lines 13a.

Of course, it is understood by those skilled in the art that in other embodiments, the memory device may include multiple common source lines 13b, such as a predetermined number of the multiple common source lines 13b, and the source region semiconductor strips 13 in the multiple memory subarray layers 1a may be connected to different multiple common source lines 13b via corresponding source connection lines 13a according to a predetermined rule. In addition, also similar to the bit line connection line 11a corresponding to the drain region semiconductor strip 11, a terminal of the source connection line 13a corresponding to each source region semiconductor strip 13 away from the source region semiconductor strip 13 may be configured as a source connection terminal to receive the source voltage.

Referring further to FIG. 12, the memory device may further include a common source lead line 13d connected to the common source line 13b, where the common source line 13b is connected to all source connection lines 13a in the memory device. The common source lead line 13d extends away from the memory array 1 in the memory device and in the height direction Z. A terminal of the common source lead line 13d away from the common source line 13b may be configured as a common source connection terminal for connecting to another stacked chip stacked together in the height direction Z in the memory device. Of course, the common source connection terminal may further be configured to connect to the control circuit on the chip on which the memory device is located, i.e., the relevant lines, the memory array, and the control circuit are arranged on the same chip.

Of course, it can be understood by those skilled in the art that the common source line 13b may be arranged in another stacked chip stacked with the memory device in the height direction Z. That is, a terminal of the source connection line 13a away from the corresponding source region semiconductor strip 13 may be configured as a source connection terminal for connection with another stacked chip stacked with the memory device in the height direction Z, such that the common source line 13b are arranged in another stacked chip.

As above, for each column of drain region semiconductor strips 11, channel semiconductor strips 12, and source region semiconductor strips 13 of the multiple memory subarray layers 1a, the multiple channel region semiconductor strips 12 in the same column are led out through different well region connection lines 12a disposed on a terminal of each channel semiconductor strip 12, and the well region connection lines 12a extends along the height direction Z.

As shown in FIG. 12, all of the well region connection lines 12a in the memory device are each connected to the same common well region line 12b, thereby uniformly applying a well region voltage to all the channel semiconductor strips 12 in the memory device through the common well region line 12b.

Of course, it will be understood by those skilled in the art that the corresponding well region connection line 12a of each channel semiconductor strip 12 in the memory device may be connected to multiple separate common well region lines 12b to apply a well voltage to each channel semiconductor strip 12 separately. For example, similar to the above, a terminal of the well region connection line 12a corresponding to each channel semiconductor strip 12 away from the channel semiconductor strip 12 serves as a well connection terminal which is configured to receive a separate well voltage.

Referring further to FIG. 12, all of the well region connection lines 12a in the memory device are each connected to the same common well region line 12b; the memory device may further include a common well region lead line 12d connected to the common well region line 12b, with the common well region lead line 12d extending away from the memory array 1 in the memory device and along the height direction Z. A terminal of the common well region lead line 12d away from the common well region line 12b may be configured as a common well region connection terminal for connection to another stacked chip stacked with the memory device in the height direction Z. Of course, the common well region connection terminal may further be configured for connection to the control circuit on the chip on which the memory device is located, i.e., the associated lines, the memory array 1, and the control circuit are arranged on the same chip. That is, through the common well region line 12b it is possible to connect all the channel semiconductor strips 12 in the memory device together to receive the same well voltage. In the embodiments, the channel semiconductor strip 12 may be a p-type semiconductor strip forming a p-well, and all the channel semiconductor strips 12 in the memory device are connected together through the common well region line 12b, receiving the same well voltage through the common well region line 12b. In addition, in the embodiments, the memory device may read signals through the same common source line 13b.

Of course, it will be understood by those skilled in the art that the common well region line 12b may be arranged in another stacked chip stacked together with the memory device in the height direction Z. That is, a terminal of the well region connection line 12a away from the corresponding channel semiconductor strip 12 may be configured as a well region connection terminal for connection to another stacked chip stacked together with the memory device in the height direction Z, thereby arranging the common well region line 12b in another stacked chip.

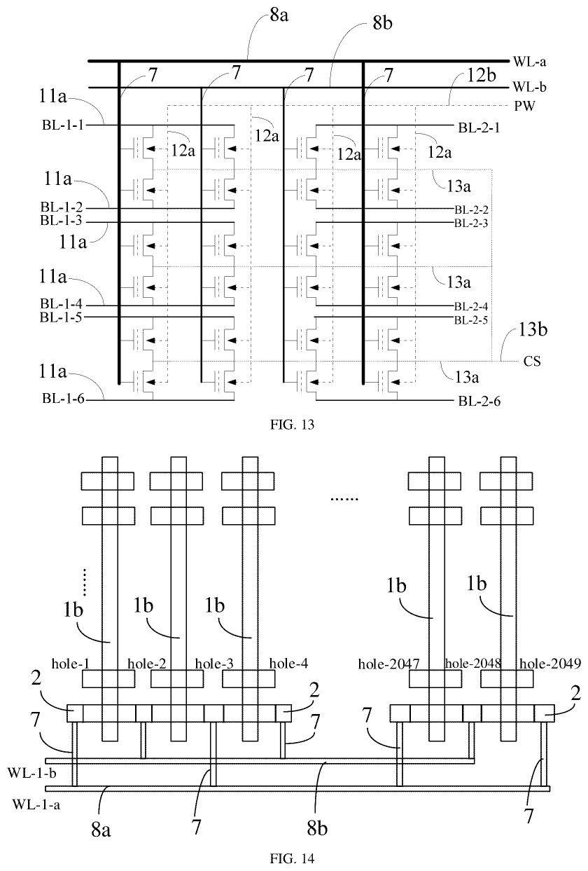

In some embodiments, it is noted that, as shown in FIG. 11 and FIG. 13, in the present disclosure, connecting wires, such as word-line 8a or 8b, word-line connection line 7, word-line lead line 6a or 6b, common source line 13b, common well region line 12b, etc. are arranged in the memory device, especially on the same side of the memory array 1 in the memory device, i.e., arranged above the memory array 1. Therefore, it may be ensured that the drain region semiconductor strips 11, the channel semiconductor strips 12, and the source region semiconductor strips 13 in the memory array 1may be each formed as single-crystal semiconductor strips by epitaxial growth, while only polycrystalline semiconductor strips can be formed by the deposition method. Compared to polycrystalline semiconductor strips formed by deposition, the drain region semiconductor strips 11, channel semiconductor strips 12, and source region semiconductor strips 13 formed by epitaxial growth of the present disclosure may have superior device performance and greatly improve the performance of the relevant memory device. Specifically, when comparing the memory cell adopted with a single-crystal semiconductor (single-crystal drain region semiconductor strip 11, channel semiconductor strip 12, and source region semiconductor strip 13) to the memory cell adopted with a polycrystalline semiconductor, the memory cell with the polycrystalline semiconductor has more interfaces, along which electrons move when passing through the polycrystalline semiconductor, i.e., the distance of electron movement increases and the current decreases significantly. According to a practical empirical test, the current of the memory cell with a polycrystalline semiconductor is only 1/10 of the current of the memory cell with a single-crystal semiconductor. Therefore, the memory device of the present disclosure, with the memory cell with a single-crystal semiconductor, may greatly improve the performance of the memory device. In addition, the low current of the memory cell with the polycrystalline semiconductor affects the read window between the read/write operation (PGM) and the erase operation (ERS) of the memory cell, which has a great impact on the reliability of the memory device, especially for the NOR memory device. In addition, for NOR memory devices, when a hot carrier injection (HCI) method is applied for read/write operations, a single-crystal semiconductor must be adopted to accomplish this.

In addition, since the connecting wires in the present disclosure are arranged on the same side of the memory array 1 in the memory device, it is more convenient to perform the bonding stacking process in three dimensions with the stacked chips, thereby improving the performance of the related memory devices, and manufacturing the chips separately is conducive to optimizing the process and reducing the manufacturing time.

It can be understood by those skilled in the art that in some embodiments, in order for the memory device to obtain better performance, the outermost memory cell may generally serve as a dummy memory cell (dummy cell) and does not perform actual storage works. For example, the memory cells included in the lowermost memory subarray layer 1a may be configured as dummy memory cells. In addition, in some embodiments, the leftmost and rightmost columns of the memory device are each arranged with a column of drain region semiconductor strips 11, channel semiconductor strips 12, and source region semiconductor strips 13, respectively. The memory cells formed by the leftmost column of the drain region semiconductor strips 11, the channel semiconductor strips 12, and the source region semiconductor strips 13, together with the gate strips 2 in the word-line holes 4 on the right side and the storage structures 5 between them, and the memory cells formed by the rightmost column of drain region semiconductor strips 11, channel semiconductor strips 12 and source region semiconductor strips 13, together with the gate strips 2 in the word-line hole 4 on the left side and the storage structures 5 between them, are also taken as dummy memory cells not participating in the actual storage work.

Therefore, in the present disclosure, unless intentionally pointed out, the memory subarray layers 1a in the entire specification do not include the lowermost memory subarray layer involved in the dummy memory cells (dummy cells); nor do the drain region semiconductor strips 11, the channel semiconductor strips 12, and the source region semiconductor strips 13 include the leftmost column of drain region semiconductor strips 11, channel semiconductor strips 12, and source region semiconductor strips 13, and the rightmost column of drain region semiconductor strips 11, channel semiconductor strips 12, and source region semiconductor strips 13, involved in the dummy memory cells (dummy cells).

Therefore, as above, in the same row, from left to right, the first word-line hole 4 only corresponds to a column of drain region semiconductor strips 11, channel semiconductor strips 12, and source region semiconductor strips 13 on the right side; the last word-line hole 4 only corresponds to a column of drain region semiconductor strips 11, channel semiconductor strips 12, and source region semiconductor strips 13 on the left side. Therefore, those skilled in the art can understand that the first and last word-line holes functionally constitute a complete word-line hole.

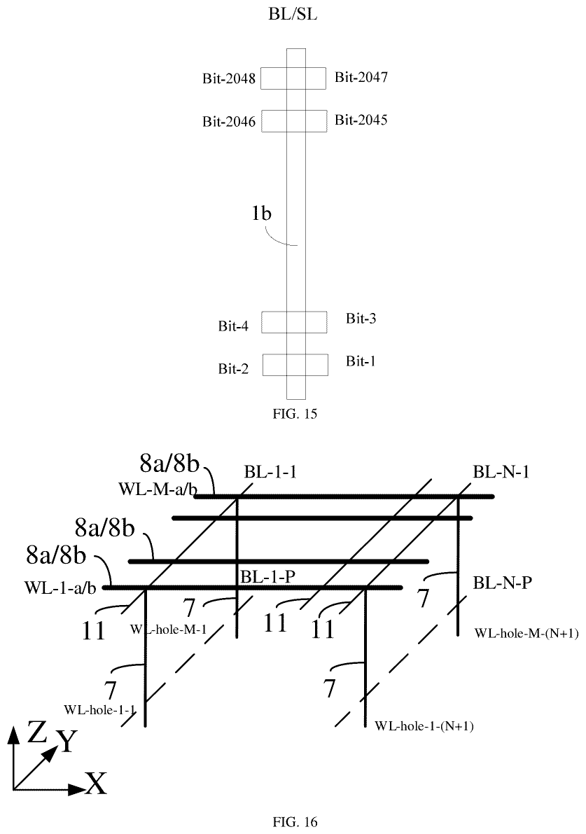

In conjunction with FIG. 13 to FIG. 16, FIG. 13 is a schematic view of a circuitry of the memory device shown in FIG. 11, FIG. 14 is a schematic sketch of a plan view of the memory device shown in FIG. 11, FIG. 15 is a schematic view of a memory cell corresponding to each layer of bit lines, and FIG. 16 is a schematic view of a three-dimensional distribution of word-lines and bit lines.

As shown in FIG. 13, the memory device includes multiple memory subarray layers 1a (six layers herein illustrated in FIG. 13), and the drain region semiconductor strips 11 in the multiple memory subarray layers 1a serve as bit lines, such as BL-1-1, BL-1-2, BL-1-3, BL-1-4, BL-1-5, BL-1-6; multiple columns of drain region semiconductor strips 11 in each memory subarray layer 1a constitute multiple columns of bit lines, such as BL-1-1, BL-2-1, . . . ; the source region semiconductors 13 in the multiple memory subarray layers la in memory device are connected to a common source line 13b; the channel semiconductor strips 12 in the multiple memory subarray layers 1a in memory device are connected to a common well region line 12b. In addition, the gate strip 2 in the same word-line hole 4, together with the drain region semiconductor layers 11c, the channel semiconductor layers 12c, and the source region semiconductor layers 13c on the left and right sides, forms two columns of memory cells (as shown in the middle two columns of memory cells), respectively. The gate strips 2 corresponding to the odd number word holes 4 are connected to an odd word-line WL-a, such as the first, fourth column memory cells, which correspond to the first word-line holes and third word-line holes, respectively; and the gate strips 2 corresponding to the even number word holes 4 are connected to an even word-line WL-b, such as the second, third column memory cells, which correspond to the second word-line holes.

As shown in FIG. 14 to FIG. 16, in each memory subarray layer 1a, for the drain region semiconductor strips 11, channel semiconductor strips 12, and source region semiconductor strips 13 extending along the column direction, one column of semiconductor strip structure 1b forms a memory cell (bit) with the gate strip 2 in the left word-line hole 4 and another memory cell (bit) with the gate strip 2 in the right word-line hole 4. The first row of odd word-line holes 4, such as hole-1, hole-3, . . . , are connected to the first row of odd word-line WL-1-a, and the first row of even word-line holes, such as hole-2, hole-4, . . . , are connected to the first row of even word-line WL-1-b.

As shown in FIG. 16, assume that the memory device includes P layers of memory subarray layers 1a, M rows of word-lines, and N columns of bit lines. Then, each memory subarray layer 1a includes N columns of drain region semiconductor strips 11 as bit lines, such as shown as BL-1-1, . . . , BL-N-1; for the P-th memory subarray layer 1a, such as BL-1-1, . . . , BL-N-P as shown, the memory device includes N*P drain region semiconductor strips 11 as bit lines. M rows of word-lines, e.g., WL-1-a/b, . . . , WL-M-a/b, each have a projection crossed with a projection of each of the N columns of bit lines on a projection plane defined by the row direction X and the column direction Y, respectively, to form multiple memory cells. P, M and N are all natural numbers greater than 0.

According to the above conditions, it is understood by those skilled in the art that in the same row direction X, the memory device includes (N+1) word-line holes 4, such as shown as WL-hole-1-1, . . . , WL-hole-1-(N+1); and in the same column direction Y, the memory device includes M word-line holes 4, such as shown as WL-hole-1-(N+1), . . . , WL-hole-M-(N+1). A side of each column of drain region semiconductor strips 11, channel semiconductor strips 12, and source region semiconductor strips 13 corresponds to M word-line holes 4. Each row of word-lines (one odd word-line 8a and one even word-line 8b) corresponds to (N+1) word-line holes 4. As above, in the same row, the word-line holes 4 at the first and last ends each correspond to only one memory cell in each memory subarray layer 1a, and therefore the word-line holes 4 at the first and last ends can be functionally regarded as a complete word-line hole; while other word-line holes 4 correspond to two memory cells (one on each of the left and right sides) in each memory subarray layer 1a. Therefore, each row of word-lines corresponds to N*2*P memory cells. When N is an even number, an odd word-line 8a corresponds to (N/2+1) word-line holes, which includes word-line holes 4 at the first and last ends of the same row, that is, an odd word-line 8a also corresponds to N/2 complete word-line holes 4, corresponding to (N/2)*P*2 memory cells. An even word-line 8b corresponds to N/2 word-line holes 4, corresponding to (N/2)*P*2 memory cells. In other words, the number of memory cells corresponding to an odd word-lines 8a and the number of memory cells corresponding to an even word-lines 8b are the same.

In some embodiments, assume that the memory device specifically includes 8 layers of the memory subarray layers 1a and 1024 rows of word-lines, each row of word-lines includes an odd word-line 8a and an even word-line 8b, each layer of the memory subarray layer 1a includes 2048 columns of the drain region semiconductor strips 11 as bit lines, and the memory device includes 2048*8 of the drain region semiconductor strips 11 as bit lines.

In the same row direction X, the memory device includes (2048+1=2049) word-line holes 4; in the same column direction Y, the memory device includes 1024 word-line holes 4. Each drain region semiconductor strip 11 as a bit line corresponds to 1024 word-line holes 4, corresponding to 1024*2 memory cells. Each row of word-lines corresponds to (2048+1=2049) word-line holes 4. The word-line holes 4 at the first and last terminals each correspond to only one memory cell in each memory subarray layer 1a, which functionally constitutes a complete word-line hole 4, which corresponds to 2048*2*8=32K memory cells. N is an even number 2048, then an odd word-line 8a corresponds to (2048/2+1=1025) word-line holes, which includes the word-line holes4 at the first and last ends of the same row, that is, an odd word-line 8a also corresponds to 1024 complete word-line holes4, which corresponds to (2048/2)*8*2 memory cells; an even word-line 8b corresponds to 2048/2 word-line holes4, which corresponds to (2048/2)*8*2 memory cells.

In the memory device, ⅛ of the memory cells corresponding to a word-line, that is, 1024*2 memory cells, may be defined as one memory page (128 complete word-line holes 4). In the memory device, 32K memory cells corresponding to one word-line may be defined as a sector, which can be understood that one sector corresponds to 2 word-lines, (2048+1) word-line holes4 (2048 complete word-line holes4), and 2048*2*8 memory cells (bit).

In the memory device, 16 sectors may be defined to form a sub memory device (eblk) including 0.5 M memory cells (2048*2*8*16=1024*2*2*8*16=1024*1024*0.5). In specific embodiments, the memory device includes 64 sub memory devices 10 including 32 M memory cells. Each memory device shares a common source line 13b and a common well region line 12b.

The memory device provided in the embodiments includes a memory array 1, and the memory array 1 includes multiple memory cells distributed in a three-dimensional array; the memory array 1 includes multiple memory subarray layers 1a stacked sequentially along a height direction Z, and each memory subarray layer 1a includes a drain region semiconductor layer, a channel semiconductor layer, and a source region semiconductor layer stacked along the height direction Z; the drain region semiconductor layer, channel semiconductor layer, and source region semiconductor layer in each memory subarray layer 1a include multiple drain region semiconductor strips 11, channel semiconductor strips 12, and source region semiconductor strips 13, respectively, distributed along a row direction X, and each drain region semiconductor strip 11, channel semiconductor strip 12, and source region semiconductor strip 13 extends along a column direction Y; multiple gate strips 2 distributed along the column direction Y are arranged on each side of each column of drain region semiconductor strips 11, channel semiconductor strips 12, and source region semiconductor strips 13, each gate strip 2 extending along the height direction Z; in the height direction Z, a projection of at least a part of each gate strip 2 coincides with a projection of a part of a corresponding channel semiconductor strip 12 in each memory subarray layer 1a on a projection plane, the projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, and a part of the source region semiconductor strip 13 adjacent to the corresponding part of the channel semiconductor strip 12 are configured to form a memory cell. The memory device has a higher storage density compared to a two-dimensional memory array.

As above, the memory device of the present disclosure includes at least two structures of memory cells. In some embodiments, in combination with FIG. 5, FIG. 7, FIG. 8 and FIG. 10, a memory cell is provided that includes a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and extends along the height direction Z. In the height direction Z, a projection of the gate portion 2′partially overlaps with a projection of the channel portion 12′on a projection plane extending along the height direction Z. A storage structure portion 5′ is arranged between the gate portion 2′ and the drain region portion 11′, the channel portion 12′, and the source region portion 13′.

The drain region portion 11′ is a part of the drain region semiconductor layer, the channel portion 12′ is a part of the channel semiconductor layer, and the source region portion 13′ is a part of the source region semiconductor layer of the memory device provided in the above embodiments. The specific structures, functions, and lamination methods of the drain region portion 11′, the channel portion 12′, the source region portion 13′, and the storage structure portion 5′ can be found in those of the drain region semiconductor layer, the channel semiconductor layer, the source region semiconductor layer, and the storage structure 5′ in each of the memory subarray layers 1a described above, and the same or similar technical effects can be achieved, which will not be repeated herein.

When the drain region portion 11′, the channel portion 12′, and the source region portion 13′ are each in a strip structure and the storage structure portion 5′ is a charge trapping storage structure portion, the specific structure of the memory cell can be seen in FIG. 5, and other structures of the memory cell can be seen in the relevant description of FIG. 5 above. When the drain region portion 11′, the channel portion 12′, and the source region portion 13′each include the body structure 15a and multiple protrusions 15b, and the storage structure portion 5′ is a charge trapping storage structure portion, the specific structure of the memory cell can be seen in FIG. 7, and other structures of the memory cell can be found in the above description of FIG. 7. When the storage structure portion 5′ is a floating gate storage structure portion, the specific structure of the memory cell can be seen in FIG. 10 and FIG. 11, and other structures of the memory cell can be seen in the above description of FIG. 10 and FIG. 11.

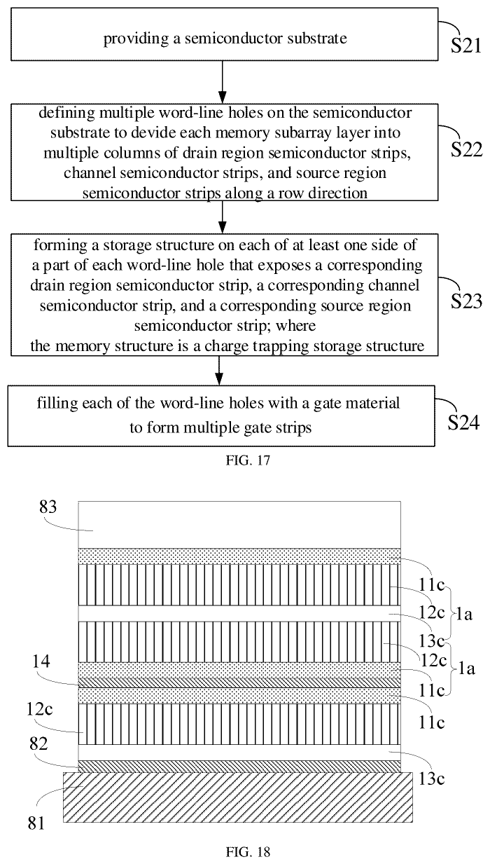

As shown in FIG. 17, FIG. 17 is a flowchart of a manufacturing method of a memory device according to an embodiment of the present disclosure. In the embodiments, a manufacturing method of a memory device is provided that may be configured to prepare the memory device provided in FIG. 1 to FIG. 4 of the above embodiments, and the storage structure 5 of the memory device is a charge trapping storage structure. Specifically, the method includes operations at blocks illustrated in FIG. 17.

At step S21: providing a semiconductor substrate.

As shown in FIG. 18, FIG. 18 is a cross-sectional view of a semiconductor substrate according to an embodiment of the present disclosure. The semiconductor substrate includes a substrate 81, a first single-crystal sacrificial semiconductor layer 82 arranged on the substrate 81, and two memory subarray layers la and a second single-crystal sacrificial semiconductor layer 14 stacked and formed alternately in sequence on the first single-crystal sacrificial semiconductor layer 82, until another two memory subarray layers 1a are formed uppermost.

The substrate 81 may be a single-crystal substrate 81; specifically, it may be made of single-crystal silicon. The first single-crystal sacrificial semiconductor layer 82 and/or the second single-crystal sacrificial semiconductor layer 14 may be made of silicon germanium (SiGe). The multiple memory subarray layers la are sequentially layered in a height direction Z perpendicular to the substrate 81. Each memory subarray layer la includes a drain region semiconductor layer 11c, a channel semiconductor layer 12c′, and a source region semiconductor layer 13c stacked along the height direction Z. Two adjacent memory subarray layers 1a in the height direction Z may share a common source region. The two adjacent memory subarray layers 1a may include sequentially stacked drain region semiconductor layer 11c, channel semiconductor layer 12c′, source region semiconductor layer 13c, channel semiconductor layer 12c′, and drain region semiconductor layer 11c, to achieve sharing the common source region semiconductor layer 13c. Therefore, for common-source memory subarray layers 1a, a second single-crystal sacrificial semiconductor layer 14 is arranged on every two memory subarray layers 1a to isolate from the other two memory subarray layers 1a. The second single-crystal sacrificial semiconductor layer 14 may be made of silicon germanium (SiGe).

It should be noted that the structure shown in FIG. 18 only exemplarily illustrates part of the structure of the semiconductor substrate; it is understood by those skilled in the art that between the first single-crystal sacrificial semiconductor layer 82 and the second single-crystal sacrificial semiconductor layer 14 shown in FIG. 18, two memory subarray layers 1a sharing a common source region semiconductor layer 13c are arranged. For the sake of brevity of the accompanying drawings, one layer of the memory subarray layer 1a is shown schematically only for illustrative purposes only.

In some embodiments, step S21 may specifically include the following.

Step S211a: providing a substrate 81.

The substrate 81 may be a single-crystal substrate 81; specifically, it may be single-crystal silicon.

Step S212a: forming multiple memory subarray layers la sequentially on the substrate 81 along the height direction Z.

Step S212a may specifically include the following.

Step a: forming the first single-crystal sacrificial semiconductor layer 82 on the substrate 81 in epitaxial growth.

The first single-crystal sacrificial semiconductor layer 82 may be silicon germanium (SiGe).

Step b: forming two memory subarray layers la and a second single-crystal sacrificial semiconductor layer 14 alternately in sequence by epitaxial growth on the first single-crystal sacrificial semiconductor layer 82; continuing to form another two memory subarray layers 1a, optionally continuing to repeatedly stack another second single-crystal sacrificial semiconductor layer 14 and another two common-source memory subarray layers 1a, until forming uppermost two common-source memory subarray layers.

The material of the second single-crystal sacrificial semiconductor layer 14 is the same as the material of the first single-crystal sacrificial semiconductor layer 82, which may also be silicon germanium (SiGe).

It is understood by those skilled in the art that the purpose of providing the first single-crystal sacrificial semiconductor layer 82 on the substrate 81 first is to avoid electrical leakage caused by the multiple memory subarray layers la directly contacting the substrate 81. However, as above, the device performance of the lowermost memory subarray layer 1a in the memory device of the present disclosure is poor, and therefore, the memory cells in the lowermost memory subarray layer 1a are generally configured as dummy memory cells and do not participate in the actual memory work. Therefore, it is understood by those skilled in the art that the first single-crystal sacrificial semiconductor layer 82 may not be arranged on the substrate 81, and a single memory subarray layer 1a or two common-source memory subarray layers 1a are formed directly on the substrate 81 as dummy memory cells, on which the second single-crystal sacrificial semiconductor layer 14 and two common-source memory subarray layers 1a are alternately formed by epitaxial growth until the uppermost layer of two common-source memory subarray layers 1a are formed. That is, the lowermost one memory subarray layer 1a or two common-source memory subarray layers 1a, as a dummy memory cell(s), does not participate in the actual memory work, and therefore, it can also prevent electrical leakage to the substrate 81.

Two adjacent memory subarray layers 1a share a common source region, and each two common-source memory subarray layers may be formed in a manner including the following.

Step b1: forming a first single-crystal semiconductor layer of a first doping type by epitaxial growth on the first single-crystal sacrificial semiconductor layer 82 or the second single-crystal sacrificial semiconductor layer 14 of the lower layer.

Specifically, a semiconductor material gas and a first-type of dopant ion gas may be simultaneously introduced to form one layer of the first single-crystal semiconductor layer of the first doping type on the first single-crystal sacrificial semiconductor layer 82 or the second single-crystal sacrificial semiconductor layer 14 of the lower layer by epitaxial growth. The first single-crystal semiconductor layer serves as a drain region semiconductor layer 11c (or a source region semiconductor layer 13c). The first-type of dopant ion may be an arsenic ion. The semiconductor material may be an existing semiconductor material for forming the drain region (or source region).

Step b2: forming a second single-crystal semiconductor layer of a second doping type on the first single-crystal semiconductor layer by epitaxial growth.

Specifically, a semiconductor material gas and a second-type of dopant ion gas may be simultaneously fed to form one layer of the second single-crystal semiconductor layer of the second doping type on the first single-crystal semiconductor layer by epitaxial growth. The second single-crystal semiconductor layer serves as a channel semiconductor layer 12c′. The second-type of dopant ion may be a BF2+ ion. The semiconductor material may be an existing semiconductor material for forming a well region.

Step b3: forming a third single-crystal semiconductor layer of the first doping type on the second single-crystal semiconductor layer by epitaxial growth.

Specifically, a semiconductor material gas and a first-type of dopant ion gas may be simultaneously fed to form one layer of the third single-crystal semiconductor layer of the first doping type on the second single-crystal semiconductor layer by epitaxial growth. The third single-crystal semiconductor layer serves as a source region semiconductor layer 13c (or a drain region semiconductor layer 11c). The first-type of dopant ion may be an arsenic ion. The semiconductor material may be an existing semiconductor material for forming the source drain region (or drain region).

In a specific implementation of step S212a, one layer of the second single-crystal sacrificial semiconductor layer 14 is further formed between every two memory subarray layers 1a. Each two adjacent memory subarray layers 1a separated by the second single-crystal sacrificial semiconductor layer 14 in the height direction Z includes sequentially stacked drain region semiconductor layer 11c, channel semiconductor layer 12c′, source region semiconductor layer 13c, channel semiconductor layer 12c′, and drain region semiconductor layer 11c to share the same source region semiconductor layer 13c.

Step b4: forming a fourth single-crystal semiconductor layer of a second doping type on the third single-crystal semiconductor layer by epitaxial growth.

This step b4 is performed in a similar manner to step b2. The fourth single-crystal semiconductor layer serve as the channel semiconductor layer 12c′.

Step b5: forming a fifth single-crystal semiconductor layer of a first doping type on the fourth single-crystal semiconductor layer by epitaxial growth.

This step b5 is performed in a similar manner as step b1. The fifth single-crystal semiconductor layer serve as the drain region semiconductor layer 11c (or source region semiconductor layer 13c).

The first single-crystal semiconductor layer, the second single-crystal semiconductor layer, and the third single-crystal semiconductor layer form a memory subarray layer 1a; the third single-crystal semiconductor layer, the fourth single-crystal semiconductor layer, and the fifth single-crystal semiconductor layer form another memory subarray layer 1a; and the two memory subarray layers 1a share the third single-crystal semiconductor layer as the shared source region semiconductor layer 13c.

It is understood that, in the embodiments, after step b5, one layer of the second single-crystal sacrificial semiconductor layer 14 is formed on the fifth single-crystal semiconductor layer, after which steps b1-b5 may be repeated on the second single-crystal sacrificial semiconductor layer 14 until a predetermined number of layers of the memory subarray layers 1a is formed.

That is, a second single-crystal sacrificial semiconductor layer 14 is formed between every two memory subarray layers 1a. Moreover, each adjacent two memory subarray layers 1a separated by the second single-crystal sacrificial semiconductor layer 14 in the height direction Z includes sequentially stacked drain region semiconductor layer 11c, channel semiconductor layer 12c′, source region semiconductor layer 13c, channel semiconductor layer 12c′, and drain region semiconductor layer 11c to share the same source region semiconductor layer 13c.

Step S213a: forming a first hard mask layer 83 on the multiple memory subarray layers 1a, and defining multiple isolation wall holes 31 in the first hard mask layer 83 and the multiple memory subarray layers 1a, and filling the multiple isolation wall holes 31 with an isolation material to form multiple isolation walls 3 to form a semiconductor substrate.

The first hard mask layer 83 may be made of silicon dioxide or silicon nitride.

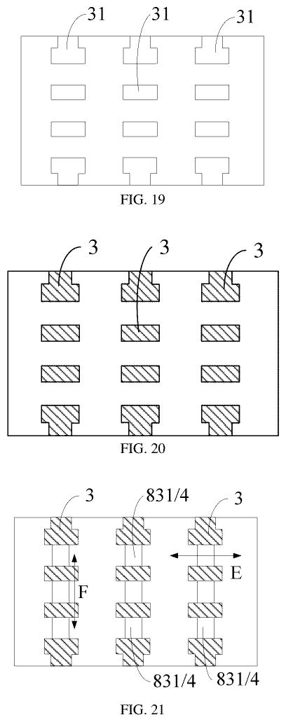

Specifically, referring to FIG. 19, FIG. 19 is a top view of defining multiple isolation wall holes 31 in the memory subarray layers la. The multiple isolation wall holes 31 may be formed etching, and the isolation wall holes 31 are arranged in a matrix in the row direction X and the column direction Y, with each isolation wall hole 31 extending in the height direction Z to a surface of the substrate 81. The specific structure of forming the isolation walls 3 in the isolation wall holes 31 can be seen in FIG. 20, which is a top view of the multiple isolation walls 3 formed in the isolation wall holes 31 shown in FIG. 19. Specifically, the isolation wall 3 near an edge of the memory device in the column direction Y extends further in the column direction Y to the edge of the memory device to ensure that the isolation wall 3 at the edge of the column direction Y can completely isolate two adjacent columns stacked structures 1b′. Specifically, in some embodiments, the isolation wall 3 near the edge of the memory device in the column direction Y is a T-shaped isolation wall 3, i.e., the isolation wall 3 includes a lateral portion and a protruding portion toward the edge of the memory device in the column direction Y, and the protruding portion is in contact with the edge of the memory device in the column direction Y to completely isolate the two adjacent column stack structures 1b′ to prevent a short circuit between the two columns of the drain region semiconductor strips 11, the channel semiconductor strips 12, and the source region semiconductor strips 13. The isolation wall 3 and the first hard mask layer 83 may be made of the same material.

In other embodiments, step S21 specifically includes the following operations.

Step S211b: providing the substrate 81.

Step S212b: forming multiple isolation walls 3 on the substrate 81, where the multiple isolation walls 3 are arranged in a matrix in the row direction X and the column direction Y, each isolation wall 3 extending along the height direction Z perpendicular to the substrate 81.

Step S213b: forming multiple memory subarray layers la sequentially on the substrate 81 and between the multiple isolation walls 3 along the height direction Z.

The specific implementation process of forming the multiple memory subarray layers 1a is the same or similar to the specific implementation process of forming the multiple memory subarray layers 1a in step S212a above, and the same or similar technical effect can be achieved, as described above.

Step S214b: forming a first hard mask layer 83 on the above structure to form the semiconductor substrate.

Specifically, the first hard mask layer 83 may be formed on the product structure after being processed by step S213b, with the first hard mask layer 83 being disposed on a side surface of the multiple memory subarray layers 1a back from the substrate 81.

At step S22: defining multiple word-line holes on the semiconductor substrate to divide each memory subarray layer into multiple columns of drain region semiconductor strips, channel semiconductor strips, and source region semiconductor strips along a row direction.

In some embodiments, step S22 specifically includes the following.

Step S221: forming the multiple word-line openings 831 on the first hard mask layer 83.

As shown in FIG. 21, FIG. 21 is a top view of forming the multiple word-line openings 831 and word-line holes 4 on the semiconductor substrate. The multiple word-line openings 831 may be formed on the first hard mask layer 83 by etching. The multiple word-line openings 831 are arranged in a matrix in the row direction X and the column direction Y.

Step S222: etching the multiple memory subarray layers 1a under the first hard mask layer 83 to form multiple word-line holes 4.

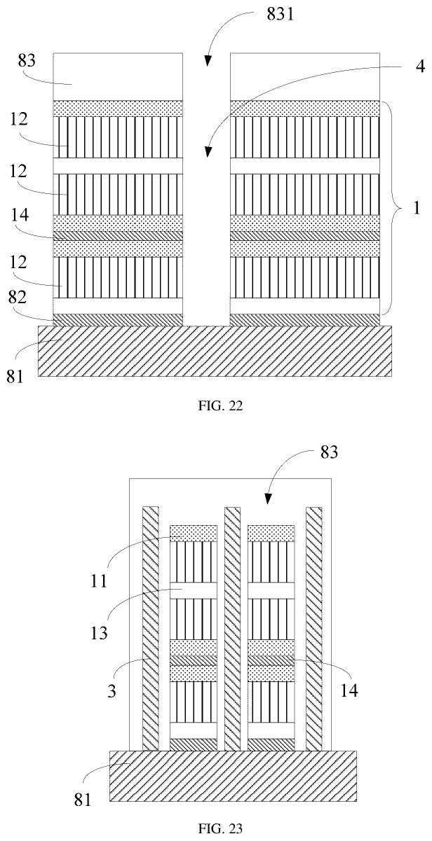

As shown in FIG. 21 to FIG. 23, FIG. 22 is a cross-sectional view in the E-direction of the product corresponding to FIG. 21; and FIG. 23 is a cross-sectional view in the F-direction of the product corresponding to FIG. 21. Specifically, the word-line holes 4 may be formed by etching, and as shown in FIG. 21, the multiple word-line holes 4 are spaced apart from the isolation walls 3; and the multiple word-line holes 4 are arranged in a matrix in the row direction X and the column direction Y, and each memory subarray layer 1a is divided into multiple columns of drain region semiconductor strips 11, channel semiconductor strips 12, and source region semiconductor strips 13 along the row direction X. As shown in FIG. 22, each word-line hole 4 extends along the height direction Z, and the left and right sides (such as the left and right sides in the orientation of FIG. 22) of each word-line hole 4 at a non-edge position expose parts of two columns of drain region semiconductor strips 11, channel semiconductor strips 12, and source region semiconductor strips 13 of the multiple memory subarray layers 1a, respectively. Each word-line hole 4's both sides in the left-right direction are the drain region semiconductor strips 11, channel semiconductor strips 12 and, source region semiconductor strips 13; both sides in the front-rear direction are isolation walls 3. In this step, an etchant with a high etch ratio for the semiconductor material and a low etch ratio for the isolation wall 3 may be applied to process the formation of the word-line holes 4. In addition, as shown in FIG. 2 to FIG. 4, the leftmost edge word-line holes 4 correspond to only one column of the drain region semiconductor strips 11, channel semiconductor strips 12 and, source region semiconductor strips 13 on right side; similarly, the rightmost edge word-line holes 4 correspond to only one column of the drain region semiconductor strips 11, channel semiconductor strips 12 and, source region semiconductor strips 13 on left side. However, it is understood by those skilled in the art that the leftmost edge line holes 4 and the rightmost edge line holes 4 can be considered as a combination to form a complete word-line hole, and the differences in the edge word-line holes 4 will not be specifically noted subsequently.

As shown in FIG. 2 and FIG. 4, the multiple word-line holes 4 together with the multiple isolation walls 3 divide the drain region semiconductor layer 11c in each memory subarray layer 1a into multiple drain region semiconductor strips 11 spaced at intervals along the row direction X; the channel semiconductor layer 12c into multiple channel semiconductor strips 12 spaced at intervals along the row direction X; and the source region semiconductor layer 13c into multiple source region semiconductor strips 13 spaced at intervals along the row direction X. The other specific structures and functions of each drain region semiconductor strip 11, channel semiconductor strip 12, and source region semiconductor strip 13 can be found in the above description and will not be repeated here. In addition, as shown in FIG. 23, the interior of the isolation wall 3 may be silicon oxide with a layer of silicon nitride wrapped around the outside, and the silicon nitride wrapped around the outside may be the same as the material of the first hard mask layer 83.

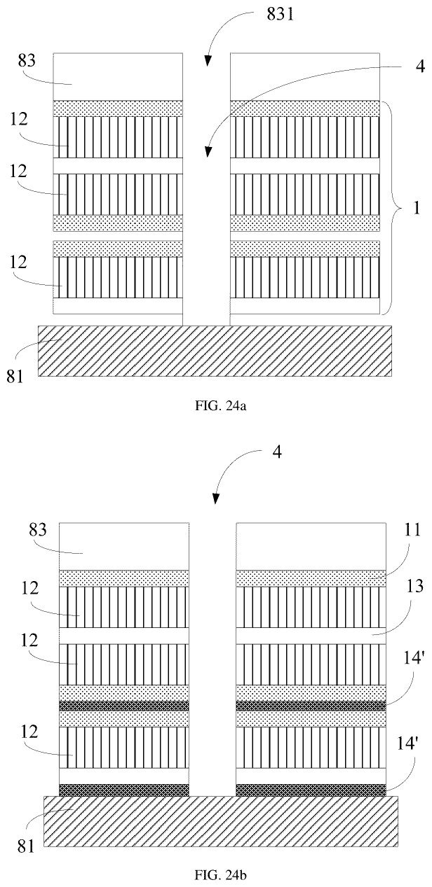

In a specific implementation, referring to FIG. 24a and FIG. 24b, FIG. 24a is a schematic view of the structure shown in FIG. 21 after being processed by step S223; FIG. 24b is a schematic view of the structure shown in FIG. 24a after being filled with the insulating material; after step S222, the method may further include the following.

Step S223: removing the first single-crystal sacrificial semiconductor layer 82 and the second single-crystal sacrificial semiconductor layer 14 through the word-line holes 4.

Specifically, the first single-crystal sacrificial semiconductor layer 82 and the second single-crystal sacrificial semiconductor layer 14 may be removed by etching.

Step S224: depositing on regions where the removed first single-crystal sacrificial semiconductor layer 82 and the second single-crystal sacrificial semiconductor layer 14 were located to fill the regions with an insulating material, thereby replacing the first single-crystal sacrificial semiconductor layer 82 and the second single-crystal sacrificial semiconductor layer 14 with an insulating isolation layer 14′.

The insulating material may be filled by means of atomic layer deposition. The insulating material may specifically be silicon oxide. It will be understood by those skilled in the art that after step S223 removing the first single-crystal sacrificial semiconductor layer 82 and the second single-crystal sacrificial semiconductor layer 14, the isolation walls 3 may provide sufficient support to the adjacent stacked structures 1b′ to facilitate subsequent execution of step S224.

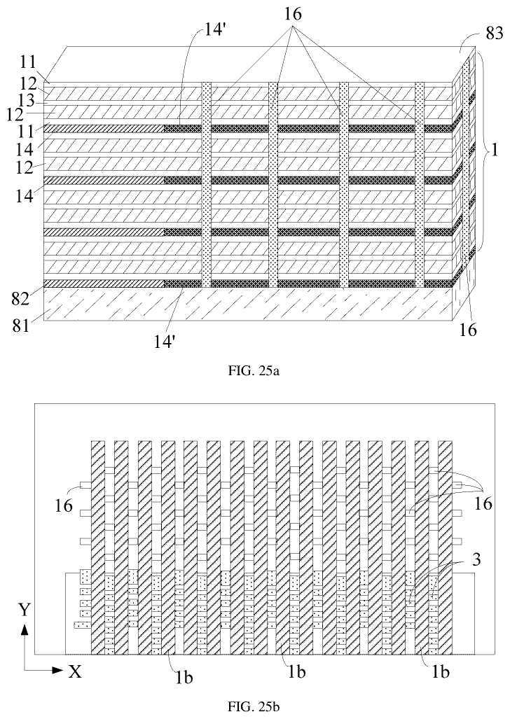

Further, it will be understood by those skilled in the art that in some embodiments, the memory array 1 further includes multiple support posts 16. Specifically, referring to FIG. 25a and FIG. 25b. FIG. 25a is a schematic view of a perspective structure of a memory array according to an embodiment of the present disclosure; and FIG. 25b is a partial plan schematic view of a memory array according to an embodiment of the present disclosure.

As shown in FIG. 25a and FIG. 25b, the memory array 1 further includes multiple support posts 16, each of which extends along the height direction Z of the memory array 1.

As described above, the first single-crystal sacrificial semiconductor layer 82 and the second single-crystal sacrificial semiconductor layer 14 are required to be replaced with the insulating isolation layer 14′. In this step, the first single-crystal sacrificial semiconductor layer 82 and the second single-crystal sacrificial semiconductor layer 14 are partially replaced with the insulating isolation layer 14′, but in subsequent steps, all of the first single-crystal sacrificial semiconductor layer 82 and the second single-crystal sacrificial semiconductor layer 14 are replaced with the insulating isolation layer 14′ as required for electrical isolation. That is, during the manufacturing of the memory array 1, after etching off the first single-crystal sacrificial semiconductor layer 82 and/or the second single-crystal sacrificial semiconductor layer 14, the memory subarray layers 1a in the relevant regions are overhanging. In these relevant regions, when the isolation walls 3 are provided, the isolation walls 3 can provide sufficient support to the overhanging memory subarray layers la in these regions to prevent the memory subarray layers 1a from collapsing.

However, the isolation walls 3 may not present in some regions. For example, in a drain/source lead region, the memory subarray layers 1a in this region are not required to manufacture the memory cells, and the drain region semiconductor strips 11, source region semiconductor strips 13, and/or channel semiconductor strips 12 in the memory subarray layers 1a in this region are required to be led out to be connected with corresponding wires. Therefore, in these regions, multiple support posts 16 are required to be arranged between two columns of the stacked structures 1b′. In this way, after etching the first single-crystal sacrificial semiconductor layer 82 and/or the second single-crystal sacrificial semiconductor layer 14 in the stacked structures 1b′ in these regions during the manufacturing of the memory array 1, the support posts 16 can provide sufficient support to the overhanging memory subarray layers 1a to prevent the memory subarray layers 1a from collapsing, and support the frame of the memory array 1 and maintain the structural stability of the memory array 1.

It will be understood by those skilled in the art that the support posts 16 may be made of the same material as the isolation wall 3 and manufactured in the same process steps as the isolation wall 3. That is, the isolation wall 3 and the support post 16 are similar in nature, except that the isolation wall 3 is arranged in the region of the memory array 1 where the memory cells are required to be manufactured, and it serves to support and form the word-line holes 4 during the manufacturing of the memory array 1; whereas the support post 16 is formed in another region of the memory array 1 where the memory cell is not required to be manufactured, for example, the drain/source lead region, and it serves to support the memory array 1 during the manufacturing process. Of course, in other embodiments, the support post 16 may be arranged in the region of the memory array 1 where the memory cells are required to be manufactured. For example, when the distance between two adjacent isolation walls 3 is far, and the isolation wall 3 does not provide sufficient support, then the support post 16 may be arranged in this region as needed to assist the isolation wall 3 to provide support. That is, the support post 16 may be arranged according to the actual needs, which is not limited by the present disclosure.

The material of the support post 16 may be silicon oxide or silicon nitride.

Step S23: forming a storage structure on each of at least one side of a part of each word-line hole that exposes a corresponding drain region semiconductor strip, a corresponding channel semiconductor strip, and a corresponding source region semiconductor strip, where the storage structure is a charge trapping storage structure.

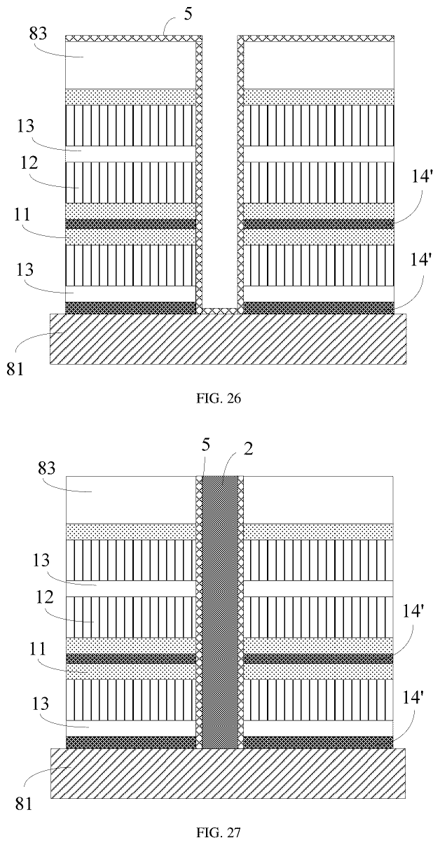

The product structure after processing by step S23 can be seen specifically in FIG. 26, which is a schematic view of the structure shown in FIG. 24b after processing by step S23. In some embodiments, step S23 specifically includes the following.

Step S231: depositing a first dielectric layer on the semiconductor substrate defining the word-line holes 4.

Specifically, one layer of the first dielectric layer is deposited within each word-line hole 4 and on a surface of the first hard mask layer 83 back from the substrate 81. The first dielectric layer within each word-line hole 4 covers surfaces of the parts of the drain region semiconductor strips 11, channel semiconductor strips 12, and source region semiconductor strips 13 that are exposed on both sides of the word-line hole 4. For example, in conjunction with FIG. 4, parts of the first stacked structures 1b′ and the second stacked structures 1b′ are exposed through word-line hole 4 of the first row and the second column (hereinafter referred to as a first word-line hole 4), the first dielectric layer in the first word-line hole 4 covers the part of the first column of semiconductor strip storage structures 1b exposed through the first word-line hole 4, and the part of the second column of semiconductor strip structures 1b exposed through the first word-line hole 4.

Step S232: depositing a charge storage layer on the first dielectric layer.

The charge storage layer is disposed on a side surface of the first dielectric layer back from a corresponding semiconductor strip structure 1b.

Step S233: depositing a second dielectric layer on the charge storage layer.

The second dielectric layer is disposed on a side surface of the charge storage layer back from the first dielectric layer.

At block S24: filling each of the word-line holes with a gate material to form multiple gate strips.

The product structure after processing by step S24 is specified in FIG. 5 and FIG. 27, where FIG. 27 is a schematic view of the structure shown in FIG. 26 after processing by step S24. As shown in FIG. 5, a projection of at least a part of each gate strip 2 coincides with a projection of a part of a corresponding channel semiconductor strip 12 in each memory subarray layer 1a on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, a part of the source region semiconductor strip 13 adjacent to the corresponding part of the channel semiconductor strip 12, and a part of the charge trapping storage structure form a memory cell.

As above, in the embodiments, the storage structure 5 is a charge trapping storage structure, such as an ONO type charge trapping storage structure, such that it can hold the electric charges injected into near the injection point. The electric charges can only move in the injection/removal direction (substantially perpendicular to the extension direction of the charge storage layer 52), and cannot move freely in the charge storage layer 52, especially not in the extension direction of the charge storage layer 52. For the charge trapping storage structure, the charge storage layer 52 is only required to have an insulating dielectric arranged on its front and back side, and the charge stored in each memory cell will be fixed near the injection point of the charge storage portion and will not move to the charge storage portion in other memory cells along the same layer of the charge storage layer 52. Therefore, in its corresponding manufacturing method, it is only necessary to form a first dielectric layer 51 and a second dielectric layer 53 on both sides of the charge storage layer 52, respectively, to separate the charge storage layer 52 from the drain region semiconductor strip 11, the channel semiconductor strip 12, the source region semiconductor strip 13 and the gate strip 2, and its manufacturing method is relatively simple.

Specifically, the above manufacturing method of memory devices may be configured to prepare the memory devices involved in the following embodiments. In conjunction with FIG. 1 to FIG. 4, the memory device includes a memory array 1, which includes multiple memory cells distributed in a three-dimensional array. The memory array 1 includes multiple stacked structures 1b′ distributed along the row direction X, each stacked structure 1b′ extending along the column direction Y, and each stacked structure 1b′ includes drain region semiconductor strips 11, channel semiconductor strips 12, and source region semiconductor strips 13 stacked along the height direction Z. Each drain region semiconductor strip 11, channel semiconductor strip 12, and source region semiconductor strip 13 extends along the column direction Y, and each drain region semiconductor strip 11, channel semiconductor strip 12, and source region semiconductor strip 13 is a single-crystal semiconductor strip.

Multiple gate strips 2 are arranged on each of two sides of each stacked structure 1b′ along the column direction Y, and each gate strip 2 extends along the height direction Z. In the height direction Z, a projection of at least a part of each gate strip 2 coincides with a projection of a part of a corresponding channel semiconductor strip 12 on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, and a part of the source region semiconductor strip 13 adjacent to the corresponding part of the channel semiconductor strip 12 form a memory cell. Specifically, a charge trapping storage structure is arranged between each gate strip 2 and corresponding drain region semiconductor strips 11, channel semiconductor strips 12, and source region semiconductor strips 13 in the multiple memory subarray layers 1a. The specific structure and function of the charge trapping storage structure, and the position relationship with the memory array 1, etc., can be found in the relevant description above.

Specifically, each stacked structure 1b′ includes multiple stacked substructures, each stacked substructure including a drain region semiconductor strip 11, a channel semiconductor strip 12, a source region semiconductor strip 13, a channel semiconductor strip 12, and a drain region semiconductor strip 11 stacked sequentially along the height direction Z to share the same source region semiconductor strip 13. Specifically, an interlayer isolation layer is arranged between two adjacent stacked substructures (i.e., the above-mentioned insulating isolation layer 14′) to isolate the two adjacent stacked substructures from each other.

Multiple isolation walls 3 distributed along the column direction Y are arranged on each side of each stacked structure 1b′, and each isolation wall 3 extends along the height direction Z and the row direction X to separate at least part of the two adjacent columns of the stacked structures 1b′. The isolation walls 3 further serve as support structures to support the two adjacent columns of the stacked structures 1b′ in the manufacturing process as shown above to facilitate the subsequent manufacturing process. Of course, after the manufacturing process, the isolation walls 3 may be further configured as support structures to support the two adjacent columns of the stacked structures 1b′. The isolation wall 3 near an edge of the memory device in the column direction Y is a T-shaped wall to completely isolate the two adjacent columns of the stacked structures 1b′. Of course, the isolation wall 3 at the edge in the column direction Y may take other shapes, such as extending in the column direction Y to the edge of the memory device in the column direction Y, etc., as long as it can completely isolate the two adjacent columns of the stacked structures 1b′ at the edge of the memory device in the column direction Y.

In the column direction Y, a gate strip 2 is arranged between two adjacent isolation walls 3 on the same column; parts of two adjacent columns of the stacked structures 1b share the same gate strip 2.

Other structures and functions of the memory device provided in the embodiments can be found in the specific description of the memory device provided in any of the above embodiments where the storage structure is a charge trapping storage structure, and will not be repeated herein.

The memory cell corresponding to the above manufacturing method includes: a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and along the height direction Z. In the height direction Z, a projection of the gate portion 2′at least partially coincides with a projection of the channel portion 12′on a projection plane, the projection plane extending along the height direction Z and the drain region portion 11′. A charge trapping storage structure portion is arranged between the gate portion 2′ and the drain region portion 11′, the channel portion 12′, and the source region portion 13′.

The specific structure and position of the charge trapping storage structure portion can be found in the above description. Other structures and functions of the memory cell can be found in the description of the memory cell with the charge trapping storage structure portion 5′ involved in the above embodiments, which will not be repeated herein.

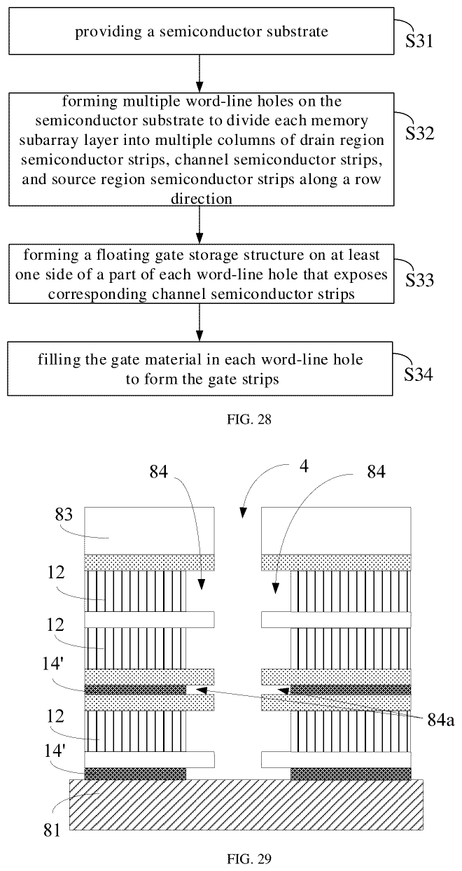

In other embodiments, referring FIG. 28, FIG. 28 is a flowchart of a manufacturing method of a memory device according to another embodiment of the present disclosure. A storage structure of the memory device herein is a floating gate storage structure. Another manufacturing method of a memory device is provided, which may be configured to prepare the memory device corresponding to FIG. 9 to FIG. 11 above. The method specifically includes operations at blocks illustrated in FIG. 23.

At step S31: providing a semiconductor substrate.

At step S32: forming multiple word-line holes on the semiconductor substrate to divide each memory subarray layer into multiple columns of drain region semiconductor strips, channel semiconductor strips, and source region semiconductor strips along a row direction.

The specific implementation process of step S31-step S32 is the same or similar to the specific implementation process of step S21-step S22 above, and can achieve the same or similar technical effect, as can be seen above, which will not be repeated herein.

It should be noted that the subsequent steps are the relevant steps after the first single-crystal sacrificial semiconductor layer 82 and the second single-crystal sacrificial semiconductor layer 14 are replaced by the insulating isolation layer 14′ using the word-line holes 4. The relevant process steps of the embodiments are the same as the relevant process steps of the previous embodiments, and will not be repeated herein.

At step S33: forming a floating gate storage structure on at least one side of a part of each word-line hole that exposes corresponding channel semiconductor strips.

Step S33 may specifically include the following.

Step S331: forming a first insulating dielectric layer 85a on at least one side of a part of each word-line hole 4 that exposes a corresponding drain region semiconductor strip 11, channel semiconductor strip 12, and source region semiconductor strip 13.

In some embodiments, step S331 specifically includes the following.

Step A: removing a part of the corresponding channel semiconductor strip 12 exposed by each word-line hole 4 to define a first recess 84.

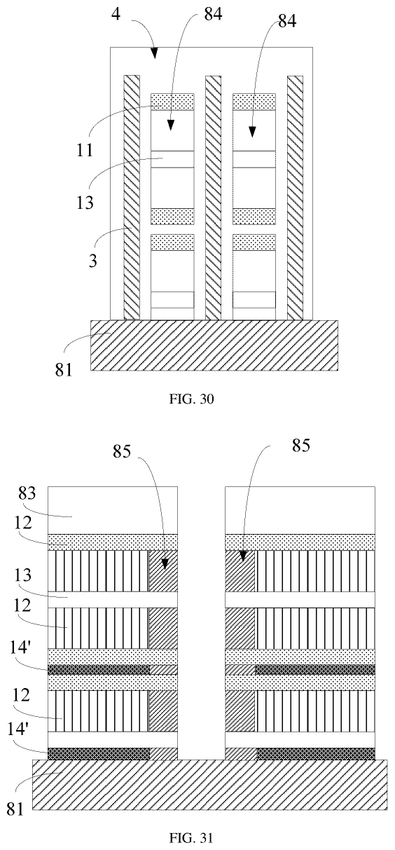

As shown in FIG. 29 and FIG. 30, FIG. 29 is a schematic view of the structure shown in FIG. 24b defining the first recess 84; FIG. 30 is a cross-sectional view of the product corresponding to FIG. 29 in another direction. Specifically, parts of the channel semiconductor strips 12 exposed on both sides of each word-line hole 4 may be removed by etching to define the first recesses 84, for example by acid etching.

In the embodiments, etching may be performed using an etchant with a high etch ratio for the channel semiconductor strips 12 and the insulating isolation layers 14′, and an etchant with a low etch ratio for the drain region semiconductor strips 11 and the source region semiconductor strips 13. For example, when the drain region semiconductor strips 11 and the source region semiconductor strips 13 are N-type semiconductor strips, and the channel semiconductor strips 12 are P-type semiconductor strips, then an etchant with a high etch ratio for the P-type semiconductor and with a low etch ratio for the N-type semiconductor may be applied for selective etching, such that only the parts of the channel semiconductor strips 12 and the insulating isolation layers 14′exposed on both sides of the word-line hole 4 are etched, thereby defining the first recesses 84.

It will be understood by those skilled in the art that when acid etching is performed on a part of the channel semiconductor strips 12, the etchant etches a part of the insulating isolation layers 14′ while etching the part of the channel semiconductor strips 12, defining third recesses 84a, as shown in FIG. 29. Although this etching is unfavorable, the third recess 84a will be backfilled in subsequent steps, in particular with the same material as the insulating isolation layer 14′.

Although in FIG. 29, the third recesses 84a are formed by etching, in other embodiments, the third recesses 84a may not be necessarily defined formed when the etching selection ratio is well controlled.

Step B: filling the multiple first recesses 84 each with a first insulating dielectric 85.

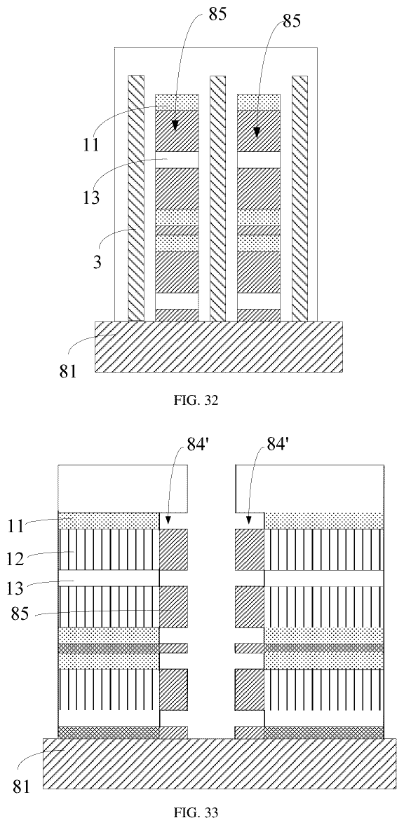

As shown in FIG. 31 and FIG. 32, FIG. 31 is a schematic view of the formation of the first insulating dielectric 85 on the structure shown in FIG. 29; FIG. 32 is a cross-sectional view in the F-direction of the product corresponding to FIG. 31. Specifically, the first insulating dielectric 85 may be filled in the first recesses 84 by deposition. The third recesses 84a may be also filled with the first insulating dielectric 85 by means of deposition. The first insulating dielectric 85 may be the same material as the insulating layer 14′, e.g., silicon oxide.

When the first recesses 84 are filled with the first insulating dielectric 85, the third recesses 84a, formed by etching off parts of the insulating layers 14′, are also filled with the first insulating dielectric 85. Since the material of the first insulating dielectric 85 is silicon oxide, which is the same material as the insulating isolation layers 14′, the device performance will not be affected.

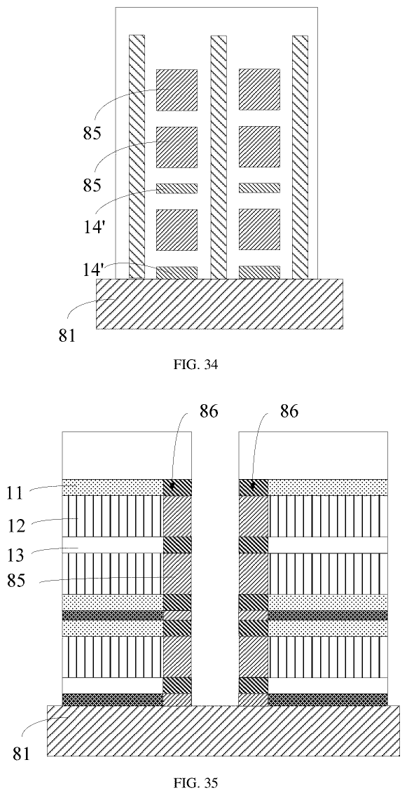

In some embodiments, referring to FIG. 33 to FIG. 35, FIG. 33 is a schematic view of the structure shown in FIG. 31 after defining the second recesses 84′; FIG. 34 is a cross-sectional view of the F-direction of the product corresponding to FIG. 33; and FIG. 35 is a schematic view of the structure shown in FIG. 33 after forming a second insulating dielectric 86. After step B, the method may further include the following.

Step C: removing parts of corresponding drain region semiconductor strips 11 and parts of corresponding source region semiconductor strips 13 exposed on both sides of each word-line hole 4 to define multiple second recesses 84′; where each second recess 84′ exposes at least a part of a corresponding first insulating dielectric 85.

The second recesses 84′ may be defined by etching. A vertical cross-sectional view of the product after removing the parts of the drain region semiconductor strips 11 and the parts of the source region semiconductor strips 13 exposed on both sides of each word-line hole 4 to define the multiple second recesses 84′ can be seen in FIG. 33. Specifically, in this step, an etchant with a low etch ratio for the channel semiconductor strips 12 and with a high etch ratio for the drain region semiconductor strips 11 and source region semiconductor strips 13 may be applied. For example, when the drain region semiconductor strip 11 and the source region semiconductor strip 13 are N-type semiconductor strips, and the channel semiconductor strip 12 is P-type semiconductor strip, an etchant with a high etch ratio for the N-type semiconductor and with a low etch ratio for the P-type semiconductor may be applied for selective etching, such that only the parts of the drain region semiconductor strips 11 and the parts of the source region semiconductor strips 13 exposed on both sides of the exposed line hole 4 are etched to define the second recesses 84′.

Step D: forming a second insulating dielectric 86 in each second recess 84′.

The second insulating dielectric 86 may be formed by deposition. The second insulating dielectric 86 may be made of silicon nitride. After step D, step E is performed.

Step E: removing the first insulating dielectric 85 in the first recesses 84 to empty the first recesses 84, and depositing a first insulating dielectric layer 85a on walls of the corresponding first recesses 84.

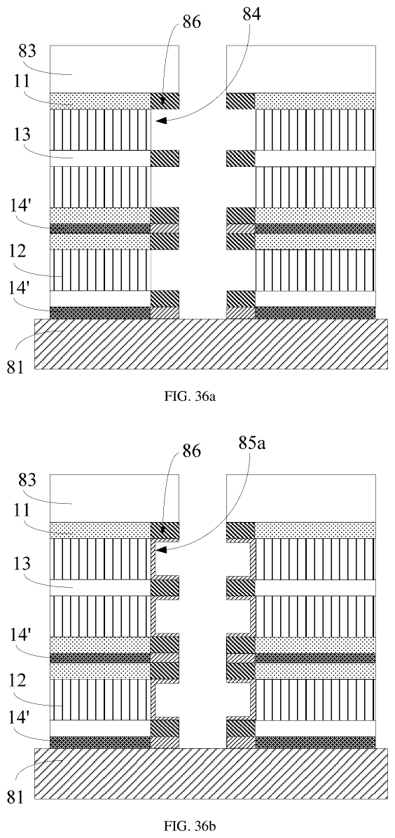

As shown in FIG. 36a and FIG. 36b, FIG. 36a is a schematic view of the structure after removing the first insulating dielectric 85 in the first recesses 84; FIG. 36b is a schematic view of the structure shown in FIG. 35 forming the first insulating dielectric layer 85a. In this step, etching may be performed using an etchant with a high etch ratio for the first insulating dielectric 85 and with a low etch ratio for the second insulating dielectric 86, e.g., an etchant with a high etch ratio for silicon oxide and with a low etch ratio for silicon nitride. Further, by controlling the amount of etchant, etch speed, and etch time to etch off the first insulating dielectric 85. Thereafter, a first insulating dielectric layer 85a is formed by deposition or growth in the first recesses 84 where the first insulating dielectric 85 was etched off; the first insulating dielectric layer 85a has a gate-shaped (U-shaped) cross-section for defining a floating gate slot.

Step S332: forming a floating gate 54 on a side surface of a part of the first insulating dielectric layer 85a back from a corresponding channel semiconductor strip 12.

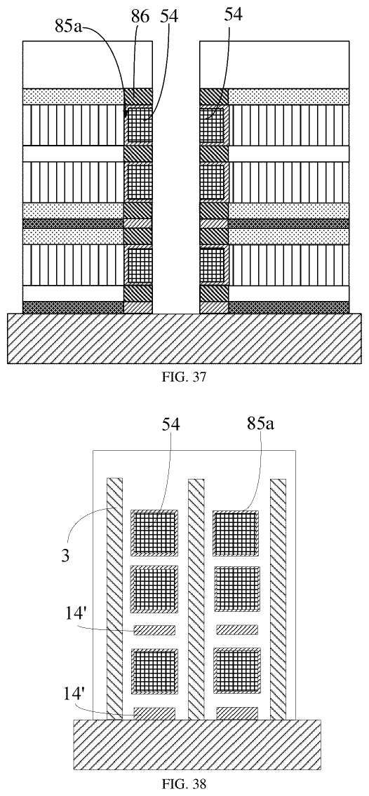

The structure of the product after step S332 can be seen in FIG. 37 and FIG. 38. FIG. 37 is a schematic view of the structure shown in FIG. 36b forming the floating gates 54; FIG. 38 is a cross-sectional view of the product corresponding to FIG. 37 in another direction.

Specifically, a floating gate material may be deposited in the floating gate slots to form the floating gate 54, and the floating gate material may include polycrystalline silicon material.

Step S333: forming a second insulating dielectric layer 85b on a side wall of each word-line hole, and the second insulating dielectric layer 85b cooperates with the first insulating dielectric layer 85a to wrap any surface of each floating gate 54.

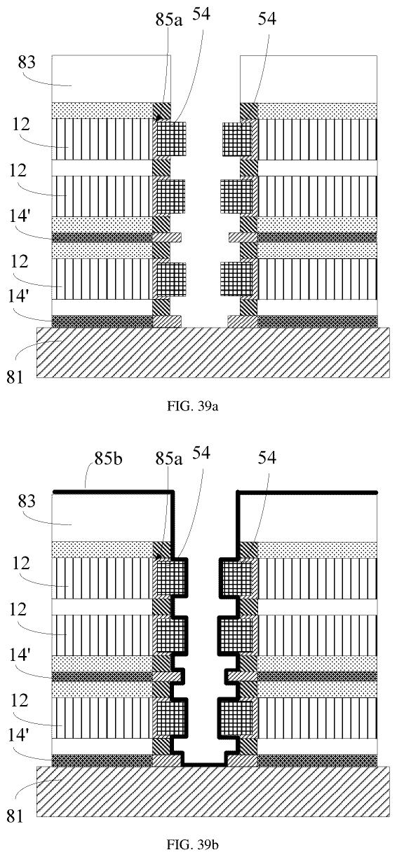

In some embodiments, referring to FIG. 39a, FIG. 39a is a schematic view of the structure after removing a part of the first hard mask layer around each word-line hole and a part of the second insulating dielectric in each second recess. Step S333 may specifically include the following.

Step 3331: removing a part of the first hard mask layer 83 around each word-line hole 4 and a part of the second insulating dielectric 86 in each second recess 84′, to widen the word-line hole 4 and expose at least a part of each floating gate 54.

It will be understood that after step 3331, the first insulating dielectric layer 85a wraps only a part of the floating gate 54.

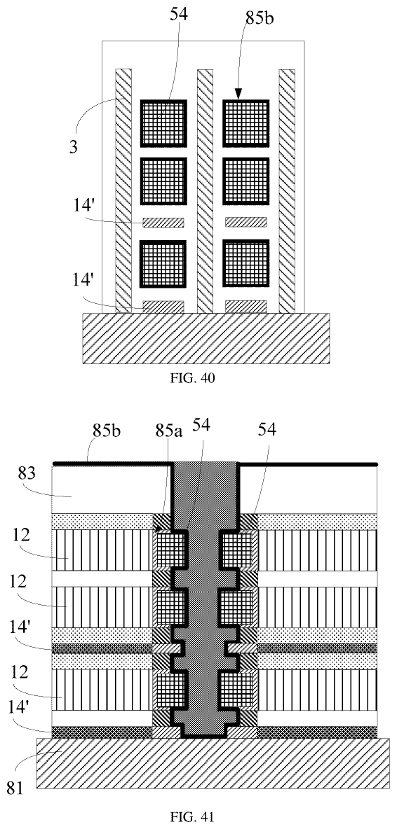

As shown in FIG. 39b and FIG. 40, FIG. 39b is a schematic view of the second insulating dielectric layer 85b; FIG. 40 is a cross-sectional view of the F-direction of the product corresponding to FIG. 39b.

Step 3332: forming the second insulating dielectric layer 85b on the side wall of each of widened word-line hole 4 such that the second insulating dielectric layer 85b wraps around an exposed portion of each floating gate 54.

As can be seen in FIG. 39b, the first insulating dielectric layer 85a and the second insulating dielectric layer 85b completely wrap and isolate various surfaces of the floating gates 54. The second insulating dielectric layer 85b includes a multilayer structure including a silicon oxide layer, a silicon nitride layer, and another silicon oxide layer. By widening the word-line hole 4, it is ensured that the second insulating dielectric layer 85b partially covers each of five surfaces of the floating gate 54. In this way, the second insulating dielectric layer 85b and the first insulating dielectric layer 85a can wrap any surface of the floating gate 54. Specifically, as shown in FIG. 39b, a part of the second insulating dielectric layer 85b covers the five surfaces of each floating gate 54, where four of each five surfaces of the floating gate 54 are at least partially covered by the part of the second insulating dielectric layer 85b and the remaining one of the five surfaces is fully covered by the second insulating dielectric layer 85b. Further, the first insulating dielectric layer 85a, in addition to covering the surface of the floating gate 54 near the channel semiconductor strip 12, also covers parts of the other four surfaces of the floating gate 54. Therefore, the first insulating dielectric layer 85a, in conjunction with the second insulating dielectric layer 85b, may wrap all surfaces of the floating gates 54.

Step S34: filling the gate material in each word-line hole to form the gate strips.

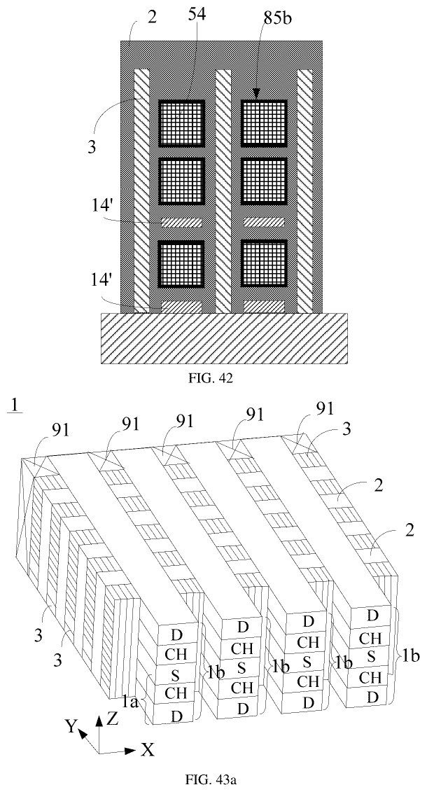

The structure of the product after step S34 can be seen in FIG. 41 and FIG. 42, FIG. 41 is a schematic view of the formation of gate strips 2; FIG. 42 is a cross-sectional view of the product corresponding to FIG. 41 in another direction. The gate strip 2 wraps all other surfaces of the floating gate 54 other than those wrapped by the first insulating dielectric layer 85a to improve the coupling rate. That is, a surface of the gate strip 2 extends in the extension direction of the second insulating dielectric layer 85b, thereby sandwiching the second insulating dielectric layer 85b and wrapping the five surfaces of the floating gate 54, and four of the five surfaces of the floating gate 54 are at least partially wrapped by the gate strip 2 through the second insulating dielectric layer 85b. The specific structure of each memory cell in the memory device produced by this manufacturing method can be seen in FIG. 10.

A projection of at least a part of each gate strip 2 coincides with a projection of a part of a corresponding channel semiconductor strip 12 in each memory subarray layer 1a on a projection plane, the projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, a part of the source region semiconductor strip 13 adjacent to the corresponding part of the channel semiconductor strip 12, and a part of a corresponding floating gate storage structure, form a memory cell.

In the embodiments, the storage structure 5 is a floating gate storage structure, as above, and the floating gate storage structure is characterized by the fact that the charge injected in can be uniformly distributed in the entire floating gate 54, and the charges can move not only in the injection/removal direction (substantially perpendicular to the extension direction of the floating gate), but also in the floating gate 54, particularly in the extension direction of the floating gate 54. Therefore, in the floating gate storage structure, the floating gate 54 of each memory cell is independent, and each surface of each floating gate 54 is required to be covered by an insulating dielectric to be isolated from each other, thereby preventing the charges stored in the floating gates 54 in one memory cell from moving to the floating gates 54 in other memory cells. Therefore, in the manufacturing method thereof, the floating gate 54 of each memory cell is independent, and the insulating dielectric formed by the first insulating dielectric layer 85a and the second insulating dielectric layer 85b can completely wrap and isolate the various surfaces of the floating gates 54, such that the floating gates 54 of each memory cell are independent and the charge stored in each floating gate 54 cannot move to the floating gates 54 of other memory cells.

Specifically, the manufacturing method may be configured to prepare the memory device involved in the following embodiments. The memory device includes a memory array 1, which includes multiple memory cells distributed in a three-dimensional array. The memory array 1 includes multiple stacked structures 1b′ distributed along the row direction X, each stacked structure 1b′ extending along the column direction Y, and each stacked structure 1b′ includes drain region semiconductor strips 11, channel semiconductor strips 12, and source region semiconductor strips 13 stacked along the height direction Z. Each drain region semiconductor strip 11, channel semiconductor strip 12, and source region semiconductor strip 13 extends along the column direction Y, and each drain region semiconductor strip 11, channel semiconductor strip 12, and source region semiconductor strip 13 is a single-crystal semiconductor strip.

Multiple gate strips 2 are arranged on each of two sides of each stacked structure 1b′ along the column direction Y, and each gate strip 2 extends along the height direction Z. In the height direction Z, a projection of at least a part of each gate strip 2 coincides with a projection of a part of a corresponding channel semiconductor strip 12 on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, and a part of the source region semiconductor strip 13 adjacent to the corresponding part of the channel semiconductor strip 12 form a memory cell. Specifically, a floating gate storage structure is arranged between each gate strip 2 and corresponding drain region semiconductor strips 11, channel semiconductor strips 12, and source region semiconductor strips 13 in the multiple memory subarray layers 1a. The floating gate storage structure includes multiple first insulating dielectric layers 85a, multiple floating gates 54, and the second insulating dielectric layer 85b. Each first insulating dielectric layer 85a is disposed between at least a corresponding channel semiconductor strip 12 and a corresponding floating gate 54, the floating gate 54 is located disposed a corresponding first insulating dielectric layer 85a and the second insulating dielectric layer 85b, and the second dielectric layer 85b is disposed between the floating gates 54 and the gate strip 2.

Specifically, each stacked structure 1b′ includes multiple stacked substructures, each stacked substructure including a drain region semiconductor strip 11, a channel semiconductor strip 12, a source region semiconductor strip 13, a channel semiconductor strip 12, and a drain region semiconductor strip 11 stacked sequentially along the height direction Z to share the same source region semiconductor strip 13. Specifically, an interlayer isolation layer is arranged between two adjacent stacked substructures to isolate the two adjacent stacked substructures from each other.

Multiple isolation walls 3 distributed along the column direction Y are arranged on each side of each stacked structure 1b′, and each isolation wall 3 extends along the height direction Z and the row direction X to separate at least part of the two adjacent columns of the stacked structures 1b′. The isolation walls 3 further serve as support structures to support the two adjacent columns of the stacked structures 1b′. The isolation wall 3 near an edge of the memory device in the column direction Y is a T-shaped wall to completely isolate the two adjacent columns of the stacked structures 1b′.

In the column direction Y, a gate strip 2 is arranged between two adjacent isolation walls 3 on the same column; parts of two adjacent columns of the stacked structures 1b′ share the same gate strip 2.

Other structures and functions of the memory device provided in the embodiments can be found in the specific description of the memory device provided in any of the above embodiments where the storage structure is a floating gate storage structure, and will not be repeated herein.

The memory cell corresponding to the above manufacturing method includes: a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and along the height direction Z. In the height direction Z, a projection of the gate portion 2′ and a projection the channel portion 12′ on a projection plane extending along the height direction Z at least partially coincide, the projection plane being located on a side of the drain region portion 11′, the channel portion 12′, and the source region portion 13′ and extending along the height direction Z and the column direction Y. A floating gate storage structure portions arranged between the gate portion 2′ and the drain region portion 11′, the channel portion 12′, and the source region portion 13′.

The floating gate storage structure portion specifically includes a corresponding first insulating dielectric layer 85a, a corresponding floating gate 54, and a part of the second insulating dielectric layer 85b. The first insulating dielectric layer 85a is disposed between the channel portion 12′ and the floating gate 54, the floating gate 54 is disposed between the first insulating dielectric layer 85a and the part of the second insulating dielectric layer 85b, and the part of the second insulating dielectric layer 85b is disposed between the floating gate 54 and the gate strip 2. The part of the second insulating dielectric layer 85b covers five surfaces of the floating gate 54. One of the five surfaces of the floating gate 54 is fully covered by the second insulating dielectric layer 85b. The part of the second insulating dielectric layer 85b includes a multilayer structure including a part of a silicon oxide layer, a part of a silicon nitride layer, and a part of another silicon oxide layer.

Other structures and functions of the memory cell can be found in the description of the memory cell for which the storage structure portion 5′ is a floating gate storage structure portion involved in the above-described embodiments, and will not be repeated herein.

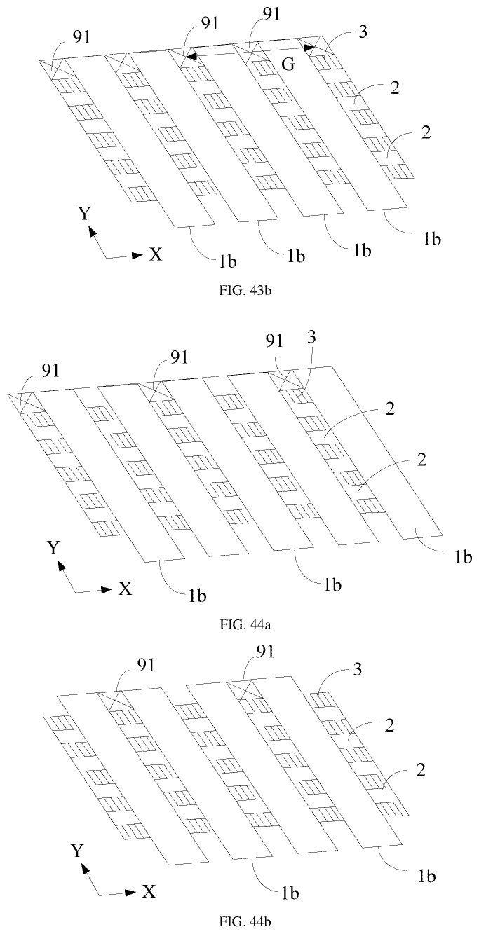

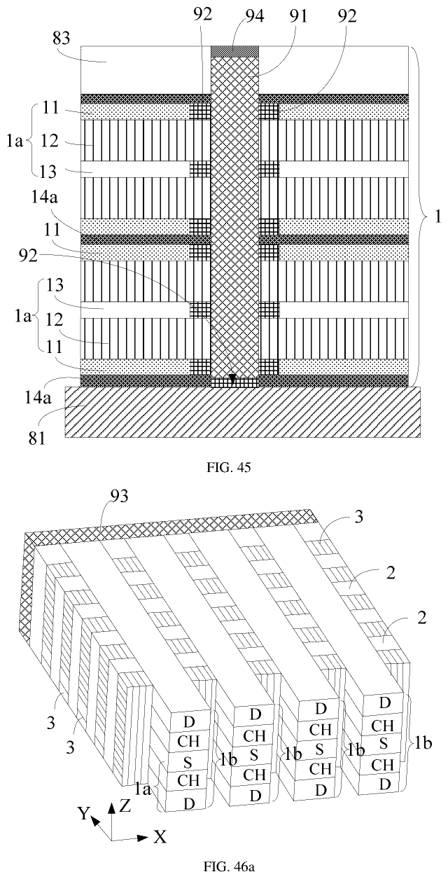

As shown in FIG. 1 to FIG. 45, FIG. 43a is a perspective structural schematic view of a memory array according to another embodiment of the present disclosure; FIG. 43b is a schematic sketch of a plan view of a memory device corresponding to the memory array shown in FIG. 43a; FIG. 44a and FIG. 44b are distribution schematic views of channel connection posts according to an embodiment of the present disclosure; FIG. 45 is a cross-sectional view along G-direction of a product corresponding to FIG. 43b. In some embodiments, another memory device is provided. The difference between this memory device and the memory device provided in any embodiments mentioned above is that: in this memory device, the channel semiconductor strips 12 in the memory arrays 1 are not led out to the surface of the memory arrays 1 through the well region connection lines 12a (as shown in FIG. 12) connected to the channel semiconductor strips 12.

Specifically, as shown in FIG. 43a to FIG. 45, each memory array 1 of the memory device further includes a channel connection structure. The channel connection structure extends along the height direction Z. The channel connection structure is in contact with each channel semiconductor strip 12 in each column of semiconductor strip structures 1b, so that each channel semiconductor strip 12 in the column of semiconductor strip structures 1b may be led out to the surface of the memory array 1 through the channel connection structure. Further, the channel connection structure is insulated from each drain region semiconductor strip 11 and each source region semiconductor strip 13 in each column of semiconductor strip structures 1b to prevent short-circuits. Each channel semiconductor strip 12 may be led out to the surface of the memory array 1 through the channel connection structure. The channel semiconductor strip refers to a channel semiconductor strip of an effective memory cell in the memory array 1, excluding a channel semiconductor strip serves as a dummy memory cell or a channel semiconductor strip of other memory cells without storage functions.

In some embodiments, the channel connection structure includes multiple channel connection posts 91. At least one side of each column of semiconductor strip structures 1b is arranged with a corresponding channel connection post 91. The channel connection posts 91 extend respectively along the height direction Z. At least a portion of the channel connection post 91 is in contact with each channel semiconductor strip 12 in an adjacent semiconductor strip structures 1b, so that each channel semiconductor strip 12 in the column of semiconductor strip structures 1b may be led out to the surface of the memory array 1 through the channel connection post 91. In some embodiments, each of the channel connection posts 91 may be respectively connected to an independent well region voltage line to apply a well region voltage to each channel semiconductor strip 12. Of course, all channel connection posts 91 may also be respectively connected to the same common well region line to uniformly apply a well region voltage to all channel semiconductor strips 12 in the memory array 1 through the common well region line. Further, the channel connection post 91 is insulated from each drain region semiconductor strip 11 and each source region semiconductor strip 13 in the adjacent column of semiconductor strip structures 1b to prevent short-circuits.

Compared with the scheme in which the channel semiconductor strips 12 in each column of semiconductor strip structures 1b are respectively led out to the surface of the memory array 1 through the well region connection line 12a, the above-mentioned scheme of the present disclosure only needs one channel connection post 91 to lead out all the channel semiconductor strips 12 in the column of semiconductor strip structures 1b, which greatly reduces areas occupied by the channel connection posts 91 on the surface of the memory array 1, and reduces the process difficulty and cost.

In specific embodiments, in conjunction with FIG. 45, each drain region semiconductor strip 11 and source region semiconductor strip 13 in each column of semiconductor strip structures 1b are spaced apart from an adjacent channel connection post 91. A first insulating material 92 is filled between each drain region semiconductor strip 11 and each source region semiconductor strip 13 in each column of semiconductor strip 1b and a corresponding adjacent channel connection post 91, so that the channel connection post 91 is insulated from each drain region semiconductor strip 11 and source region semiconductor strip 13 in each adjacent column of semiconductor strip structures 1b. The first insulating material 92 may be silicon oxide.

As shown in FIG. 43a or FIG. 43b, corresponding channel connection posts 91 may be arranged on two sides of each column of semiconductor strip structures 1b respectively, and two adjacent columns of semiconductor strip structures 1b share a corresponding same channel connection post 91.

In some embodiments, as shown in FIG. 44a, a corresponding channel connection post 91 is arranged on each odd column of semiconductor strip structures 1b at a same side (such as the left side) thereof. In this way, from left to right, a first column of channel semiconductor strip structures 1b may be applied with a well region voltage through a first channel connection post 91; a second and a third columns of channel semiconductor strip structures 1b may be both applied with a well region voltage through a second channel connection post 91; a fourth and a fifth columns of channel semiconductor strip structures 1b may be both applied with a well region voltage through a third channel connection post 91.

Alternatively, as shown in FIG. 44b, a corresponding channel connection post 91 is arranged on each even column of semiconductor strip structures 1b at a same side (such as the left side) thereof. In this way, from left to right, a first and a second columns of channel semiconductor strip structures 1b may be both applied with a well region voltage through a first channel connection post 91; a third and a fourth columns of channel semiconductor strip structures 1b may be both applied with a well region voltage through a second channel connection post 91.

In conjunction with FIG. 44b, the multiple channel connection posts 91 are distributed in a straight line along the row direction X. Of course, the multiple channel connection posts 91 may also be arranged in a staggered manner along the row direction X, such as in a zigzag distribution.

In some embodiments, an end of each of the channel connection posts 91 away from the substrate 81 is exposed through the multiple memory subarray layers. The ends of the channel connection posts 91 are connected together through a common connection structure, so as to be uniformly applied a well region voltage through the common connection structure.

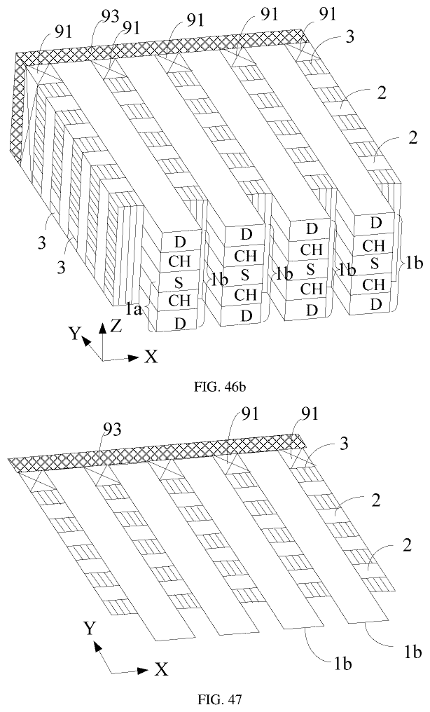

In some embodiments, as shown in FIG. 46a to FIG. 47, FIG. 46a and FIG. 46b are perspective structural schematic views of a memory array 1 according to another embodiment of the present disclosure; FIG. 47 is a schematic sketch of a plan view of a memory device corresponding to the memory array shown in FIG. 46b. As shown in FIG. 46a, the channel connection structure includes a channel connection wall 93. The channel connection wall 93 is arranged at a position of an end edge of the semiconductor strip structures 1b of a corresponding memory array 1, and extends along the height direction Z and the row direction X. The channel connection wall 93 is in contact with each channel semiconductor strip 12 in each column of semiconductor strip structures 1b, so that each channel semiconductor strip 12 in the column of semiconductor strip structures 1b may be led out to the surface of the memory array 1 through the channel connection wall 93. Further, the channel connection wall 93 is insulated from each drain region semiconductor strip 12 and each source region semiconductor strip 13 in the column of semiconductor strip structures 1b to prevent short-circuits.

In specific embodiments, each drain region semiconductor strip 11 and source region semiconductor strip 13 in each column of semiconductor strip structures 1b are spaced apart from an adjacent channel connection wall 93. The first insulating material 92 is filled between each drain region semiconductor strip 11 and each source region semiconductor strip 13 in each column of semiconductor strip structures 1b and the corresponding adjacent channel connection wall 93, so that the channel connection wall 93 is insulated from each drain region semiconductor strip 11 and each source region semiconductor strip 13 in each adjacent column of semiconductor strip structures 1b. The first insulating material 92 may be silicon oxide.

In specific embodiments, as shown in FIG. 46b, the channel connection structure includes multiple channel connection posts 91 and a channel connection wall 93. Specifically, each of the channel connection posts 91 may be connected to the channel connection wall 93, making the multiple channel connection posts 91 to be connected together through the channel connection wall 93. In some embodiments, the common well region line may be specifically connected to the channel connection wall 93 to uniformly apply a well region voltage to all the channel semiconductor strips 12 in the memory device.

As shown in FIG. 46b, along the column direction Y, corresponding channel connection posts 91 are arranged on both sides of the end of the column of semiconductor strip structures 1b respectively. The channel connection post 91 extends along the column direction Y to the position of the end edge of the column of semiconductor strip structures 1b. The channel connection wall 93 is arranged at the position of the end edge of the column of semiconductor strip structures 1b, extends along the height direction Z and the row direction X, and is in contact with all the channel connection posts 91, thereby connecting all the channel connection posts 91 in the memory array 1 together. The channel connection posts 91 and the channel connection wall 93 may be integrally formed, and the process is simple.

Of course, those skilled in the art can understand that each of the channel connection posts 91 in the memory array 1 may also be independent of each other to respectively apply a well region voltage to the channel semiconductor strips 12 in each column of semiconductor strip structures 1b. For example, similar to the above, an end of each of the channel connection posts 91 away from the substrate 81 serves as a well region connection terminal, which is configured to receive a separate well region voltage.

Specifically, the channel connection posts 91 and/or the channel connection wall 93 are made of a conductive material. Materials of the channel connection posts 91 and/or the channel connection wall 93 include polysilicon and/or metal. In some embodiments, the materials of the channel connection posts 91 and/or the channel connection wall 93 include polysilicon. In some embodiments, as shown in FIG. 45, each memory array 1 further includes a connection layer 94. The connection layer 94 is arranged on surfaces of sides of the channel connection posts 91 and/or the channel connection wall 93 away from the substrate 81. An electrical conductivity of the connection layer 94 is better than an electrical conductivity of the channel connection posts 91 and/or the channel connection wall 93. In some embodiments, a separate well region line or a common well region line may be specifically connected to the connection layer 94 to apply a well region voltage to the channel semiconductor strips 12. The connection layer 94 with better electrical conductivity is used to connect with the well region line in the above-mentioned embodiments, because the impedance of the connection layer 94 is smaller, more time is saved during signal transmission, making the response speed of the memory device faster.

Specifically, a material of the connection layer 94 includes a metal silicide.

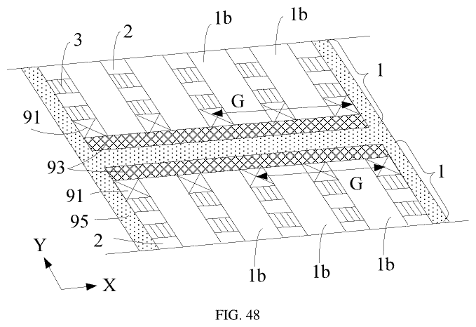

As shown in FIG. 48, FIG. 48 is a partial top view of a memory device according to an embodiment of the present disclosure. In some embodiments, a number of the memory arrays 1 in the memory device is multiple. The channel connection structure in each memory array 1 is located at the position of the end edge of the memory array 1, so that during the manufacturing process, the channel connection structures of two memory arrays 1 may be produced simultaneously, and then separated by subsequent processes. A second insulating material 95 is filled between two adjacent memory arrays 1 to isolate the channel connection structures between the two adjacent memory arrays 1. A material of the second insulating material 95 may also be silicon oxide. The channel connection structure includes the channel connection posts 91 and/or the channel connection wall 93.

Of course, in other embodiments, the channel connection wall 93 and/or the channel connection posts 91 may also be arranged in a middle position of each memory array 1. Those skilled in the art can understand that during the manufacturing process of the channel connection structure corresponding to some embodiments, the channel connection structure corresponding to each memory array 1 needs to be produced separately.

In specific embodiments, each memory array 1 includes multiple channel connection posts 91 and a channel connection wall 93. The multiple channel connection posts 91 are respectively in contact with the channel connection wall 93. The channel connection wall 93 is located at an end edge of the memory array 1, and extends along the height direction Z and the row direction X. The second insulating material 95 is specifically filled between the channel connection structures of two adjacent memory arrays 1. Further, as shown in FIG. 48, the second insulating material 95 also surrounds other surfaces of the memory array 1, and the second insulating material 95 on each surface extends along the height direction Z and the column direction Y or the row direction X.

The memory device provided in some embodiments is provided with the substrate 81, at least one memory array 1 is arranged on the substrate 81, and each memory array 1 includes multiple memory subarray layers 1a sequentially stacked along the height direction Z. Each memory subarray layer 1a includes the drain region semiconductor layer, the channel semiconductor layer, and the source region semiconductor layer stacked along the height direction Z. In each memory subarray layer 1a, the drain region semiconductor layer includes multiple drain region semiconductor strips 11 spaced apart along the row direction X, the channel semiconductor layer include multiple channel semiconductor strips 12 spaced apart along the row direction X, and the source region semiconductor layer include multiple source region semiconductor strips 13 spaced apart along the row direction X. Each drain region semiconductor strip 11, channel semiconductor strip 12, and source region semiconductor strip 13 extends along the column direction Y. The column of drain region semiconductor strips 11, channel semiconductor strips 12, and source region semiconductor strips 13 in multiple memory subarray layers 1a is defined as the column of semiconductor strip structures 1b. Compared with a two-dimensional memory device, the storage density of the memory device is higher. In addition, each memory array 1 further includes the channel connection structure. The channel connection structure extends along the height direction Z. The channel connection structure is in contact with each channel semiconductor strip 12 in each column of semiconductor strip structures 1b, so that each channel semiconductor strip 12 in the column of semiconductor strip structures 1b may be led out to the surface of the memory array 1 through the channel connection structure. The channel connection structure is insulated from each drain region semiconductor strip 11 and each source region semiconductor strip 13 to prevent short-circuits. Compared with the scheme in which each channel semiconductor strip 12 in each column of semiconductor strip structures 1b is respectively led out to the surface of the memory array 1 through the well region connection line 12a, this scheme only needs the channel connection structure to lead out all the channel semiconductor strips 12 in the column of semiconductor strip structures 1b, which greatly reduces the area occupied by the channel connection structure on the surface of the memory array 1, and reduces the process difficulty and cost.

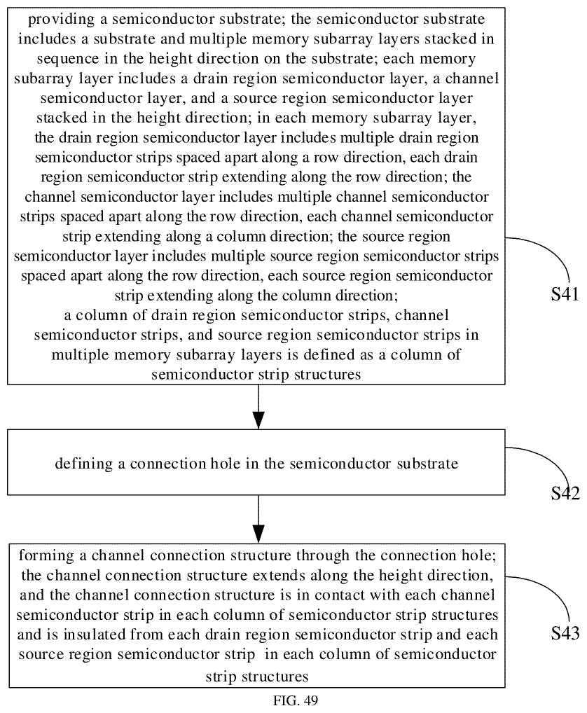

As shown in FIG. 49, FIG. 49 is a flowchart of a manufacturing method of a memory device according to further another embodiment of the present disclosure. In some embodiments, a manufacturing method of a memory device is provided, which may be configured to produce the memory device provided in FIG. 43a to FIG. 48 of the above-mentioned embodiments. The method specifically includes operations at blocks illustrated in FIG. 49.

Step S41: providing a semiconductor substrate. The semiconductor substrate includes a substrate and multiple memory subarray layers stacked in sequence in the height direction on the substrate. Each memory subarray layer includes a drain region semiconductor layer, a channel semiconductor layer, and a source region semiconductor layer stacked in the height direction. In each memory subarray layer, the drain region semiconductor layer, the channel semiconductor layer, and the source region semiconductor layer respectively include multiple drain region semiconductor strips, multiple channel semiconductor strips, and multiple source region semiconductor strips spaced apart along a row direction. Each of the drain region semiconductor strips, each of the channel semiconductor strips, and each of the source region semiconductor strips extending along the row direction respectively. A column of drain region semiconductor strips, channel semiconductor strips, and source region semiconductor strips in multiple memory subarray layers is defined as a column of semiconductor strip structures.

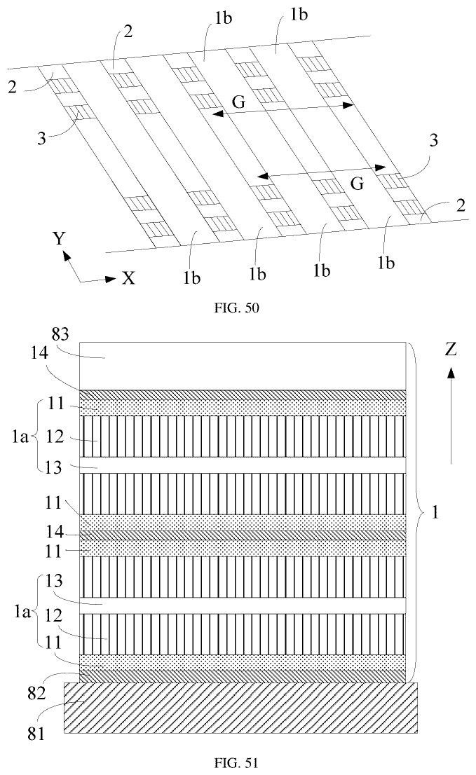

As shown in FIG. 50 and FIG. 51, FIG. 50 is a top view of the semiconductor substrate according to an embodiment of the present disclosure; FIG. 51 is a cross-sectional view along G-direction of a product shown in FIG. 50. The semiconductor substrate includes the substrate 81, a first single-crystal sacrificial semiconductor layer 82 arranged on the substrate 81, multiple memory subarray layers 1a and second single-crystal sacrificial semiconductor layers 14 alternately formed on the first single-crystal sacrificial semiconductor layer 82, and a first hard mask layer 83 arranged on a surface of a side of the second single-crystal sacrificial semiconductor layer 14 away from the substrate 81. Two common-source memory subarray layers 1a may be alternately arranged with the second single-crystal sacrificial semiconductor layer 14 to achieve a higher storage density, or one memory subarray layer 1a may be alternately arranged with the second single-crystal sacrificial semiconductor layer 14.

The multiple memory subarray layers 1a are stacked in sequence along the height direction Z perpendicular to the substrate 81. Each memory subarray layer 1a includes the drain region semiconductor layer, the channel semiconductor layer, and the source region semiconductor layer stacked along the height direction Z. In each memory subarray layer 1a, the drain region semiconductor layer include multiple drain region semiconductor strips 11 spaced apart along the row direction X, the channel semiconductor layer includes multiple channel semiconductor strips 12 spaced apart along the row direction X, and the source region semiconductor layer includes multiple source region semiconductor strips 13 spaced apart along the row direction X. Each drain region semiconductor strip 11, channel semiconductor strip 12, and source region semiconductor strip 13 extends along the column direction Y. A column of drain region semiconductor strips 11, channel semiconductor strips 12, and source region semiconductor strips 14 in multiple memory subarray layers is defined as the column of semiconductor strip structures 1b. Multiple gate strips 2 spaced apart along the column direction Y are arranged between two adjacent columns of drain region semiconductor strips 11, channel semiconductor strips 12, and source region semiconductor strips 13, and each gate strip 2 extends along the height direction Z.

The semiconductor substrate is also arranged with multiple isolation walls 3 and multiple gate strips 2. The isolation walls 3 and the gate strips 2 respectively extend along the height direction Z to the surface of the substrate 81. For the other specific structures and manufacturing methods of the semiconductor substrate, please refer to the relevant descriptions in the specific structures and manufacturing methods of the memory device provided in any of the above-mentioned embodiments, and details will not be repeated here.

Step S42: defining a connection hole in the semiconductor substrate.

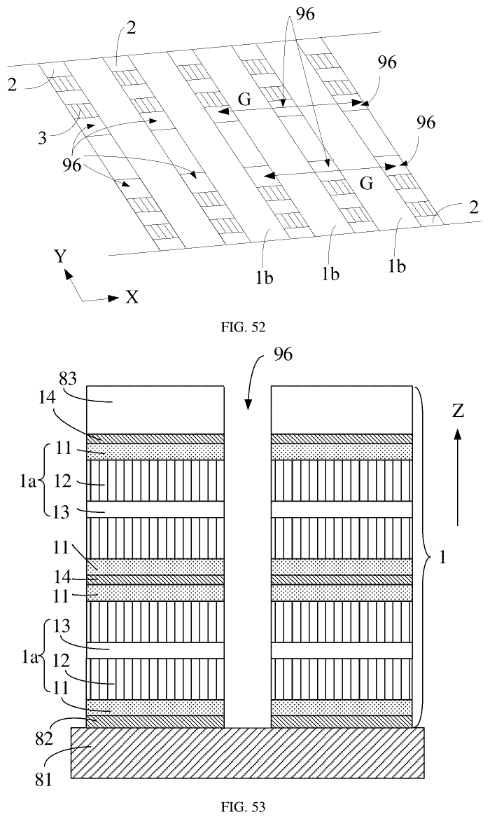

As shown in FIG. 52 and FIG. 53, FIG. 52 is a top view of the semiconductor substrate shown in FIG. 50 after defining the connection hole; FIG. 53 is a cross-sectional view along G-direction of a product shown in FIG. 52. The connection hole may be defined in the semiconductor substrate at positions different from the gate strips 2 and the isolation walls 3 by means of etching. In some embodiments, the connection hole includes first-type connection holes 96. The first-type connection holes 96, in cooperation with the gate strips 2 and the isolation walls 3, divide each memory subarray layer 1a into multiple columns of drain region semiconductor strips 11, channel semiconductor strips 12, and source region semiconductor strips 13.

Specifically, each first-type connection hole 96 extends along the height direction Z to the surface of the substrate 81. Each first-type connection hole 96 exposes parts of each drain region semiconductor strip 11, channel semiconductor strip 12, and source region semiconductor strip 13 in an adjacent semiconductor strip structures 1b. The first-type connection holes 96 are configured to form the channel connection posts 91.

Step S43: forming a channel connection structure through the connection hole. The channel connection structure extends along the height direction, and the channel connection structure is in contact with each channel semiconductor strip in each column of semiconductor strip structures and is insulated from each drain region semiconductor strip and each source region semiconductor strip in each column of semiconductor strip structures.

As shown in FIG. 54 to FIG. 59, FIG. 54 to FIG. 59 are schematic views of structures at specific operations of forming the channel connection posts 91 through the first-type connection holes 96. Step S43 specifically includes the following operations.

Step S431: removing the first single-crystal sacrificial semiconductor layer 82 and the second single-crystal sacrificial semiconductor layers 14 through the first-type connection holes 96.

Specifically, as shown in FIG. 54, the first single-crystal sacrificial semiconductor layer 82 and the second single-crystal sacrificial semiconductor layers 14 may be removed by means of etching.

Step S432: filling a third insulating material in areas where the first single-crystal sacrificial semiconductor layer 82 and the second single-crystal sacrificial semiconductor layers 14 have been removed.

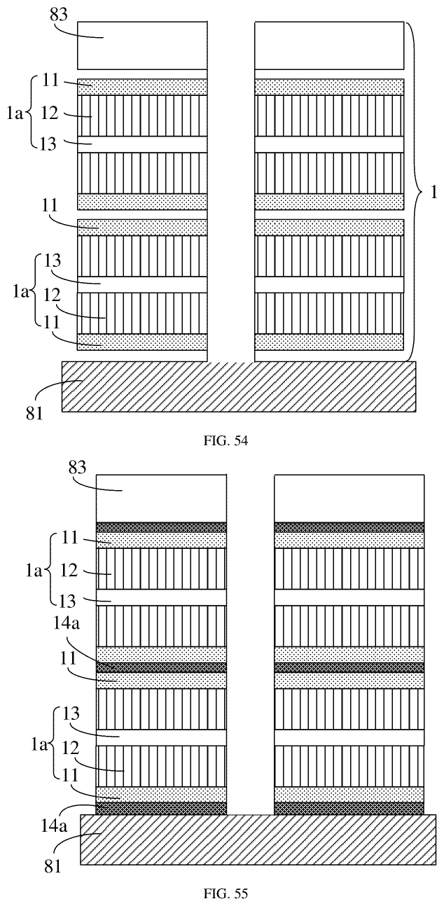

Specifically, as shown in FIG. 55, deposition may be carried out in the areas where the removed first single-crystal sacrificial semiconductor layer 82 and second single-crystal sacrificial semiconductor layers 14 were originally located, so as to fill the third insulating material in the areas where the removed first single-crystal sacrificial semiconductor layer 82 and second single-crystal sacrificial semiconductor layers 14 were originally located, thereby replacing the first single-crystal sacrificial semiconductor layer 82 and the second single-crystal sacrificial semiconductor layers 14 with an insulating isolation layer. It can be understood that a part of the insulating isolation layer corresponding to each column of semiconductor strip structures 1b is the interlayer isolation strip 14a mentioned above.

The third insulating material may be filled by means of atomic layer deposition. The third insulating material may specifically be silicon oxide. Those skilled in the art can understand that after the first single-crystal sacrificial semiconductor layer 82 and the second single-crystal sacrificial semiconductor layers 14 are removed in step S431, the isolation walls 3 may provide sufficient support for the adjacent stacked structures, so as to facilitate the subsequent operation of step S432.

Step S433: removing parts of the drain region semiconductor strips 11 and the source region semiconductor strips 13 on both sides exposed by each first-type connection hole 96 to form isolation recesses 97.

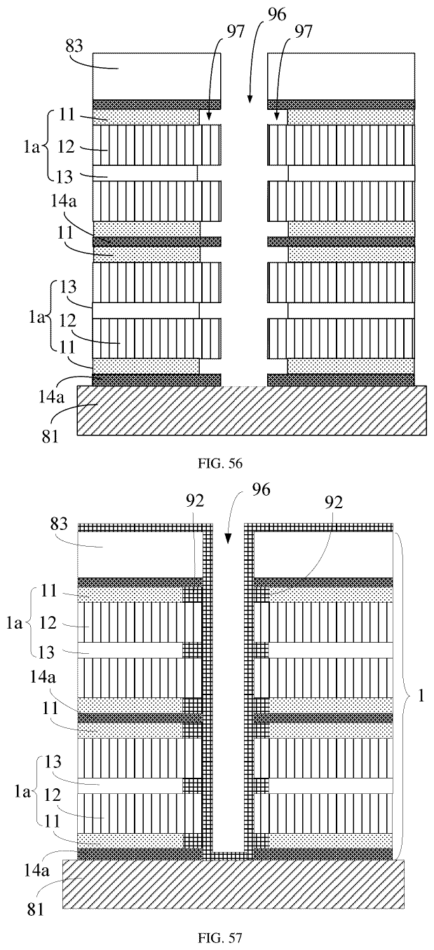

In combination with FIG. 56, the isolation recesses 97 may be formed by means of etching. Specifically, an etching process with a low etching ratio for the channel semiconductor strips 12 and a high etching ratio for the drain region semiconductor strips 11 and the source region semiconductor strips 13 may be used for etching. For example, in the case the drain region semiconductor strips 11 and the source region semiconductor strips 13 are N-type semiconductor strips, and the channel semiconductor strips 12 are P-type semiconductor strips, an etching process with a high etching ratio for the N-type semiconductor material and a low etching ratio for the P-type semiconductor material may be used for selective etching, so that only the parts of the drain region semiconductor strips 11 and the source region semiconductor strips 13 on both sides exposed by each first-type connection hole 96 are etched to form the isolation recesses 97.

Step S434: filling the first insulating material 92 in the isolation recesses 97 to cover the exposed drain region semiconductor strips 11 and source region semiconductor strips 13.

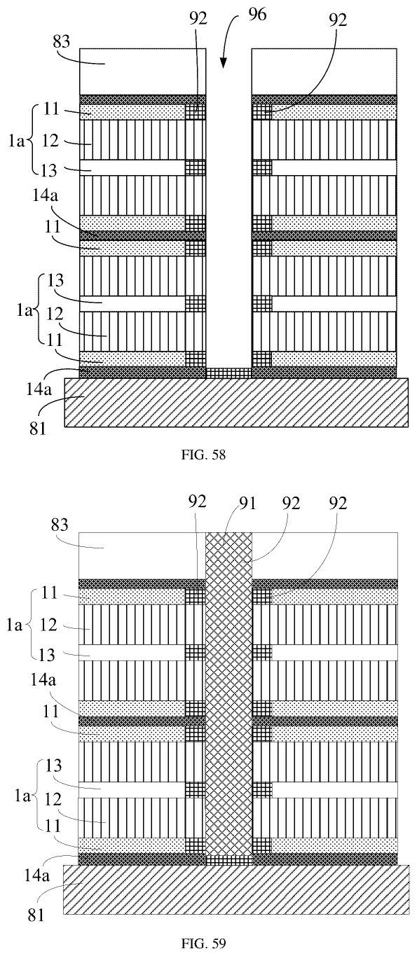

As shown in FIG. 57, the first insulating material 92 may be filled in the first-type connection holes 96 by means of deposition to cover the exposed drain region semiconductor strips 11, source region semiconductor strips 13, side walls of the first-type connection holes 96, an upper surface of the semiconductor substrate, and a surface of the substrate 81 exposed through the first-type connection holes 96. Then, as shown in FIG. 58, the first insulating material 92 on the upper surface of the semiconductor substrate and the side walls of the first-type connection holes 96 is removed, and each channel semiconductor strip 12 is exposed through the first-type connection holes 96. The first insulating material 92 on the surface of the substrate 81 exposed through the first-type connection holes 96 may not be removed or only partially removed, so that the channel connection posts 91 formed subsequently are insulated from the substrate 81 through the first insulating material 92. Of course, the channel connection posts 91 and the substrate 81 may also be set to have opposite conductivity types. For example, in the case the substrate 81 is N-type doped, the channel connection posts 91 are P-type doped. It can be understood that the first insulating material 92 on the surface of the substrate 81 exposed through the first-type connection holes 96 may be selectively removed entirely or partially. The first insulating material 92 is silicon oxide.

Since the interlayer isolation strips 14a and the first insulating material 92 are made of the same material, after the first single-crystal sacrificial semiconductor layer 82 and the second single-crystal sacrificial semiconductor layers 14 are removed, the isolation recesses 97 may be formed, and then silicon oxide may be deposited to form the interlayer isolation strips 14a in the areas where the first single-crystal sacrificial semiconductor layer 82 and the second single-crystal sacrificial semiconductor layers 14 were removed, and the first insulating material 92 may be filled in the isolation recesses 97. In this way, one deposition process may be reduced, and the interlayer isolation strips 14a and the first insulating material 92 may be formed simultaneously.

Step S435: filling a first conductive medium 99 in the first-type connection holes 96 to form the channel connection posts 91 in contact with the channel semiconductor strips 12.

As shown in FIG. 43a and FIG. 59, the first conductive medium 99 is filled in the entire first-type connection holes 96 and is in contact with each channel semiconductor strip 12 in the two adjacent columns of semiconductor strip structures 1b respectively, thereby forming the channel connection posts 91. Through the channel connection posts 91, each channel semiconductor strip 12 in the two adjacent columns of semiconductor strip structures 1b is led out to the surface of the semiconductor substrate. The first conductive medium 99 includes polysilicon and/or metal.

In specific embodiments, at least one side of each column of semiconductor strip structures 1b is arranged with a corresponding channel connection post 91. The channel connection posts 91 respectively extend along the height direction Z. At least part of the channel connection post 91 is in contact with each channel semiconductor strip 12 in the adjacent semiconductor strip structures 1b, so that each channel semiconductor strip 12 in the column of semiconductor strip structures 1b may be led out to the surface of the memory array 1 through the channel connection post 91. The channel connection post 91 is insulated from each drain region semiconductor strip 11 and each source region semiconductor strip 13 to prevent short-circuits. Compared with the scheme in which each channel semiconductor strip 12 in each column of semiconductor strip structures 1b is led out to the surface of the memory array 1 through the well-region connection line 12a, this scheme only needs one channel connection post 91 to lead out all the channel semiconductor strips 12 in the column of semiconductor strip structures 1b, which greatly reduces the area occupied by the channel connection posts 91 on the surface of the memory array 1 and reduces the process difficulty and cost.

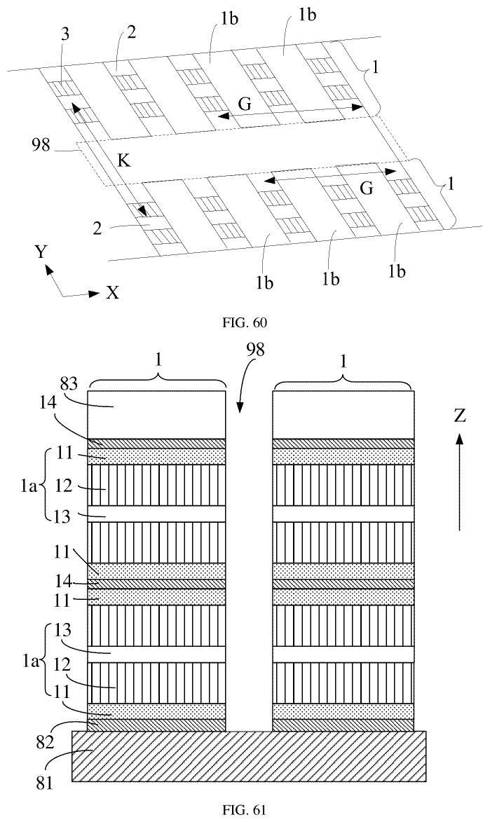

In other embodiments, as shown in FIG. 60 to FIG. 61, FIG. 60 is a schematic view of the semiconductor substrate after defining second-type connection holes 98; FIG. 61 is a cross-sectional view along a K-direction of the product shown in FIG. 60. The connection hole defined in step S42 includes multiple second-type connection holes 98. The second-type connection holes 98 extend along the height direction Z and the row direction X to the surface of the substrate 81. The second-type connection holes 98 may be configured to divide the multiple memory subarray layers into multiple memory arrays 1 spaced apart along the column direction Y, and to form the channel connection wall 93 of each memory array 1. Each second-type connection hole 98 exposes the positions of the end edge of each drain region semiconductor strip 11, channel semiconductor strip 12, and source region semiconductor strip 13 in the adjacent memory array 2. The second-type connection holes 98 are configured to form the channel connection walls 93. The manufacturing method of the channel connection wall 93 is similar to the manufacturing method of the channel connection post 91 mentioned above. The difference is that the positions of the first-type connection holes 96 and the second-type connection holes 98 are different, and the number of the channel connection wall 93 and the number of the channel connection posts 93 for each memory array 1 are also different.

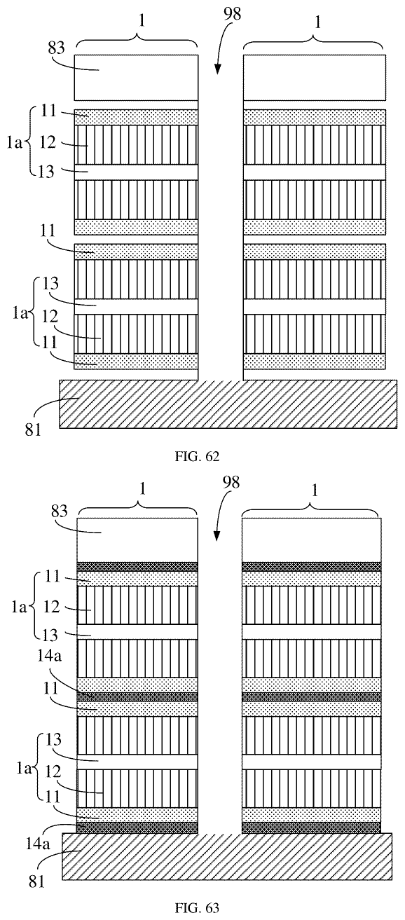

In some embodiments, as shown in FIG. 62 to FIG. 72, FIG. 62 to FIG. 72 are schematic views of structures at specific operations of step S43. Step S43 specifically includes the following operations.

Step S436: removing the first single-crystal sacrificial semiconductor layer 82 and the second single-crystal sacrificial semiconductor layers 14 through the second-type connection holes 98.

The product after step S436 may be shown in FIG. 62.

Step S437: filling the third insulating material in the areas where the first single-crystal sacrificial semiconductor layer 82 and the second single-crystal sacrificial semiconductor layers 14 have been removed.

The product after step S437 may be shown in FIG. 63.

Step S438: removing parts of the positions of the end edge of each drain region semiconductor strip 11 and source region semiconductor strip 13 in the two adjacent memory arrays 2 exposed through the second-type connection hole 98 to form isolation recesses 97.

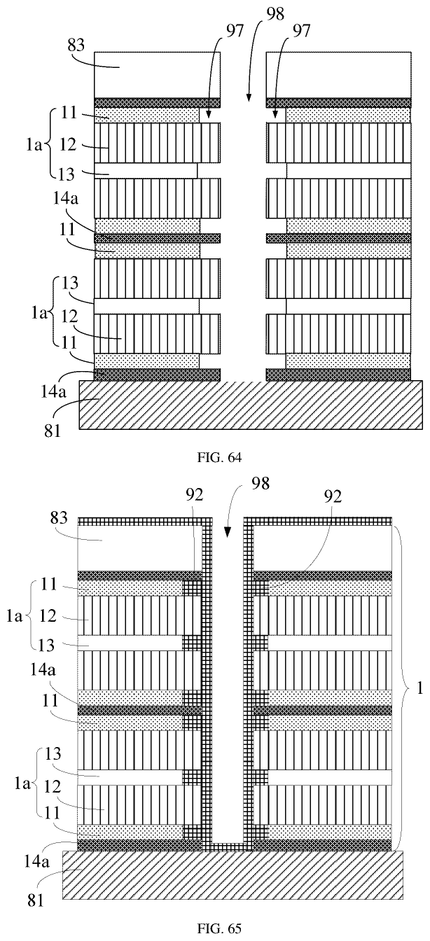

The product after step S438 may be shown in FIG. 64.

Step S439: filling the first insulating material 92 in the isolation recesses 97 to cover the exposed drain region semiconductor strips 11 and source region semiconductor strips 13.

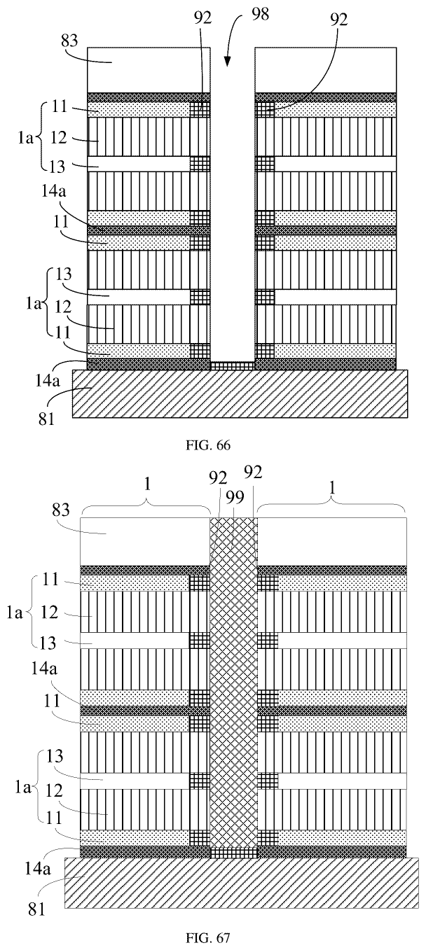

The product after step S439 may be shown in FIG. 65. Then, as shown in FIG. 66, all or part of the first insulating material 92 exposed on the surface of the substrate 81 through the second-type connection hole 98 is removed.

Step S440: filling the first conductive medium 99 in the second-type connection hole 98.

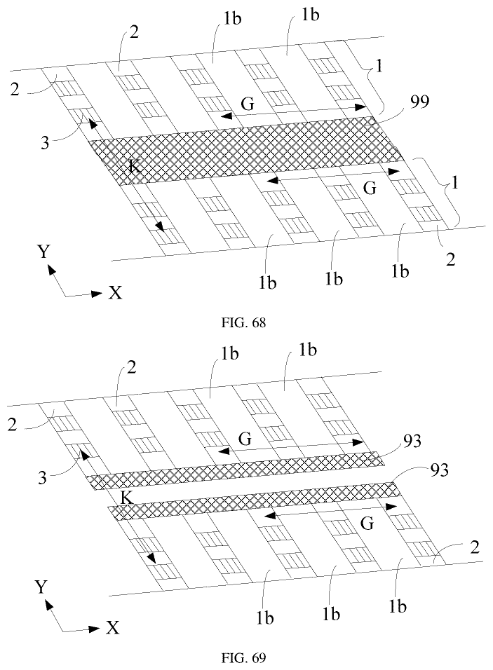

The product after step S440 may be shown in FIG. 67. The top view of the product corresponding to FIG. 67 is shown in FIG. 68.

The specific implementation of step $436 to step S440 mentioned above is similar to the specific implementation of step S431 to step S435 mentioned above. For details, please refer to the above content.

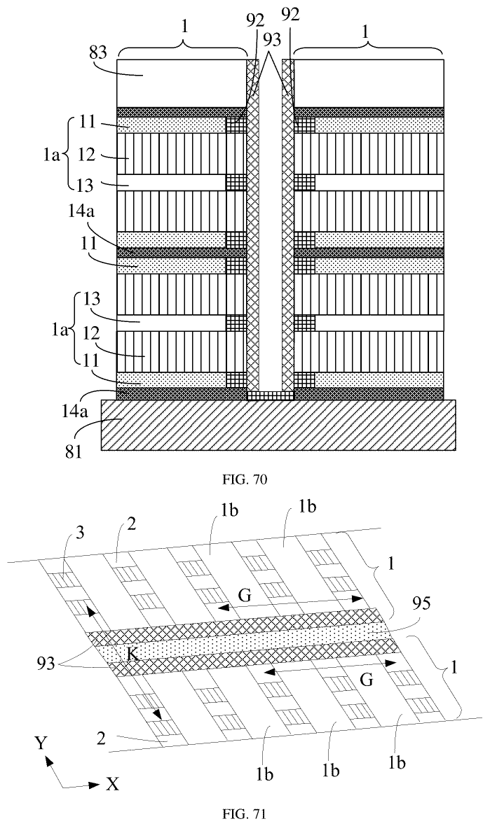

Further, as shown in FIG. 69 and FIG. 70, FIG. 69 is a schematic view of a product after removing part of the first conductive medium 99 in the second-type connection hole 98; FIG. 70 is a cross-sectional view along the K-direction of the product shown in FIG. 69. After step S440, the method further includes the following operation.

Step S441: removing part of the first conductive medium 99 in the second-type connection hole 98 along the column direction Y to form the channel connection wall 93 on each memory array 1 of the two adjacent memory arrays 1.

The channel connection wall 93 is disposed at the position of the end edge of each memory array 1, and extends along the height direction Z and the row direction X.

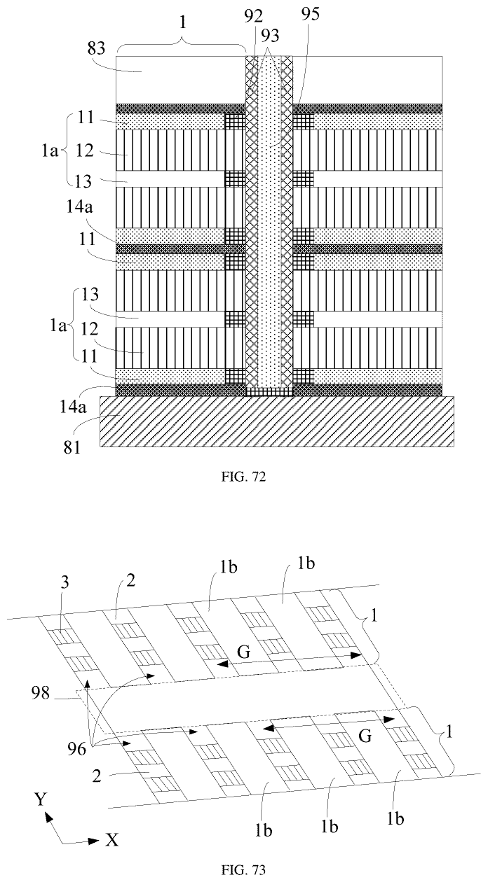

In combination with FIG. 71 to FIG. 72, FIG. 71 is a top view of a semiconductor substrate after filling the second insulating material 95 in a gap between two adjacent memory arrays 1; FIG. 72 is a cross-sectional view along the K-direction of the product shown in FIG. 70. After step S441, the method further includes the following operation.

Step S442: filling the second insulating material 95 at least in the gap between two adjacent memory arrays 1.

Specifically, the second insulating material 95 extends along the height direction Z to the surface of the substrate 81, and extends along the row direction X to completely isolate the channel connection walls 93 on two adjacent memory arrays 1. Further, as shown in FIG. 48, the second insulating material 95 may also be filled on other exposed surfaces of each memory array 1, so that the second insulating material 95 also surrounds other surfaces of the memory array 1. The second insulating material 95 on each surface extends along the height direction Z and the column direction Y or the row direction X.

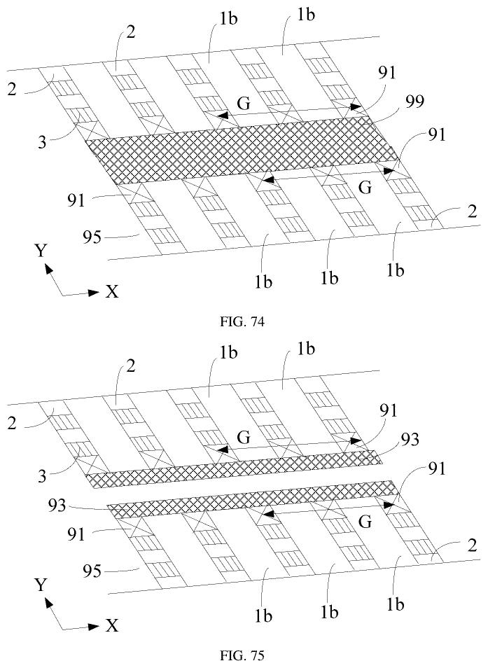

Of course, in other embodiments, as shown in FIG. 73, FIG. 73 is a top view of a semiconductor substrate after defining the first-type connection holes 96 and the second-type connection hole 98. The connection hole includes the first-type connection holes 96 and the second-type connection hole 98. In some embodiments, step S431 and step S436 may be carried out simultaneously; step S432 and step S437 may be carried out simultaneously; step S433 and step S438 may be carried out simultaneously; step S434 and step S439 may be carried out simultaneously; step S435 and step S440 may be carried out simultaneously. As shown in FIG. 74, while filling the first-type connection holes 96, the second-type connection hole 98 are filled synchronously, which simplifies the process and reduces the cost. As shown in FIG. 75, the first conductive medium 99 filled in the first-type connection holes 96 is configured to form the channel connection posts 91, and the first conductive medium 99 filled in the second-type connection hole 98 is configured to form the channel connection walls 93. It can be understood that since the first-type connection holes 96 corresponding to each memory array 1 are communicated with an adjacent second-type connection hole 98, the channel connection posts 91 formed in the first-type connection holes 96 are respectively in contact with the channel connection wall 93 formed in the second-type connection hole 98. Thus, a well region voltage may be uniformly applied to each channel semiconductor strip 12 through multiple channel connection posts 91 via the channel connection wall 93.

In the present disclosure, the semiconductor substrate is divided into multiple memory arrays 1 through the second-type connection holes 98, and multiple channel connection posts 91 and/or channel connection wall 93 are formed on each memory array 1. Compared with the scheme where multiple channel connection posts 91 and/or channel connection wall 93 corresponding to one memory array 1 are shared by the entire semiconductor substrate, this scheme may reduce parasitic capacitance and make the operation speed faster.

Specifically, the first conductive medium includes polysilicon and/or metal. In some embodiments, the first conductive medium includes polysilicon. In specific embodiments, as shown in FIG. 45, after the channel connection posts 91 and/or channel connection wall 93 are formed, the method further includes the following operation.

Step S443: arranging a second conductive medium on the surfaces of the channel connection posts 91 and/or the channel connection wall 93 away from the substrate 81 to form a connection layer 94.

Specifically, the connection layer 94 may be formed by deposition. The electrical conductivity of the second conductive medium is better than the electrical conductivity of the first conductive medium 99. The connection layer 94 with better electrical conductivity is used, and since the impedance of the connection layer 94 is smaller, more time is saved during signal transmission, making the response speed of the memory device faster. The second conductive medium may include a silicide containing metal.

Specifically, step S443 may be executed at any stage after forming the channel connection posts 91 and/or the channel connection wall 93. The present disclosure does not limit this.

The manufacturing method of the memory device provided in some embodiments is provided with the semiconductor substrate. The semiconductor substrate includes the substrate 81 and multiple memory subarray layers 1a stacked in sequence along the height direction Z on the substrate 81. Each memory subarray layer 1a includes a drain region semiconductor layer, a channel semiconductor layer, and a source region semiconductor layer stacked along the height direction Z. In each memory subarray layer 1a, the drain region semiconductor layer includes multiple drain region semiconductor strips 11 spaced apart along the row direction X, the channel semiconductor layer include multiple channel semiconductor strips 12 spaced apart along the row direction X, and the source region semiconductor layer include multiple source region semiconductor strips 13 spaced apart along the row direction X. Each drain region semiconductor strip 11, channel semiconductor strip 12, and source region semiconductor strip 13 extends along the column direction Y. The column of drain region semiconductor strips 11, channel semiconductor strips 12, and source region semiconductor strips 13 in multiple memory subarray layers la is defined as the column of semiconductor strip structures 1b. Compared with a two-dimensional memory device, the storage density of the memory device is higher. The connection hole is defined in the semiconductor substrate. The channel connection structure is formed in the connection hole. The channel connection structure extends along the height direction Z. At least part of the channel connection structure is in contact with each channel semiconductor strip 12 in the adjacent semiconductor strip structures 1b, so that each channel semiconductor strip 12 in the column of semiconductor strip structures 1b may be led out to the surface of the memory array 1 through the channel connection structure. The channel connection structure is not in contact with each drain region semiconductor strip 11 and each source region semiconductor strip 13 to prevent short-circuits. Compared with the scheme in which each channel semiconductor strip 12 in each column of semiconductor strip structures 1b is respectively led out to the surface of the memory array 1 through the well region connection line 12a, this scheme only needs the channel connection structure to lead out all the channel semiconductor strips 12 in the column of semiconductor strip structures 1b, which greatly reduces the area occupied by the channel connection structure on the surface of the memory array 1, and reduces the process difficulty and cost.

The above is only some embodiments of the present disclosure, and is not intended to limit the scope of the present disclosure. Any equivalent structure or equivalent process transformation using the contents and the accompanying drawings of the present disclosure, or any direct or indirect application in other related technical fields, is included in the scope of the present disclosure.

1. A memory device, comprising:
a substrate;
at least one memory array, arranged on the substrate, wherein each memory array comprises a plurality of memory subarray layers sequentially stacked along a height direction, and each memory subarray layer comprises a drain region semiconductor layer, a channel semiconductor layer, and a source region semiconductor layer stacked along the height direction; in each memory subarray layer, the drain region semiconductor layer comprises a plurality of drain region semiconductor strips spaced apart along a row direction, each drain region semiconductor strip extending along the row direction; the channel semiconductor layer comprises a plurality of channel semiconductor strips spaced apart along the row direction, each channel semiconductor strip extending along a column direction; the source region semiconductor layer comprises a plurality of source region semiconductor strips spaced apart along the row direction, each source region semiconductor strip extending along the column direction; a column of drain region semiconductor strips, channel semiconductor strips, and source region semiconductor strips in the memory subarray layers is defined as a column of semiconductor strip structures;
each memory array further comprises a channel connection structure, the channel connection structure extends along the height direction, and the channel connection structure is in contact with each channel semiconductor strip in each column of semiconductor strip structures, and is insulated from each drain region semiconductor strip and each source region semiconductor strip in each column of semiconductor strip structures.

2. The memory device according to claim 1, wherein
the channel connection structure comprises a plurality of channel connection posts; at least one side of each column of semiconductor strip structures is arranged with a corresponding channel connection post; each of the channel connection posts extends along the height direction, and at least a portion of each of the channel connection posts is in contact with each channel semiconductor strip in an adjacent column of semiconductor strip structures, and is insulated from each drain region semiconductor strip and each source region semiconductor strip in the adjacent column of semiconductor strip structures; and/or
the channel connection structure comprises a channel connection wall; the channel connection wall extends along the height direction and the row direction, and the channel connection wall is in contact with each channel semiconductor strip in each column of semiconductor strip structures, and is insulated from each drain region semiconductor strip and each source region semiconductor strip in each column of semiconductor strip structures.

3. The memory device according to claim 2, wherein two sides of each column of semiconductor strip structures are arranged with corresponding channel connection posts respectively, and two adjacent columns of semiconductor strip structures share a corresponding same channel connection post.

4. The memory device according to claim 2, wherein each of the channel connection posts is connected to the channel connection wall respectively, so that the plurality of channel connection posts are connected together through the channel connection wall.

5. The memory device according to claim 2, wherein in the column direction, both two sides of an end of each column of semiconductor strip structures are arranged with corresponding channel connection posts respectively, and each of the channel connection posts extends along the column direction to a position of an end edge of a corresponding column of semiconductor strip structures; the channel connection wall is arranged at the position of the end edge of each column of semiconductor strip structures, and extends along the height direction and the row direction and is in contact with the plurality of channel connection posts, for connecting the plurality of channel connection posts together.

6. The memory device according to claim 4, wherein the channel connection posts and the channel connection wall are integrally formed.

7. The memory device according to claim 2, wherein
each odd column of semiconductor strip structures is arranged with a corresponding channel connection post at a same side thereof; or
each even column of semiconductor strip structures is arranged with a corresponding channel connection post at a same side thereof.

8. The memory device according to claim 1, wherein a material of the channel connection structure comprises polysilicon;
each memory array further comprises:
a connection layer, arranged on a surface of a side of the channel connection structure away from the substrate; an electrical conductivity of the connection layer is better than an electrical conductivity of the channel connection structure.

9. The memory device according to claim 8, wherein a material of the connection layer comprises a metal silicide.

10. The memory device according to claim 1, wherein each drain region semiconductor strip and each source region semiconductor strip in each column of semiconductor strip structures are spaced apart from an adjacent channel connection structure; and a first insulating material is filled between each drain region semiconductor strip and each source region semiconductor strip in each column of semiconductor strip structures and the adjacent channel connection structure to achieve insulation through the first insulating material.

11. The memory device according to claim 1, wherein a number of the memory arrays is multiple; the channel connection structure in each memory array is located at a position of an end edge of the memory array, and a second insulating material is filled between two adjacent memory arrays to isolate the channel connection structure between the two adjacent memory arrays.

12. The memory device according to claim 2, wherein the plurality of channel connection posts are distributed in a straight line along the row direction; or the plurality of channel connection posts are staggered along the row direction.

13. A manufacturing method of a memory device, comprising:
providing a semiconductor substrate, wherein the semiconductor substrate comprises a substrate and a plurality of memory subarray layers arranged on the substrate and sequentially stacked in a height direction, and each memory subarray layer comprises a drain region semiconductor layer, a channel semiconductor layer, and a source region semiconductor layer stacked along the height direction; in each memory subarray layer, the drain region semiconductor layer comprises a plurality of drain region semiconductor strips spaced apart along a row direction, each drain region semiconductor strip extending along the row direction; the channel semiconductor layer comprises a plurality of channel semiconductor strips spaced apart along the row direction, each channel semiconductor strip extending along a column direction; the source region semiconductor layer comprises a plurality of source region semiconductor strips spaced apart along the row direction, each source region semiconductor strip extending along the column direction; a column of drain region semiconductor strips, channel semiconductor strips, and source region semiconductor strips in the memory subarray layers are defined as a column of semiconductor strip structures;
defining a connection hole on the semiconductor substrate;
forming a channel connection structure through the connection hole, wherein the channel connection structure extends along the height direction, and the channel connection structure is in contact with each channel semiconductor strip in each column of semiconductor strip structures, and is insulated from each drain region semiconductor strip and each source region semiconductor strip in each column of semiconductor strip structures.

14. The method according to claim 13, wherein
the connection hole comprises a plurality of first-type connection holes, each of the first-type connection holes extends to the substrate along the height direction, and each of the first-type connection holes exposes a portion of each drain region semiconductor strip, channel semiconductor strip, and source region semiconductor strip in an adjacent column of semiconductor strip structures, so as to form a plurality of channel connection posts; at least one side of each column of semiconductor strip structures is arranged with a corresponding channel connection post;
the channel connection posts extend along the height direction, and at least a portion of a channel connection post is in contact with each channel semiconductor strip in the adjacent column of semiconductor strip structures, and is insulated from each drain region semiconductor strip and each source region semiconductor strip; and/or
the connection hole comprises a second-type connection hole, the second-type connection hole extends to the substrate along the height direction and the row direction, and is configured to form a channel connection wall of each memory array; the second-type connection hole exposes a position of an end edge of each drain region semiconductor strip, channel semiconductor strip, and source region semiconductor strip in an adjacent memory array; the channel connection wall extends along the height direction and the row direction, and the channel connection wall is in contact with each channel semiconductor strip in each column of semiconductor strip structures, and is insulated from each drain region semiconductor strip and each source region semiconductor strip in each column of semiconductor strip structures.

15. The method according to claim 14, wherein the forming a channel connection structure through the connection hole, comprises:
removing parts of the drain region semiconductor strips and the source region semiconductor strips exposed through each of the first-type connection holes and/or the second-type connection hole to form isolation recesses;
filling the isolation recesses with a first insulating material to cover the exposed drain region semiconductor strips and the exposed source region semiconductor strips;
filling a first conductive medium in each of the first-type connection holes and/or the second-type connection hole to form each of the channel connection posts and/or the channel connection wall in contact with the channel semiconductor strips.

16. The method according to claim 15, further comprising:
removing a portion of the first conductive medium in the second-type connection hole along the column direction to form the channel connection wall on each of two adjacent memory arrays; wherein the channel connection wall is arranged at the position of the end edge of each memory array and extends along the height direction and the row direction.

17. The method according to claim 16, wherein further comprising:
filling a second insulating material in at least a gap between the two adjacent memory arrays.

18. The method according to claim 15, wherein the first conductive medium comprises polysilicon;
the method further comprises:
disposing a second conductive medium on surfaces of the channel connection posts and/or the channel connection wall away from the substrate to form a connection layer; wherein an electrical conductivity of the second conductive medium is better than an electrical conductivity of the first conductive medium.

19. The method according to claim 14, wherein the first-type connection holes and the second-type connection hole are formed simultaneously and filled with a first conductive material to simultaneously form the channel connection posts and the channel connection wall.

20. The method according to claim 18, wherein the second conductive medium comprises a silicide containing a metal.
